(19) United States
(12) Patent Application Publication
(10) Pub. No.: US 2023/0116120 A1
(43) Pub. Date: Apr. 13, 2023

(54) CHEMICALLY AMPLIFIED RESIST COMPOSITION AND PATTERNING PROCESS

(71) Applicant: Shin-Etsu Chemical Co., Ltd., Tokyo (JP)

(72) Inventors: Masaki Ohashi, Joetsu-shi (JP); Masahiro Fukushima, Joetsu-shi (JP); Kazuhiro Katayama, Joetsu-shi (JP)

(73) Assignee: Shin-Etsu Chemical Co., Ltd., Tokyo (JP)

(21) Appl. No.: 17/944,654

(22) Filed: Sep. 14, 2022

(30) Foreign Application Priority Data
Sep. 24, 2021 (JP) 2021-155463

(51) Int. Cl. G03F 7/029; G03F 7/038; G03F 7/039; G03F 7/004; G03F 7/20

(52) U.S. Cl. CPC G03F 7/0295; G03F 7/0048; G03F 7/0382; G03F 7/0392; G03F 7/2006

(57) ABSTRACT

A chemically amplified resist composition comprising (A) a polymer adapted to increase its solubility in alkaline aqueous solution under the action of acid, (B) a photoacid generator capable of generating an acid upon exposure to KrF excimer laser, ArF excimer laser, EB or EUV, and (C) a quencher in the form of an amine compound of specific structure is provided. The resist composition has a high sensitivity and forms a pattern with a high resolution and improved LWR or CDU, independent of whether it is of positive or negative tone.

### CROSS-REFERENCE TO RELATED APPLICATION

This non-provisional application claims priority under 35 U.S.C. §119(a) on Patent Application No. 2021-155463 filed in Japan on Sep. 24, 2021, the entire contents of which are hereby incorporated by reference.

### TECHNICAL FIELD

This invention relates to a chemically amplified resist composition and a pattern forming process.

### BACKGROUND ART

To meet the demand for higher integration density and operating speed of LSIs, the effort to reduce the pattern rule is in rapid progress. In particular, the enlargement of the logic memory market to comply with the wide-spread use of smart phones drives forward the miniaturization technology. As the advanced miniaturization technology, manufacturing of microelectronic devices at the 10-nm node by double patterning of the ArF immersion lithography has been implemented in a mass scale. Manufacturing of 7-nm node devices as the next generation by the double patterning technology is approaching to the verge of high-volume application. The candidate for 5-nm node devices as the next generation but one is EUV lithography.

With the progress of miniaturization in logic devices, the flash memory now takes the form of devices having stacked layers of gate, known as 3D-NAND. The capacity is increased by increasing the number of stacked layers. As the number of stacked layers increases, the hard mask used in processing of layers becomes thicker and the photoresist film also becomes thicker. While the resist film for logic devices becomes thinner, the resist film for 3D-NAND becomes thicker.

As the pattern feature size is reduced, approaching to the diffraction limit of light, light contrast lowers. In the case of positive resist film, a lowering of light contrast leads to reductions of resolution and focus margin of hole and trench patterns. For avoiding such inconvenience, an attempt is made to enhance the dissolution contrast of resist film.

Chemically amplified resist compositions comprising an acid generator capable of generating an acid upon exposure to light or EB include chemically amplified positive resist compositions wherein deprotection reaction takes place under the action of acid and chemically amplified negative resist compositions wherein polarity switch or crosslinking reaction takes place under the action of acid. Quenchers (or acid diffusion controlling agents) are often added to these resist compositions for the purpose of controlling the diffusion of the acid to unexposed region to improve the contrast. The addition of quenchers is fully effective to this purpose. A number of amine quenchers were proposed as disclosed in Patent Documents 1 and 2. The amine quencher, however, volatilizes in part during post-exposure bake (PEB), failing to achieve adequate acid diffusion control. It was considered to prevent volatilization by introducing a long-chain alkyl group or bulky structure in the amine compounds. This converts the amine compound to a highly lipophilic structure, which inhibits solubility in alkaline developer and detracts from resolution.

Not only quenchers of amine structure, but also quenchers of onium salt type have been developed. With respect to the acid labile group used in (meth)acrylate polymers for the ArF lithography resist material, deprotection reaction takes place when a photoacid generator capable of generating a sulfonic acid having fluorine substituted at α-position (referred to “α-fluorinated sulfonic acid”) is used, but not when an acid generator capable of generating a sulfonic acid not having fluorine substituted at α-position (referred to “α-non-fluorinated sulfonic acid”) or carboxylic acid is used. If a sulfonium or iodonium salt capable of generating an α-fluorinated sulfonic acid is combined with a sulfonium or iodonium salt capable of generating an α-non-fluorinated sulfonic acid, the sulfonium or iodonium salt capable of generating an α-non-fluorinated sulfonic acid undergoes ion exchange with the α-fluorinated sulfonic acid. Through the ion exchange, the α-fluorinated sulfonic acid thus generated by light exposure is converted back to the sulfonium or iodonium salt while the sulfonium or iodonium salt of an α-non-fluorinated sulfonic acid or carboxylic acid functions as a quencher. Patent Document 3 discloses a resist composition having such a function.

The quenchers of photo-decomposable onium salt type are effective for improving LWR and CDU. Since these compounds have a photosensitive structure, specifically absorb radiation of wavelength 193 nm in the ArF lithography, a resist film containing the same is reduced in transmittance. As a result, in the case of positive resist compositions, the cross-sectional shape of a pattern is tapered. In addition, the quenchers of photo-decomposable onium salt type have the problem that the photo-decomposed products inhibit the dissolving power of developer, leading to a loss of resolution. These reasons negate an approach of increasing the amount of the quencher to enhance the acid diffusion controlling ability.

A technique of incorporating a photoacid generator into a base polymer is an effective means for controlling acid diffusion. For example. Patent Document 4 discloses a sulfonium salt having a partially fluorinated alkane sulfonic acid anion as a polymerizable unit. At the stage of ultra-fine generation of sub-10-nm node, even such a technique fails to clear the requirement of LWR or CDU. Also, excessive suppression of acid diffusion leads to insufficient resolution and low sensitivity.

### Citation List

Patent Document 1: JP-A 2001-194776
Patent Document 2: JP-A 2002-226470
Patent Document 3: WO 2008/066011
Patent Document 4: JP-A 2008-133448

### DISCLOSURE OF INVENTION

For the acid-catalyzed chemically amplified resist material, it is desired to develop a high-sensitivity resist composition capable of reducing the LWR of line patterns or improving the CDU of hole patterns and increasing resolution. To this end, it is necessary to adequately control the acid diffusion and to increase the contrast.

An object of the invention is to provide a chemically amplified resist composition which exhibits a high sensitivity and forms a pattern with a reduced LWR or improved CDU and satisfactory resolution, independent of whether it is of positive tone or negative tone: and a pattern forming process using the same.

The inventors have found that using a specific polymer, a photoacid generator, and a specific amine compound as a quencher, a chemically amplified resist composition having a high sensitivity, reduced LWR, improved CDU. and satisfactory resolution is obtained.

In one aspect, the invention provides a chemically amplified resist composition comprising
(A) a polymer A adapted to increase its solubility in alkaline aqueous solution under the action of acid,
(B) a photoacid generator capable of generating an acid upon exposure to KrF excimer laser radiation, ArF excimer laser radiation, EB or EUV, and
(C) a quencher in the form of an amine compound.
The photoacid generator (B) has the formula (1a) or (1b):

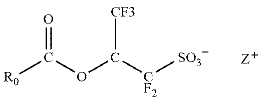

wherein R⁰ is hydrogen or a C₁-C₅₀ hydrocarbyl group in which some or all of the hydrogen atoms may be substituted by halogen and any constituent —CH₂— may be replaced by —O— or —C(═O)—, Z⁺ is an organic cation.

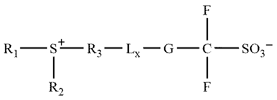

wherein R¹ and R² are each independently a C₁-C₂₀ hydrocarbyl group which may contain a heteroatom, R¹ and R² may bond together to form a ring with the sulfur atom to which they are attached, R³ is a C₁-C₂₀ hydrocarbylene group which may contain a heteroatom, G is a single bond or a C₁-C₂₀ hydrocarbylene group which may contain a heteroatom, and Lx is a divalent linking group.

The amine compound has the formula (2):

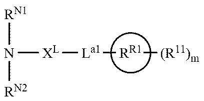

wherein m is an integer of 0 to 10,
R^{N1} and R^{N2} are each independently hydrogen or a C₁-C₂₀ hydrocarbyl group in which some or all of the hydrogen atoms may be substituted by halogen and any constituent —CH₂— may be replaced by —O— or —C(═O)—, R^{N1} and R^{N2} may bond together to form a ring with the nitrogen atom to which they are attached, the ring optionally containing —O— or —S—, with the proviso that R^{N1} and R^{N2} are not hydrogen at the same time,
X^{L} is a C₁-C₄₀ hydrocarbylene group which may contain a heteroatom,
L^{a1} is a single bond, ether bond, ester bond, sulfonic ester bond, carbonate bond or carbamate bond,
the ring R^{R1} is a C₂-C₂₀ (m+1)-valent heterocyclic group having a lactone, lactam, sultone or sultam structure,
R¹¹ is a C₁-C₂₀ hydrocarbyl group which may contain a heteroatom, and when m is 2 or more, a plurality of R¹¹ may be the same or different, and a plurality of R¹¹ may bond together to form a ring with the atoms on R^{R1} to which they are attached.

In a preferred embodiment, the polymer A comprises repeat units having the formula (a1) or (a2).

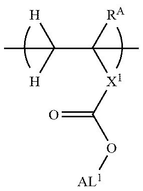

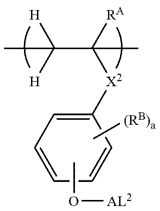

Herein R^{A} is each independently hydrogen, fluorine, methyl or trifluoromethyl; X¹ is a single bond, phenylene, naphthylene, or *—C(═O)—O—X¹¹— wherein X¹¹ is a C₁-C₁₀ alkanediyl group which may contain a hydroxy moiety, ether bond, ester bond or lactone ring, or phenylene group or naphthylene group; X² is a single bond or *—C(═O)—O—; the asterisk (*) designates a point of attachment to the carbon atom in the backbone; AL¹ and AL² are each independently an acid labile group; R^{B} is a C₁-C₂₀ hydrocarbyl group which may contain a heteroatom; and a is an integer of 0 to 4.

In a preferred embodiment, the polymer A comprises repeat units having the formula (b1) or (b2).

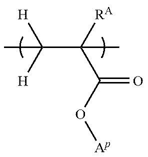

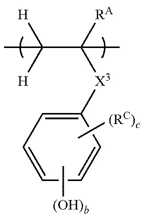

Herein R^{A} is each independently hydrogen, fluorine, methyl or trifluoromethyl; A^{p} is hydrogen, or a polar group containing at least one structure selected from a hydroxy moiety, cyano moiety, carbonyl moiety, carboxy moiety, ether bond, ester bond, sulfonic ester bond, carbonate bond, lactone ring, sultone ring, and carboxylic anhydride (—C(═O)—O—C(═O)—); X³ is a single bond or *—C(═O)—O—, the asterisk (*) designates a point of attachment to the carbon atom in the backbone; R^{C} is halogen, cyano group, or a C₁-C₂₀ hydrocarbyl group which may contain a heteroatom, C₁-C₂₀ hydrocarbyloxy group which may contain a heteroatom, or C₂-C₂₀ hydrocarbylcarbonyl group which may contain a heteroatom; b is an integer of 1 to 4, c is an integer of 0 to 4, and 1 ≤ b+c ≤ 5.

The resist composition may further comprise (D) an organic solvent, (E) a quencher other than the amine compound having formula (2), and/or (F) a surfactant.

In another aspect, the invention provides a pattern forming process comprising the steps of applying the chemically amplified resist composition defined herein onto a substrate to form a resist film thereon, exposing the resist film to KrF excimer laser radiation, ArF excimer laser radiation, EB or EUV, and developing the exposed resist film in a developer.

### ADVANTAGEOUS EFFECTS OF INVENTION

The chemically amplified resist composition has a high ability to control acid diffusion and a high dissolution contrast, and forms a pattern of good profile with low LWR or improved CDU and high resolution.

### BRIEF DESCRIPTION OF DRAWINGS

FIG. 1 is a ¹H-NMR spectrum of Compound Q-1 synthesized in Synthesis Example 1-1.

FIG. 2 is a ¹H-NMR spectrum of Compound Q-2 synthesized in Synthesis Example 1-2.

FIG. 3 is a ¹H-NMR spectrum of Compound Q-3 synthesized in Synthesis Example 1-3.

### DESCRIPTION OF EMBODIMENTS

As used herein, the singular forms “a,” “an” and “the” include plural referents unless the context clearly dictates otherwise. “Optional” or “optionally” means that the subsequently described event or circumstances may or may not occur, and that description includes instances where the event or circumstance occurs and instances where it does not. The notation (Cₙ—Cₘ) means a group containing from n to m carbon atoms per group. The term “group” and “moiety” are interchangeable. In chemical formulae, the broken line (—-) and asterisk (*) each designate a point of attachment, namely valence bond. Me stands for methyl and Ac for acetyl.

The abbreviations and acronyms have the following meaning.
EB: electron beam
EUV: extreme ultraviolet
Mw: weight average molecular weight
Mn: number average molecular weight
Mw/Mn: molecular weight dispersity
GPC: gel permeation chromatography
PEB: post-exposure bake
PAG: photoacid generator
LWR: line width roughness
CDU: critical dimension uniformity

### Resist Composition

One embodiment of the invention is a chemically amplified resist composition comprising (A) a polymer A adapted to increase its solubility in alkaline aqueous solution under the action of acid, (B) a photoacid generator capable of generating an acid upon exposure to KrF excimer laser radiation, ArF excimer laser radiation, EB or EUV, and (C) a quencher in the form of an amine compound of specific structure as essential components.

### (A) Polymer

The chemically amplified resist composition comprises (A) a polymer A adapted to increase its solubility in alkaline aqueous solution under the action of acid. Preferably the polymer A comprises repeat units having an acid labile group, specifically repeat units having the formula (a1) or repeat units having the formula (a2). These units are also referred to as repeat units (a1) and (a2).

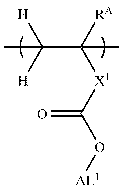

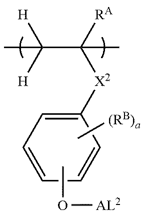

In formulae (a1) and (a2), R^{A} is each independently hydrogen, fluorine, methyl or trifluoromethyl. X¹ is a single bond, phenylene, naphthylene, or *—C(═O)—O—X¹¹—, wherein X¹¹ is a C₁-C₁₀ alkanediyl group which may contain a hydroxy moiety, ether bond, ester bond or lactone ring, or phenylene group or naphthylene group. X² is a single bond or *—C(═O)—O—. The asterisk (*) designates a point of attachment to the carbon atom in the backbone. AL¹ and AL² are each independently an acid labile group.

In formula (a2). R^{B} is a C₁-C₂₀ hydrocarbyl group which may contain a heteroatom. The hydrocarbyl group may be saturated or unsaturated and straight, branched or cyclic. Examples thereof include C₁-C₂₀ alkyl groups such as methyl, ethyl, n-propyl, isopropyl, n-butyl, and tert-butyl; C₃-C₂₀ cyclic saturated hydrocarbyl groups such as cyclopropyl, cyclopentyl, cyclohexyl, cyclopropylmethyl, 4-methylcyclohexyl, cyclohexylmethyl, norbornyl, and adamantyl; C₂-C₂₀ alkenyl groups such as vinyl, allyl, propenyl, butenyl, and hexenyl; C₃-C₂₀ cyclic unsaturated hydrocarbyl groups such as cyclohexenyl; C₆-C₂₀ aryl groups such as phenyl and naphthyl; C₇-C₂₀ aralkyl groups such as benzyl, 1-phenylethyl and 2-phenylethyl; and combinations thereof. In the hydrocarbyl group, some or all of the hydrogen atoms may be substituted by a moiety containing a heteroatom such as oxygen, sulfur, nitrogen or halogen, and any constituent —CH₂— may be replaced by a moiety containing a heteroatom such as oxygen, sulfur or nitrogen, so that the group may contain a hydroxy moiety, fluorine, chlorine, bromine, iodine, cyano moiety, carbonyl moiety, ether bond, ester bond, sulfonic ester bond, carbonate bond, lactone ring, sultone ring, carboxylic anhydride (—C(═O)—O—C(═O)—) or haloalkyl moiety.

In formula (a2). “a” is an integer of 0 to 4, preferably 0 or 1.

Examples of the structure of formula (a1) wherein X¹ is a variant are illustrated below, but not limited thereto. Herein R^{A} and AL¹ are as defined above.

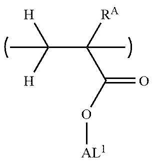

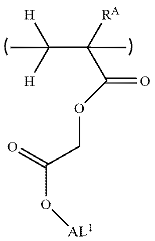

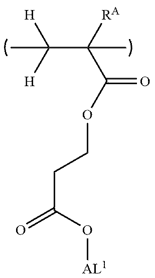

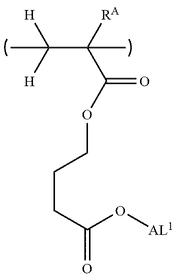

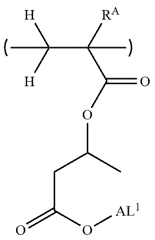

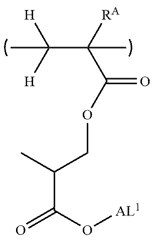

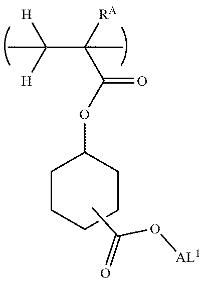

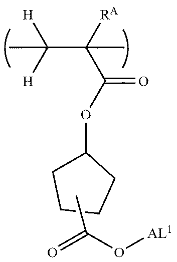

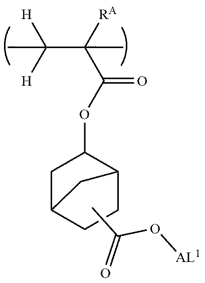

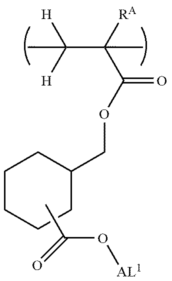

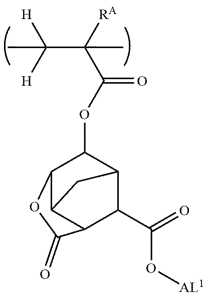

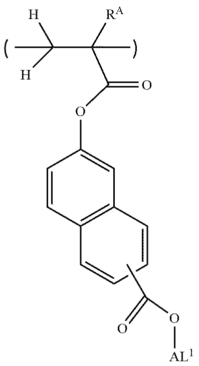

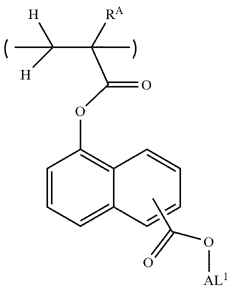

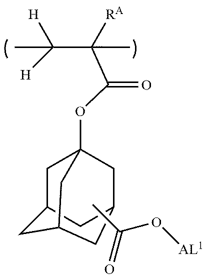

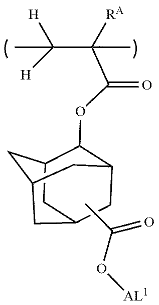

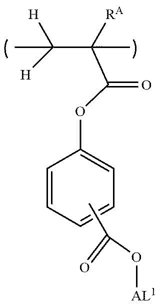

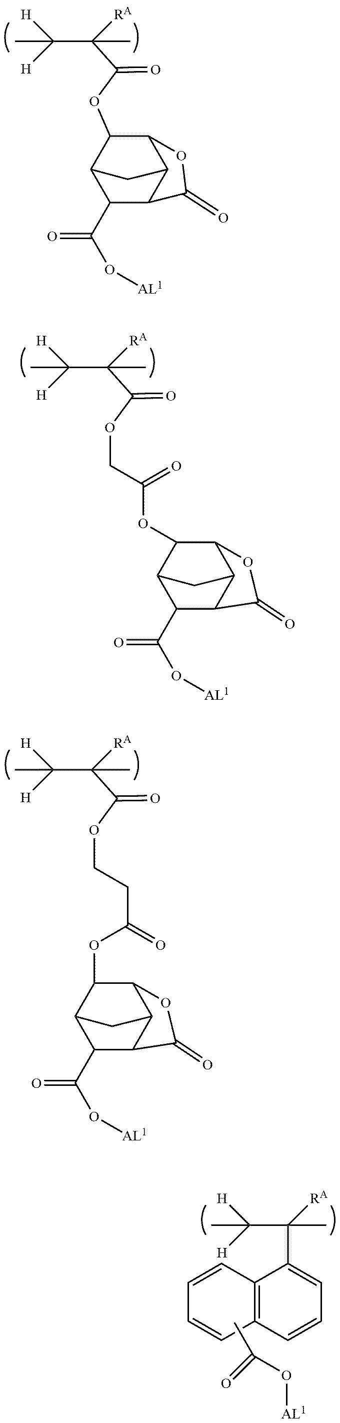

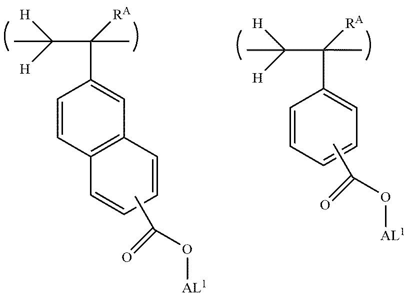

A polymer comprising repeat units (a1) turns alkali soluble through the mechanism that it is decomposed to generate a carboxy group under the action of acid.

The acid labile groups represented by AL¹ and AL² may be selected from a variety of such groups. Preferred examples of the acid labile group are groups of the following formulae (L1) to (L4), C₄-C₂₀, preferably C₄-C₁₅ tertiary hydrocarbyl groups, trialkylsilyl groups in which each alkyl moiety has 1 to 6 carbon atoms, and C₄-C₂₀ saturated hydrocarbyl groups containing a carbonyl moiety, ether bond or ester bond.

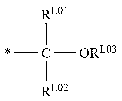

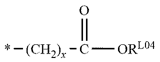

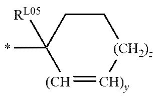

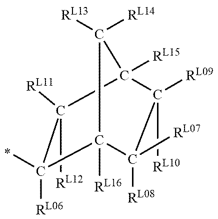

In formula (L1), R^{L01} and R^{L02} are each independently hydrogen or a C₁-C₁₈ saturated hydrocarbyl group. The saturated hydrocarbyl group may be straight, branched or cyclic and examples thereof include alkyl groups such as methyl, ethyl, propyl, isopropyl, n-butyl, sec-butyl, tert-butyl, n-octyl, and 2-ethylhexyl, and cyclic saturated hydrocarbyl groups such as cyclopentyl, cyclohexyl, norbornyl, tricyclodecanyl, tetracyclododecanyl, and adamantyl. Of the saturated hydrocarbyl groups, those of 1 to 10 carbon atoms are preferred.

R^{L03} is a C₁-C₁₈, preferably C₁-C₁₀ hydrocarbyl group which may contain a moiety containing a heteroatom. The hydrocarbyl group may be saturated or unsaturated and straight, branched or cyclic. Saturated hydrocarbyl groups are preferred. In the saturated hydrocarbyl group, some or all of the hydrogen atoms may be substituted by hydroxy, saturated hydrocarbyloxy, oxo, amino, saturated hydrocarbylamino or the like, or any constituent —CH₂— may be replaced by a moiety containing a heteroatom, typically oxygen. Suitable saturated hydrocarbyl groups are as exemplified above for the saturated hydrocarbyl groups R^{L01} and R^{L02}. Examples of the substituted saturated hydrocarbyl group are shown below.

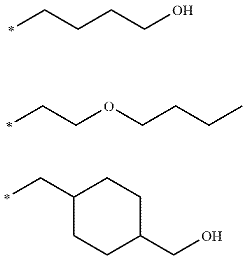

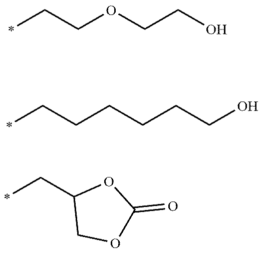 [SMILES: *CCOCCO ; *CCCCCCO ; *CC1COC(=O)O1]

Any two of R^{L01}, R^{L02}, and R^{L03} may bond together to form a ring with the carbon atom or the carbon and oxygen atoms to which they are attached. When any two of R^{L01}, R^{L02} and R^{L03} form a ring, each is independently a C₁-C₁₈, preferably C₁-C₁₀ alkanediyl group.

In formula (L2), R^{L04} is a C₄-C₂₀, preferably C₄-C₁₅ tertiary hydrocarbyl group, a trialkylsilyl group in which each alkyl moiety has 1 to 6 carbon atoms, a C₄-C₂₀ saturated hydrocarbyl group containing a carbonyl moiety, ether bond or ester bond, or a group of formula (L1). The subscript x is an integer of 0 to 6.

Of the groups R^{L04}, the tertiary hydrocarbyl group may be branched or cyclic, and examples thereof include tert-butyl, tert-pentyl, 1,1-diethylpropyl, 2-cyclopentylpropan-2-yl, 2-cyclohexylpropan-2-yl, 2-(bicyclo[2.2.1]heptan-2-yl)propan-2-yl, 2-(adamantan-1-yl)propan-2-yl, 1-ethylcyclopentyl, 1-butylcyclopentyl, 1-ethylcyclohexyl, 1-butylcyclohexyl, 1-ethyl-2-cyclopentenyl, 1-ethyl-2-cyclohexenyl, 2-methyl-2-adamantyl, and 2-ethyl-2-adamantyl. Exemplary trialkylsilyl groups include trimethylsilyl, triethylsilyl, and dimethyl-tert-butylsilyl. Exemplary saturated hydrocarbyl groups containing a carbonyl, ether bond or ester bond include 3-oxocyclohexyl, 4-methyl-2-oxooxan-4-yl, and 5-methyl-2-oxooxolan-5-yl.

In formula (L3), R^{L05} is an optionally substituted C₁-C₈ saturated hydrocarbyl group or an optionally substituted C₆-C₂₀ aryl group. The optionally substituted saturated hydrocarbyl group may be straight, branched or cyclic and examples thereof include alkyl groups such as methyl, ethyl, propyl, isopropyl, n-butyl, sec-butyl, tert-butyl, tert-pentyl, n-pentyl, and n-hexyl, cyclic saturated hydrocarbyl groups such as cyclopentyl and cyclohexyl, and substituted forms of the foregoing in which some or all of the hydrogen atoms are substituted by hydroxy, C₁-C₆ saturated hydrocarbyloxy, carboxy, C₁-C₆ saturated hydrocarbylcarbonyl, oxo, amino, C₁-C₆ saturated hydrocarbylamino, cyano, mercapto, C₁-C₆ saturated hydrocarbylthio, sulfo or the like. Examples of the optionally substituted aryl group include phenyl, methylphenyl, naphthyl, anthryl, phenanthryl, and pyrenyl, and substituted forms of the foregoing in which some or all of the hydrogen atoms are substituted by hydroxy, C₁-C₁₀ saturated hydrocarbyloxy, carboxy. C₁-C₁₀ saturated hydrocarbylcarbonyl, oxo, amino, C₁-C₁₀ saturated hydrocarbylamino, cyano, mercapto, C₁-C₁₀ saturated hydrocarbylthio, sulfo or the like.

In formula (L3), y is equal to 0 or 1, z is an integer of 0 to 3. and 2y+z is equal to 2 or 3.

In formula (L4). R^{L06} is an optionally substituted C₁-C₈ saturated hydrocarbyl group or an optionally substituted C₆-C₂₀ aryl group. Examples of the optionally substituted saturated hydrocarbyl and optionally substituted aryl groups are the same as exemplified above for R^{L05}.

R^{L07} to R^{L16} are each independently hydrogen or an optionally substituted C₁-C₁₅ hydrocarbyl group. The hydrocarbyl group may be saturated or unsaturated and straight, branched or cyclic, with saturated hydrocarbyl groups being preferred. Examples of the hydrocarbyl group include alkyl groups such as methyl, ethyl, propyl, isopropyl, n-butyl, sec-butyl, tert-butyl, tert-pentyl, n-pentyl, n-hexyl, n-octyl, n-nonyl, and n-decyl; cyclic saturated hydrocarbyl groups such as cyclopentyl, cyclohexyl, cyclopentylmethyl, cyclopentylethyl, cyclopentylbutyl, cyclohexylmethyl, cyclohexylethyl and cyclohexylbutyl; and substituted forms of the foregoing in which some or all of the hydrogen atoms are substituted by hydroxy, C₁-C₁₀ saturated hydrocarbyloxy, carboxy, C₁-C₁₀ saturated hydrocarbyloxycarbonyl, oxo, amino, C₁-C₁₀ saturated hydrocarbylamino, cyano, mercapto, C₁-C₁₀ saturated hydrocarbylthio, sulfo or the like. Alternatively, two of R^{L07} to R^{L16} may bond together to form a ring with the carbon atom to which they are attached (for example, a pair of R^{L07} and R^{L08}, R^{L07} and R^{L09}, R^{L07} and R^{L10}, R^{L08} and R^{L10}, R^{L09} and R^{L10}, R^{L11} and R^{L12}, R^{L13} and R^{L14} or a similar pair form a ring). Each of ring-forming R^{L07} to R^{L16} represents a C₁-C₁₅ hydrocarbylene group, examples of which are the ones exemplified above for the hydrocarbyl groups, with one hydrogen atom being eliminated. Two of R^{L07} to R^{L16} which are attached to vicinal carbon atoms may bond together directly to form a double bond (for example, a pair of R^{L07} and R^{L09}, R^{L09} and R^{L15}, R^{L13} and R^{L15}, R^{L14} and R^{L15}, or a similar pair).

Of the acid labile groups having formula (L1), the straight and branched ones are exemplified by the following groups, but not limited thereto.

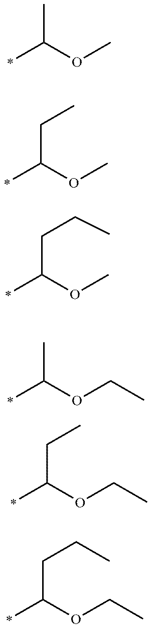

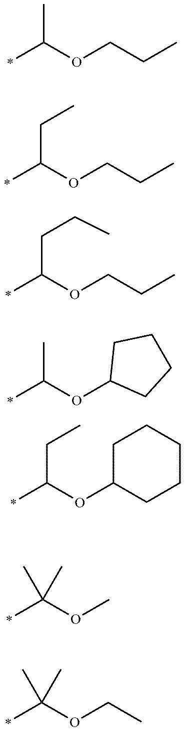

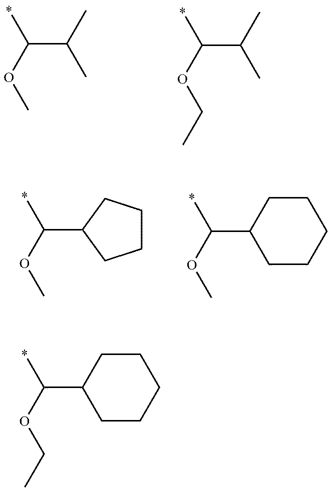

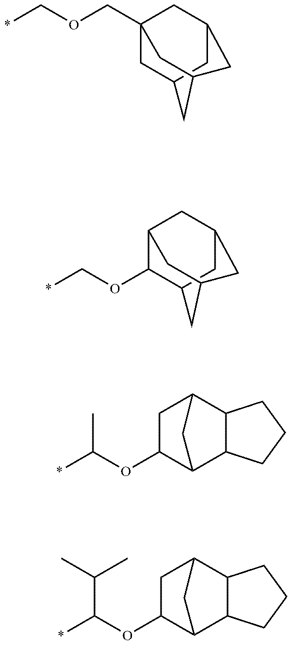 [SMILES: *COCC12CC3CC(CC(C3)C1)C2 ; *COC1C2CC3CC(C2)CC1C3 ; *C(C)OC1CC2CC1C1CCCC21 ; *C(OC1CC2CC1C1CCCC21)C(C)C]

Of the acid labile groups having formula (L1), the cyclic ones are, for example, tetrahydrofuran-2-yl, 2-methyltetrahydrofuran-2-yl, tetrahydropyran-2-yl, and 2-methyltetrahydropyran-2-yl.

Examples of the acid labile group having formula (L2) include tert-butoxycarbonyl, tert-butoxycarbonylmethyl, tert-pentyloxycarbonyl, tert-pentyloxycarbonylmethyl, 1,1-diethylpropyloxycarbonyl, 1,1-diethylpropyloxycarbonylmethyl, 1-ethylcyclopentyloxycarbonyl, 1-ethylcyclopentyloxycarbonylmethyl, 1-ethyl-2-cyclopentenyloxycarbonyl, 1-ethyl-2-cyclopentenyloxycarbonylmethyl, 1-ethoxyethoxycarbonylmethyl, 2-tetrahydropyranyloxycarbonylmethyl, and 2-tetrahydrofuranyloxycarbonylmethyl groups.

Examples of the acid labile group having formula (L3) include 1-methylcyclopentyl, 1-ethylcyclopentyl, 1-n-propylcyclopentyl, 1-isopropylcyclopentyl, 1-n-butylcyclopentyl, 1-sec-butylcyclopentyl, 1-cyclohexylcyclopentyl, 1-(4-methoxy-n-butyl)cyclopentyl, 1-methylcyclohexyl, 1-ethylcyclohexyl, 3-methyl-1-cyclopenten-3-yl, 3-ethyl-1-cyclopenten-3-yl, 3-methyl-1-cyclohexen-3-yl, and 3-ethyl-1-cyclohexen-3-yl groups.

Of the acid labile groups having formula (L4), groups having the following formulae (L4-1) to (L4-4) are preferred.

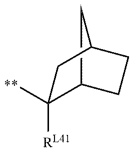

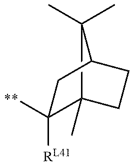

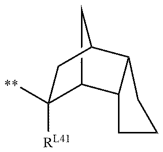

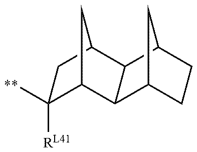

In formulae (L4-1) to (L4-4), the double asterisks (**) denotes a bonding site and direction. R^{L41} is each independently a C₁-C₁₀ hydrocarbyl group. The hydrocarbyl group may be saturated or unsaturated and straight, branched or cyclic, with saturated hydrocarbyl groups being preferred. Suitable hydrocarbyl groups include alkyl groups such as methyl, ethyl, propyl, isopropyl, n-butyl, sec-butyl, tert-butyl, tert-pentyl, n-pentyl, and n-hexyl, and cyclic saturated hydrocarbyl groups such as cyclopentyl and cyclohexyl.

For formulae (L4-1) to (L4-4), there can exist stereoisomers (enantiomers or diastereomers). Each of formulae (L4-1) to (L4-4) collectively represents all such stereoisomers. When the acid labile group is of formula (L4), there may be contained a plurality of stereoisomers.

For example, the formula (L4-3) represents one or a mixture of two selected from groups having the following formulae (L4-3-1) and (L4-3-2).

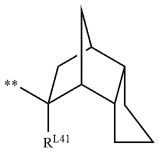

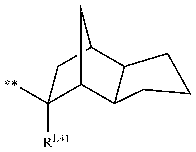

Herein R^{L41} and double asterisks (**) are as defined above.

Similarly, the formula (L4-4) represents one or a mixture of two or more selected from groups having the following formulae (L4-4-1) to (L4-4-4).

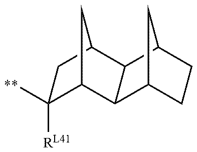

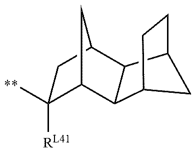

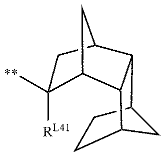

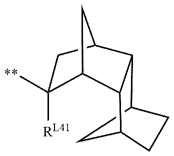

Herein R^{L41} and double asterisks (**) are as defined above.

Each of formulae (L4-1) to (L4-4), (LA-3-1), (L4-3-2), and (L4-4-1) to (L4-4-4) collectively represents an enantiomer thereof and a mixture of enantiomers.

It is noted that in the above formulae (L4-1) to (L4-4), (L4-3-1), (L4-3-2), and (L4-4-1) to (L4-4-4), the bond direction is on the exo side relative to the bicyclo[2.2.1]heptane ring, which ensures high reactivity for acid catalyzed elimination reaction (see JP-A 2000-336121). In preparing these monomers having a tertiary exo-saturated hydrocarbyl group of bicyclo[2.2.1]heptane skeleton as a substituent group, there may be contained monomers substituted with an endo-alkyl group as represented by the following formulae (L4-1-endo) to (LA-4-endo). For good reactivity, an exo proportion of at least 50 mol% is preferred, with an exo proportion of at least 80 mol% being more preferred.

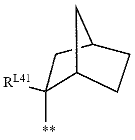

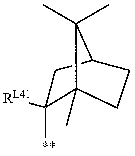

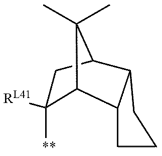

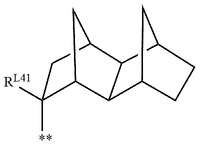

Herein R^{L41} and double asterisks (**) are as defined above.

Illustrative examples of the acid labile group having formula (L4) are given below, but not limited thereto.

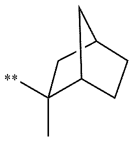

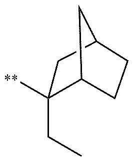

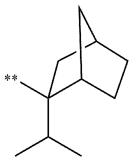

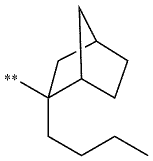

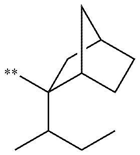

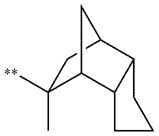

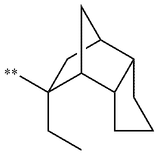

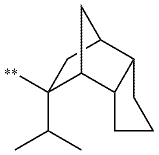

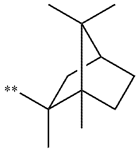

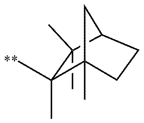

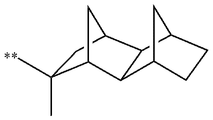

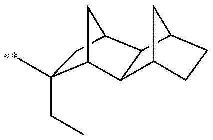

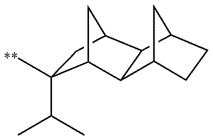

Herein double asterisks (**) is as defined above.

Of the acid labile groups represented by AL¹ and AL², examples of the C₄-C₂₀ tertiary hydrocarbyl groups, trialkylsilyl groups in which each alkyl moiety has 1 to 6 carbon atoms, and C₄-C₂₀ saturated hydrocarbyl groups containing carbonyl, ether bond or ester bond are as exemplified above for R^{L04}.

Illustrative examples of the repeat units (a1) are given below, but not limited thereto. Herein R^{A} is as defined above.

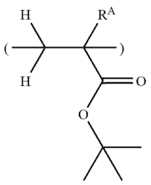

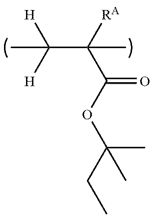

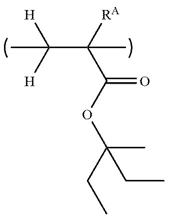

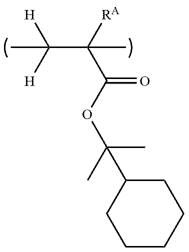

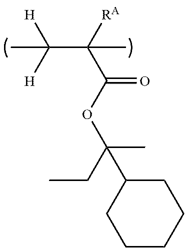

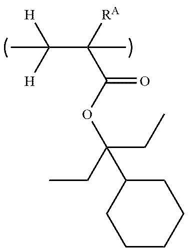

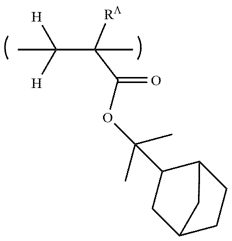

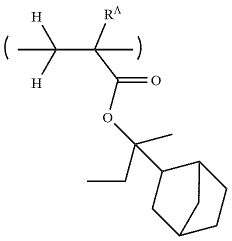

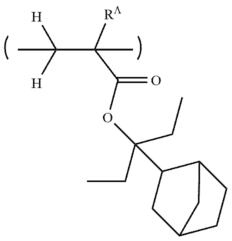

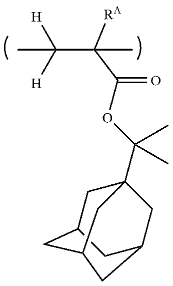

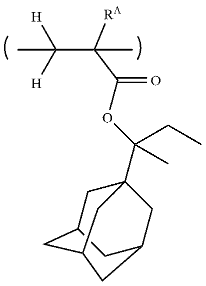

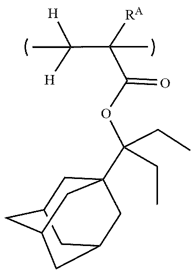

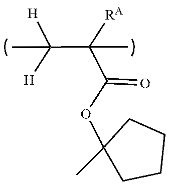

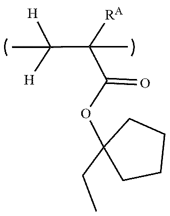

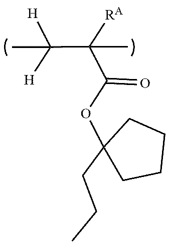

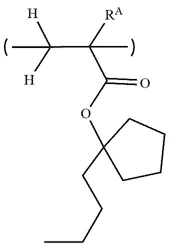

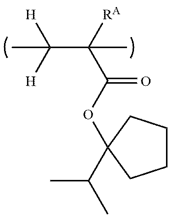

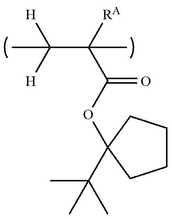

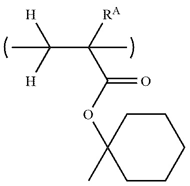

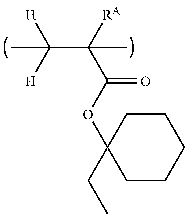

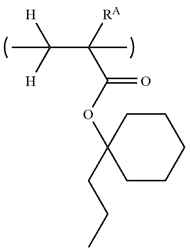

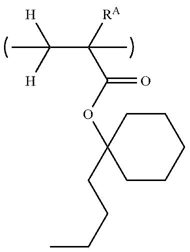

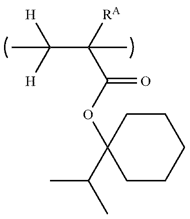

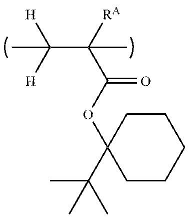

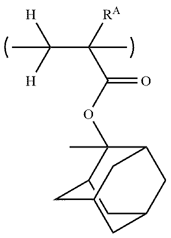

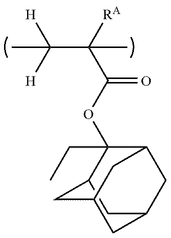

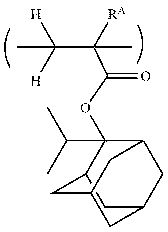

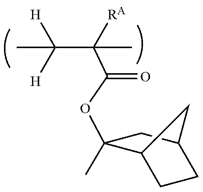

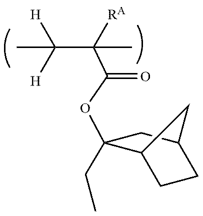

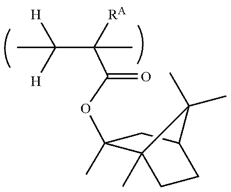

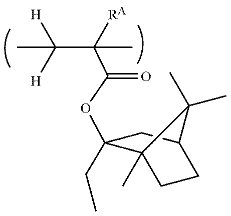

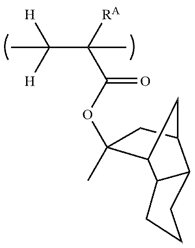

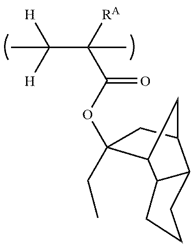

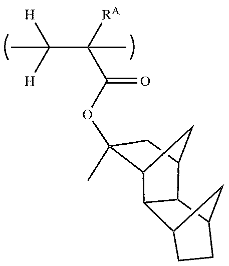

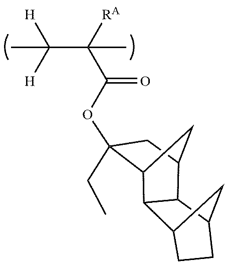

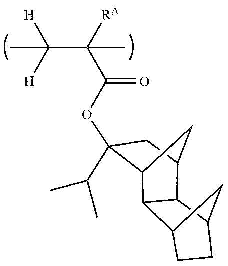

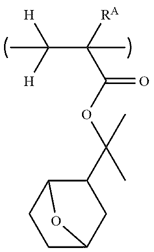

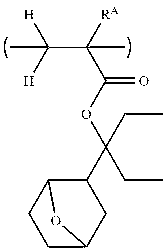

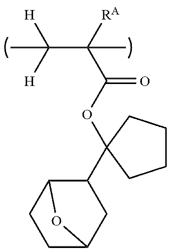

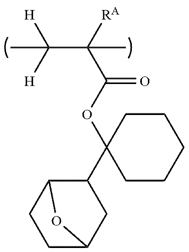

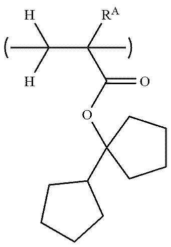

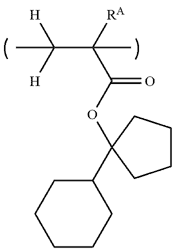

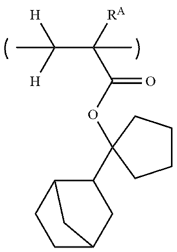

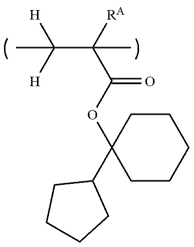

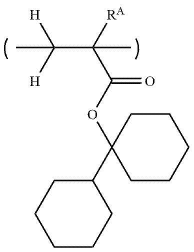

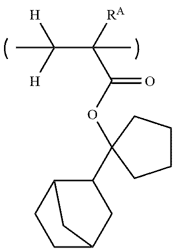

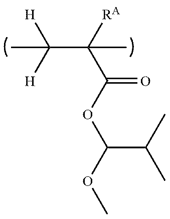

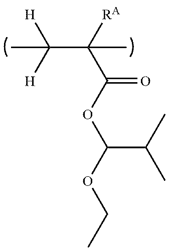

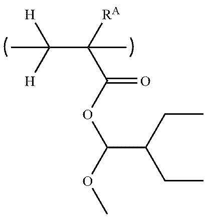

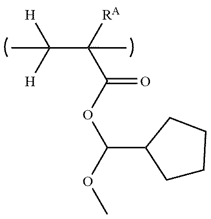

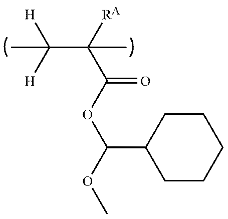

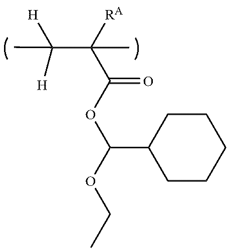

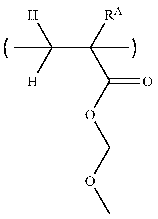

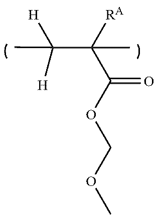

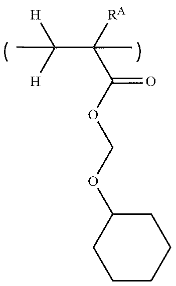

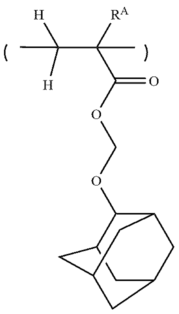

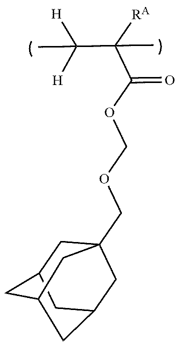

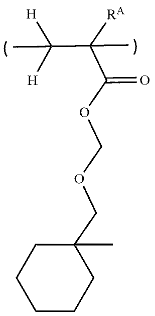

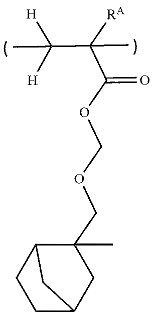

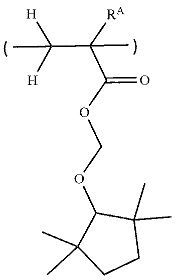

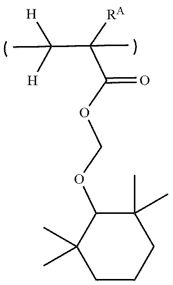

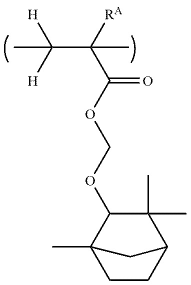

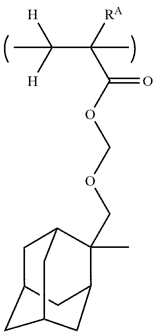

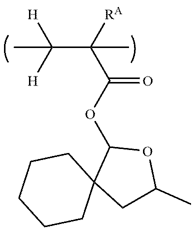

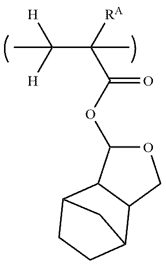

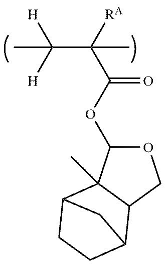

Like the repeat units (a1), a polymer comprising repeat units (a2) turns alkali soluble through the mechanism that it is decomposed to generate a hydroxy group under the action of acid. Illustrative examples of the repeat units (a2) are given below, but not limited thereto. Herein R^{A} is as defined above.

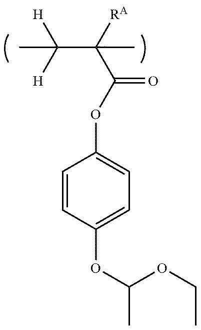

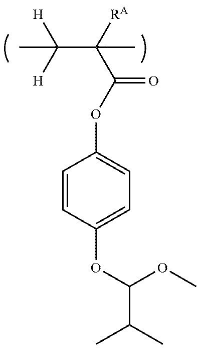

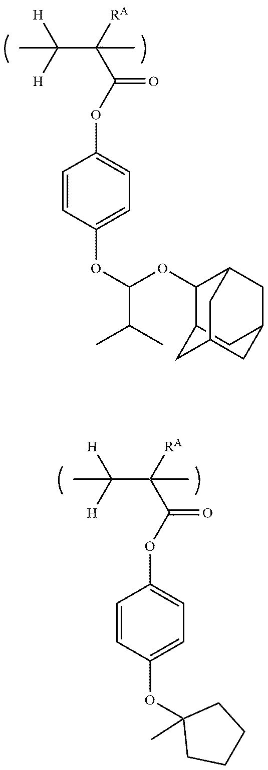

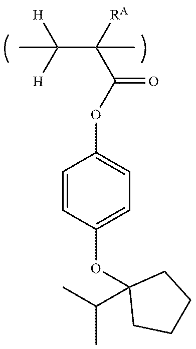

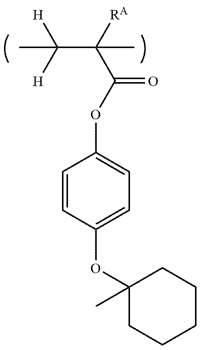

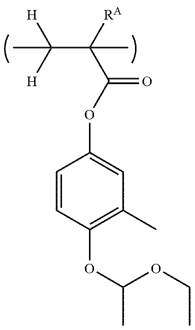

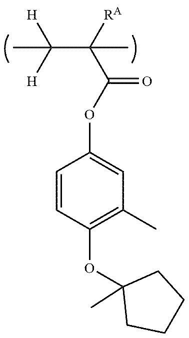

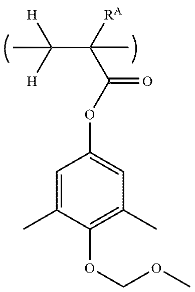

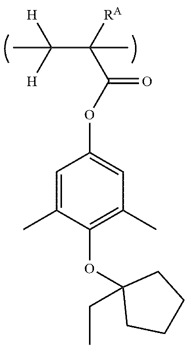

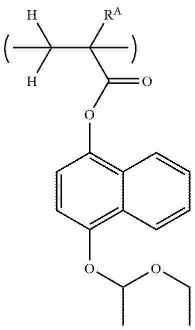

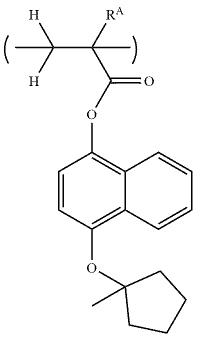

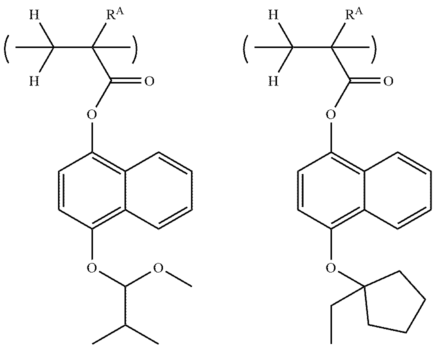

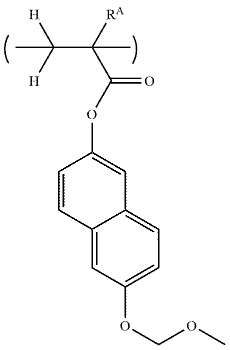

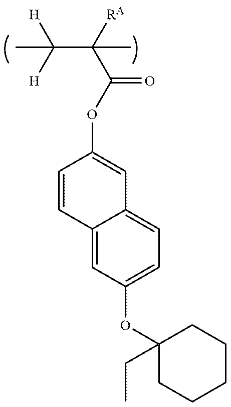

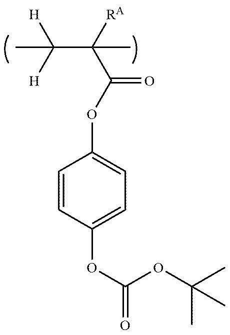

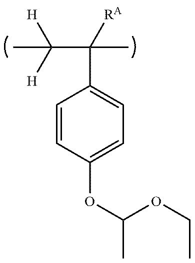

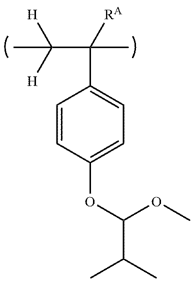

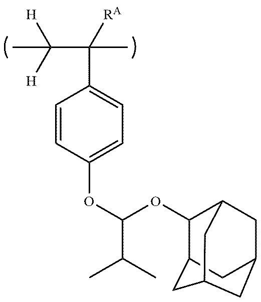

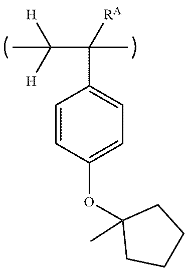

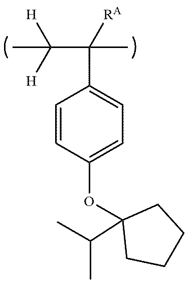

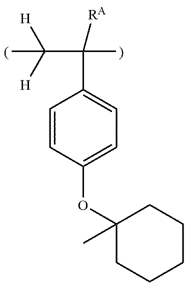

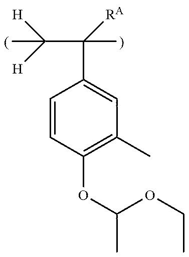

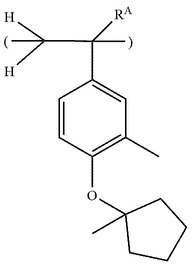

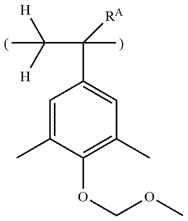

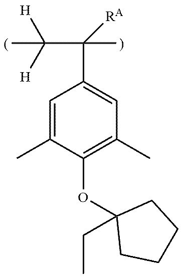

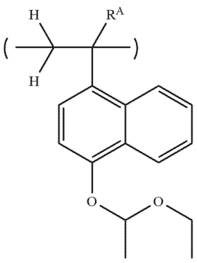

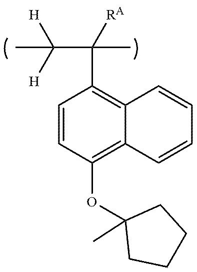

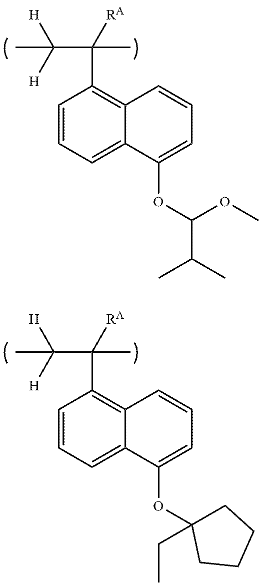

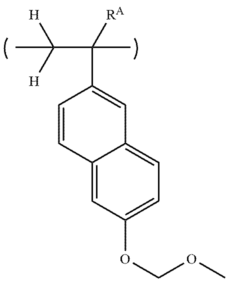

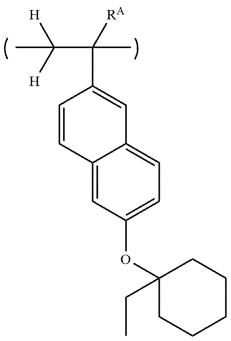

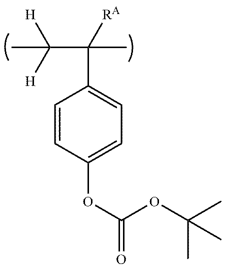

In a preferred embodiment, the polymer A further comprises repeat units having the formula (b1) or repeat units having the formula (b2), which are simply referred to as repeat units (b1) or (b2).

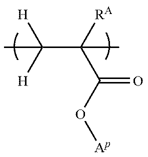

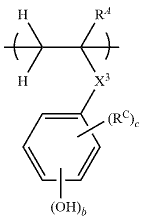

In formulae (b1) and (b2), R^{A} is each independently hydrogen, fluorine, methyl or trifluoromethyl. A^{P} is hydrogen or a polar group containing at least one structure selected from among hydroxy, cyano, carbonyl, carboxy, ether bond, ester bond, sulfonic ester bond, carbonate bond, lactone ring, sultone ring and carboxylic anhydride (—C(═O)—O—C(═O)—). X³ is a single bond or *—C(═O)—O—. The asterisk (*) designates a point of attachment to the carbon atom in the backbone. R^{C} is halogen, cyano, a C₁-C₂₀ hydrocarbyl group which may contain a heteroatom, C₁-C₂₀ hydrocarbyloxy group which may contain a heteroatom or C₂-C₂₀ hydrocarbylcarbonyl group which may contain a heteroatom. The subscript b is an integer of 1 to 4, c is an integer of 0 to 4, and the sum of b and c is from 1 to 5.

Examples of the repeat unit (b1) are shown below, but not limited thereto. Herein, R^{A} is as defined above.

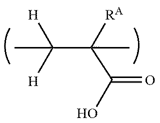

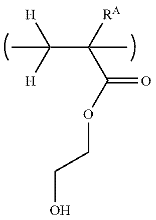

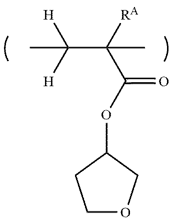

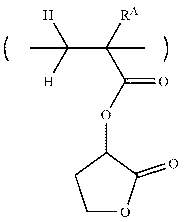

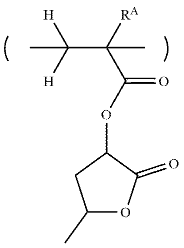

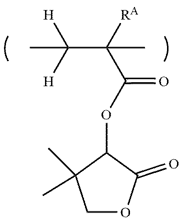

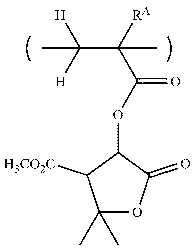

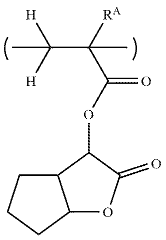

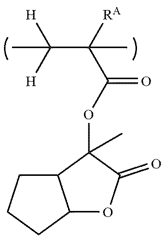

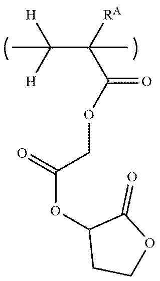

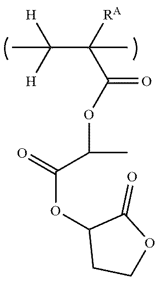

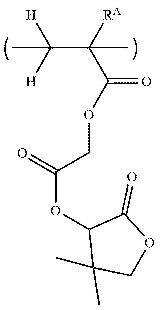

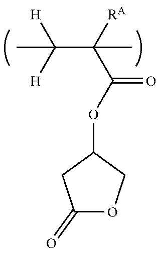

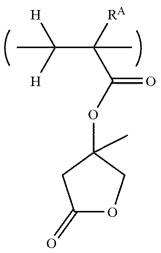

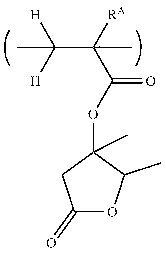

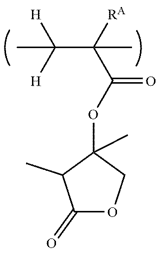

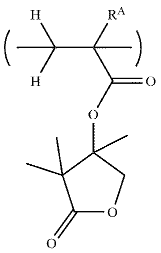

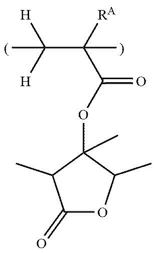

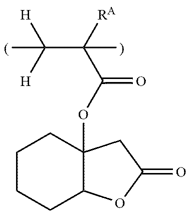

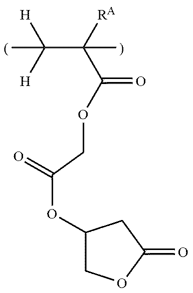

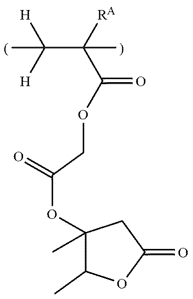

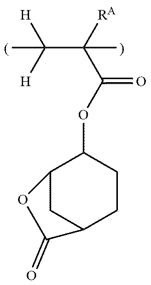

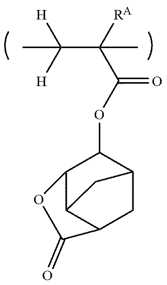

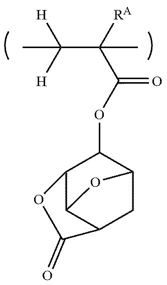

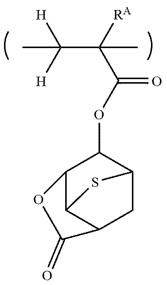

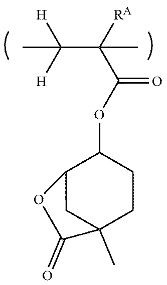

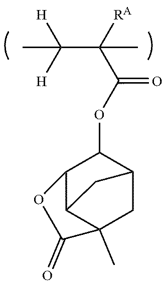

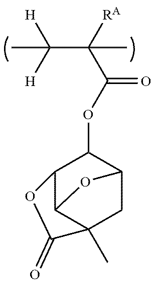

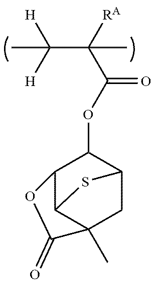

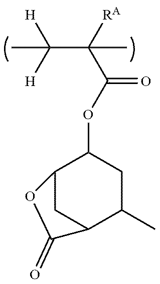

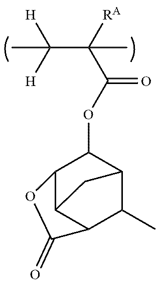

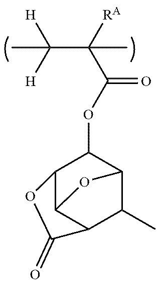

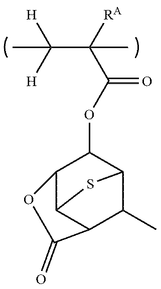

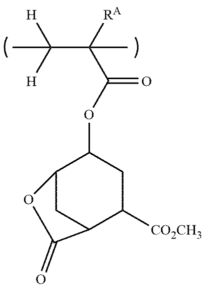

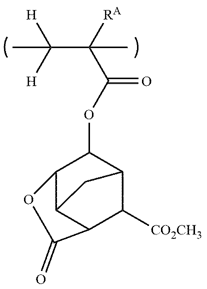

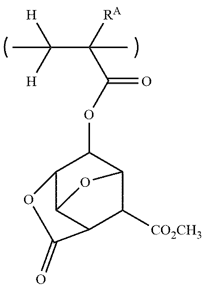

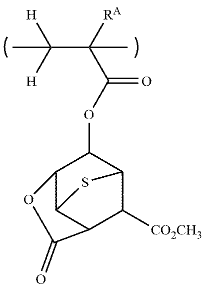

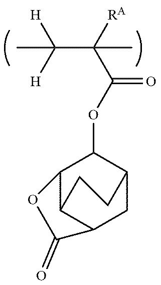

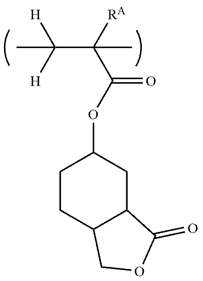

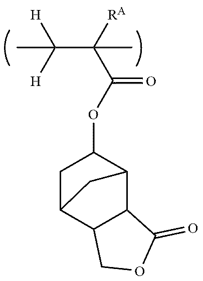

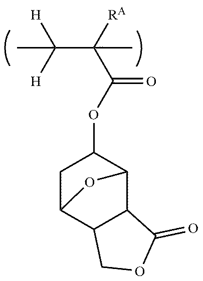

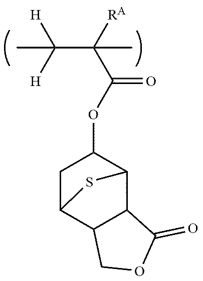

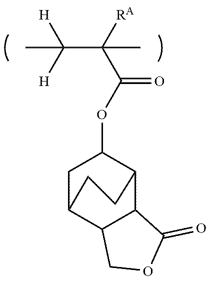

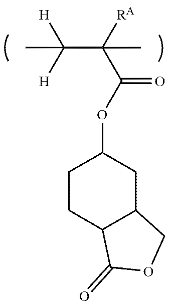

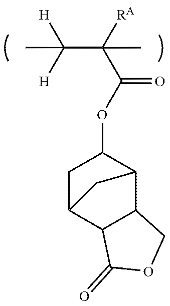

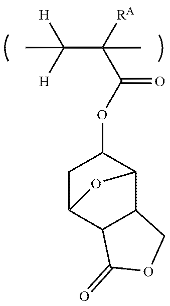

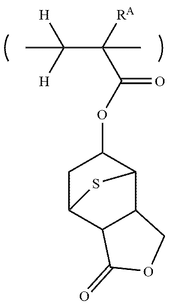

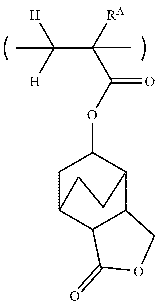

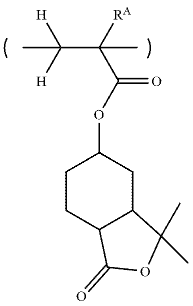

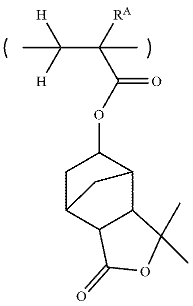

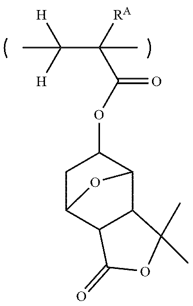

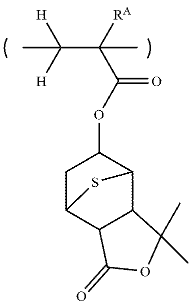

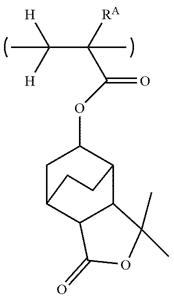

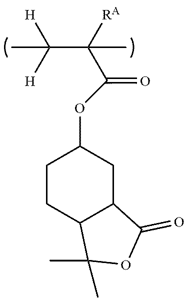

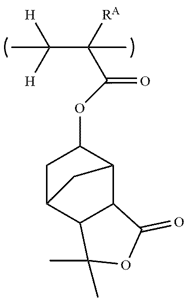

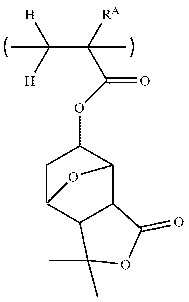

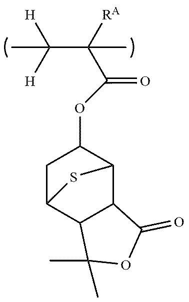

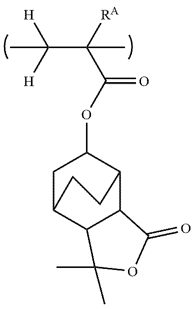

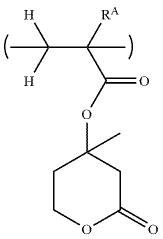

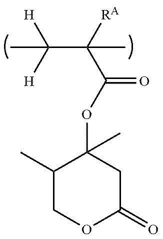

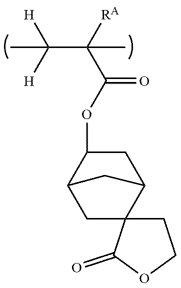

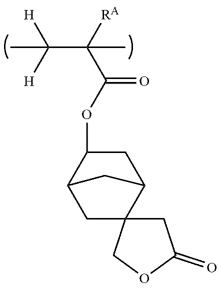

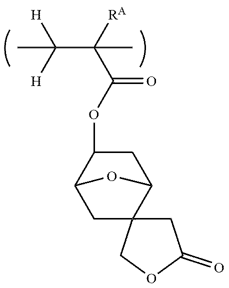

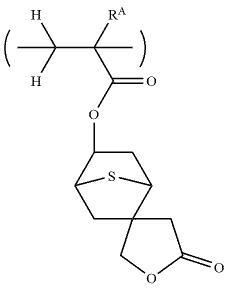

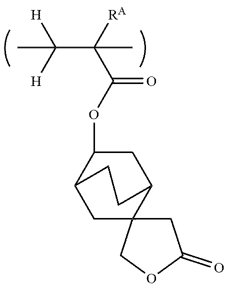

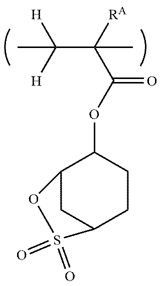

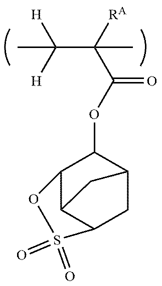

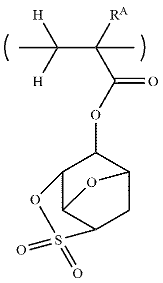

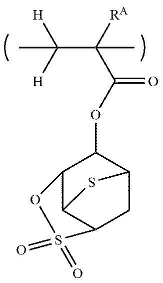

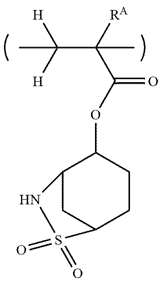

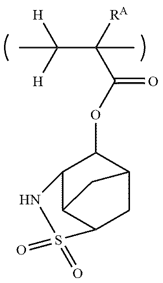

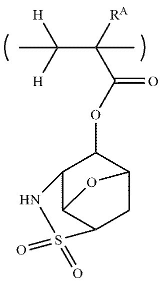

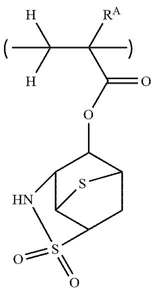

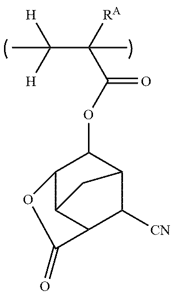

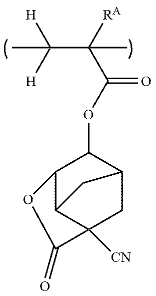

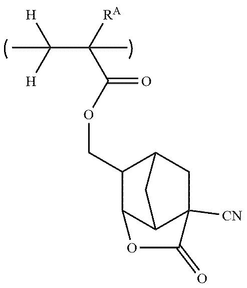

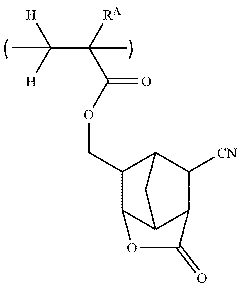

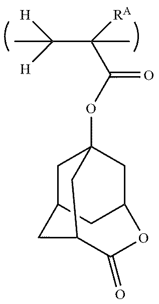

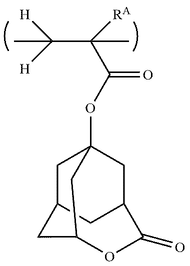

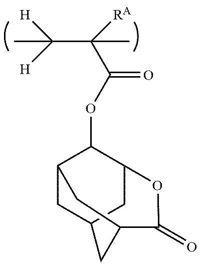

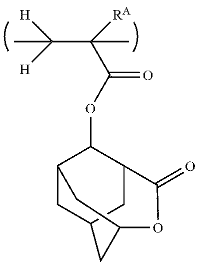

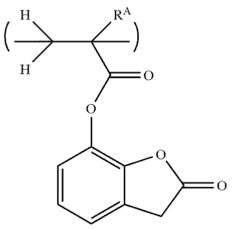

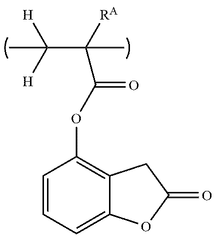

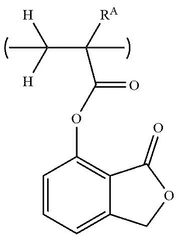

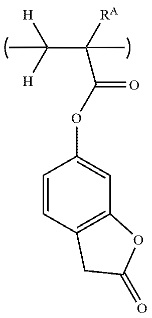

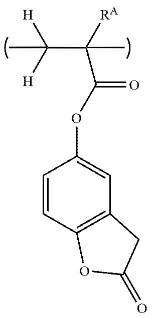

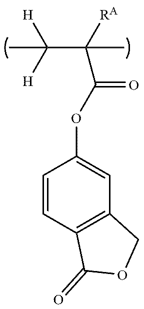

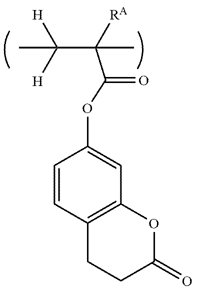

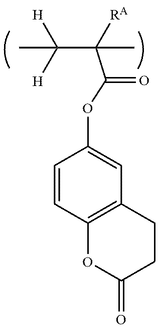

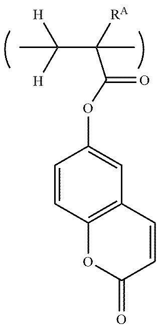

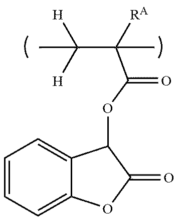

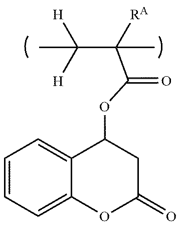

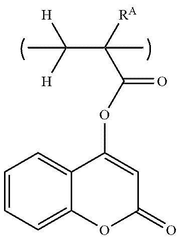

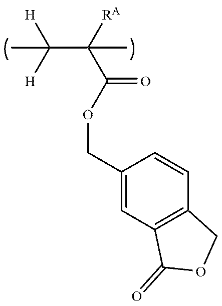

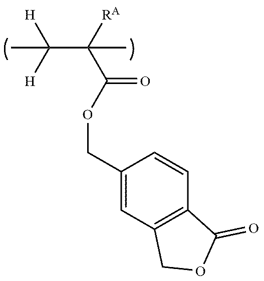

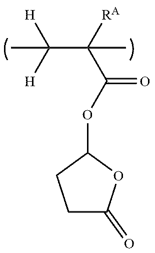

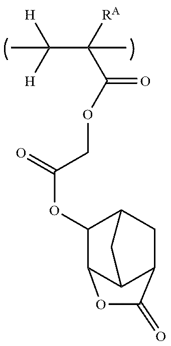

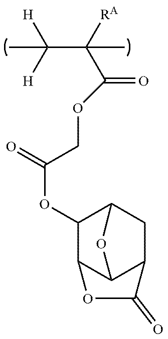

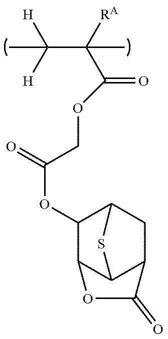

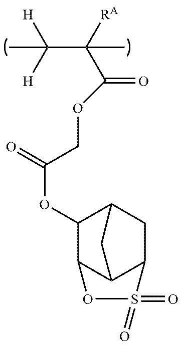

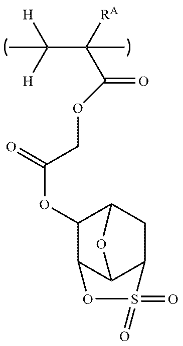

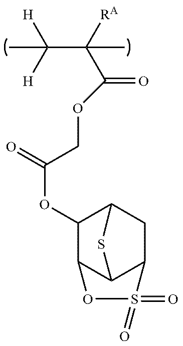

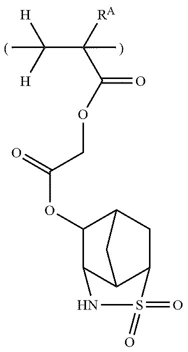

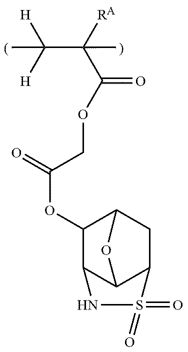

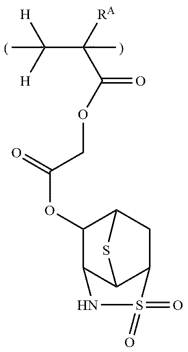

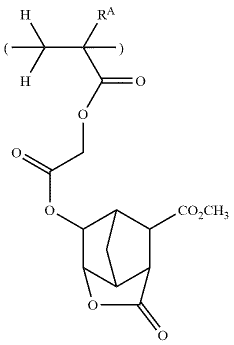

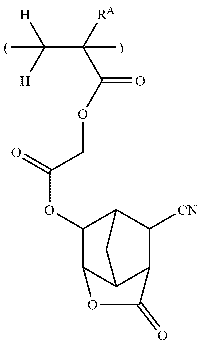

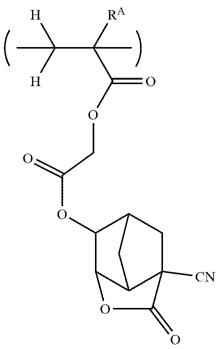

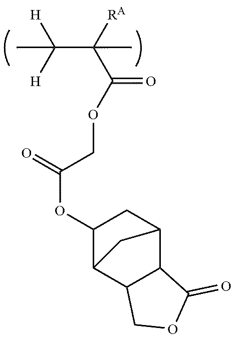

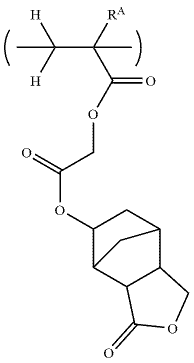

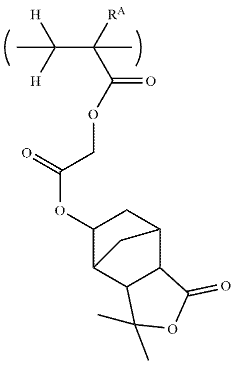

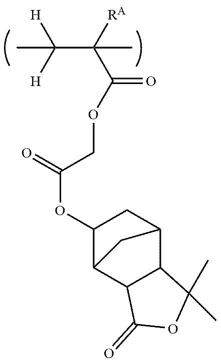

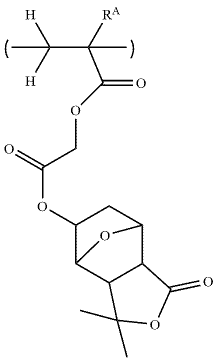

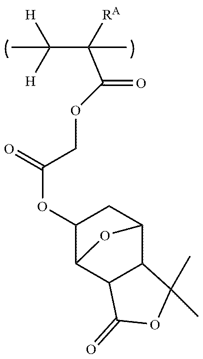

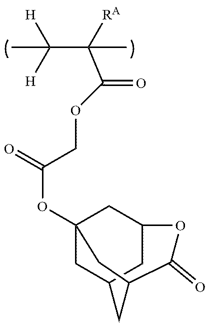

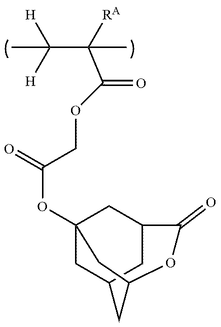

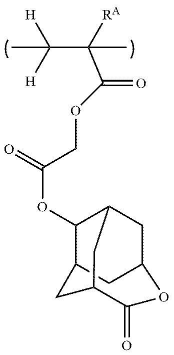

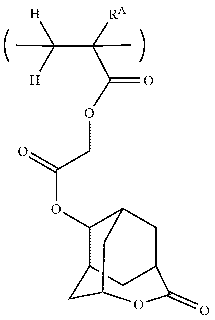

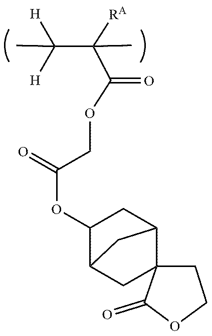

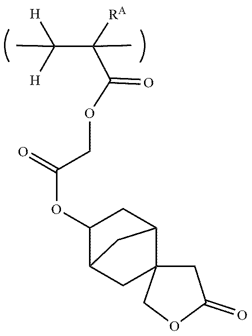

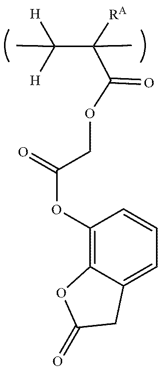

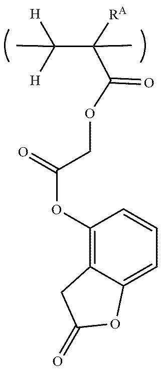

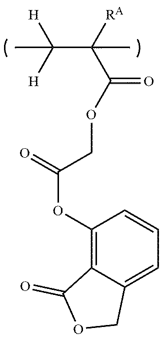

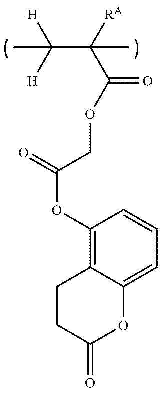

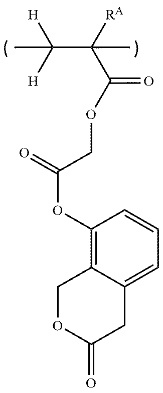

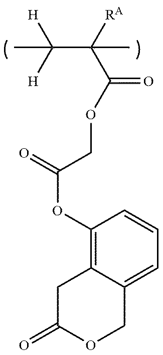

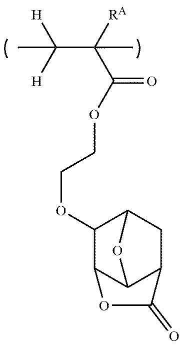

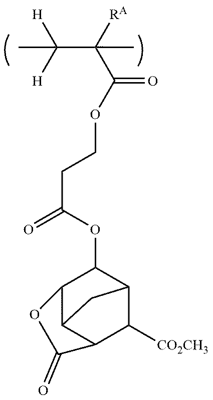

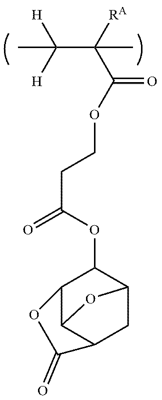

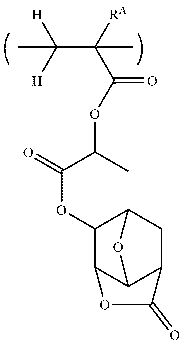

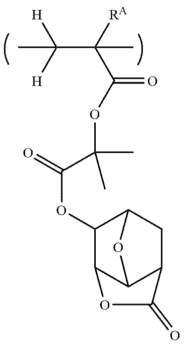

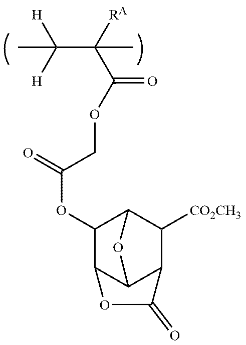

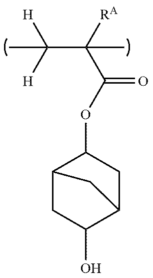

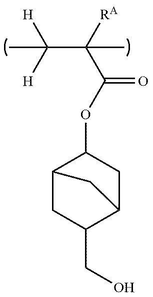

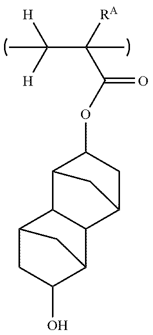

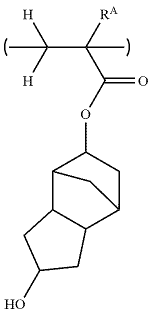

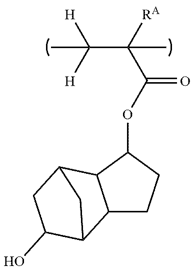

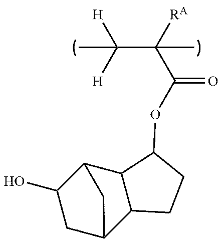

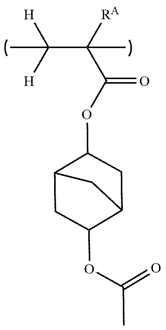

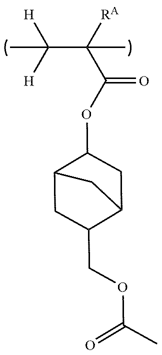

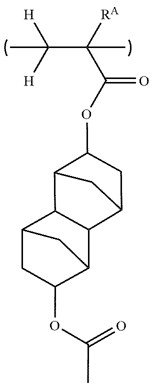

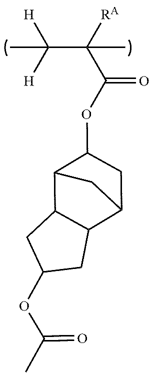

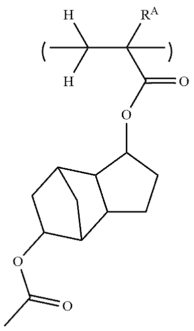

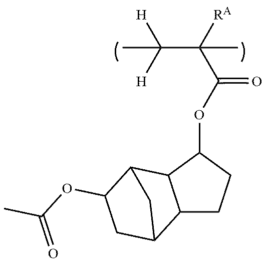

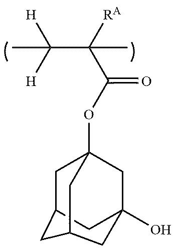

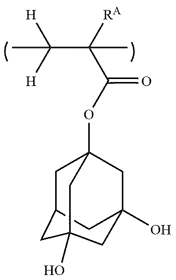

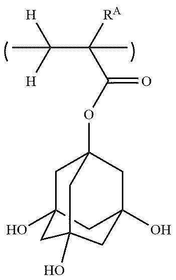

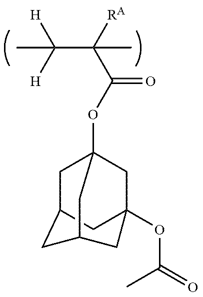

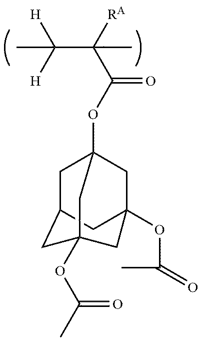

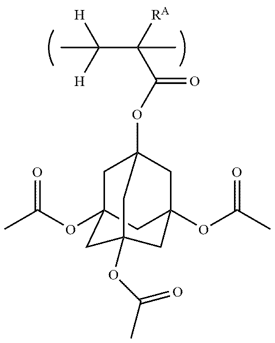

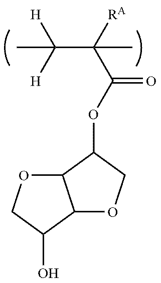

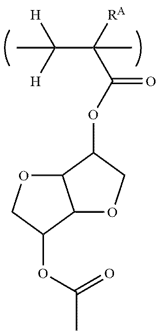

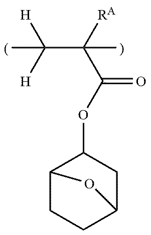

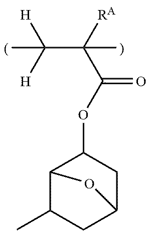

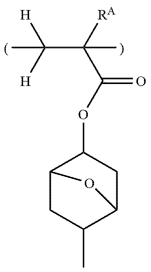

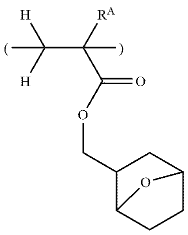

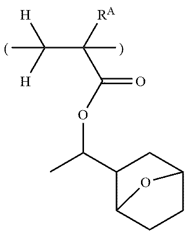

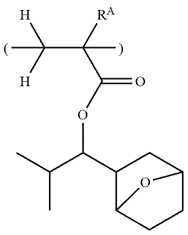

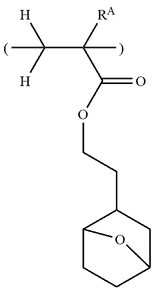

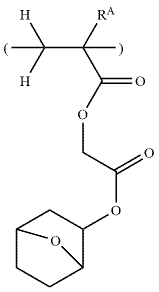

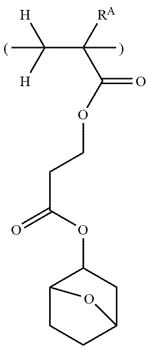

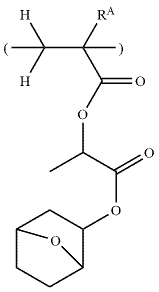

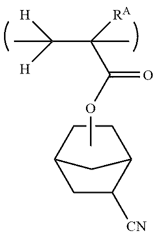

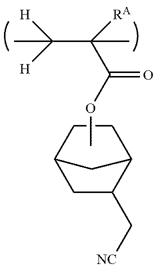

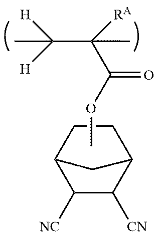

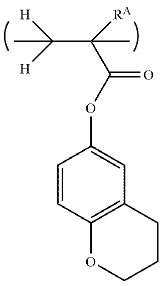

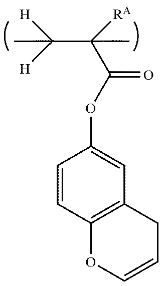

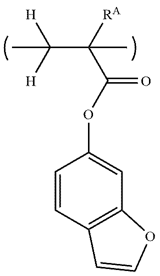

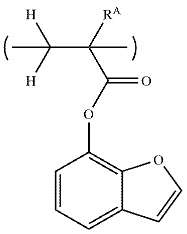

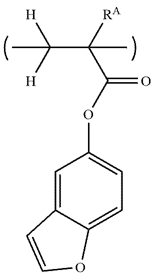

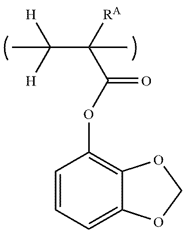

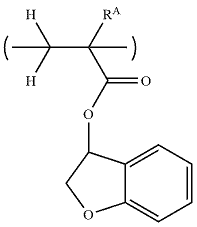

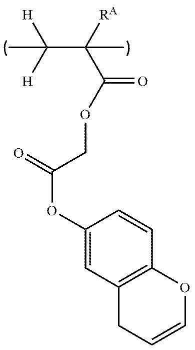

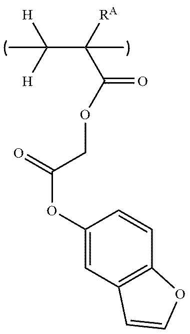

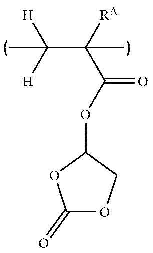

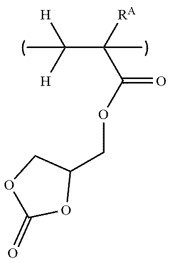

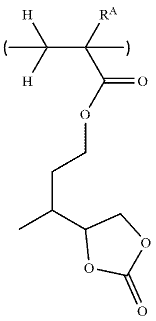

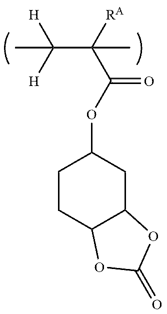

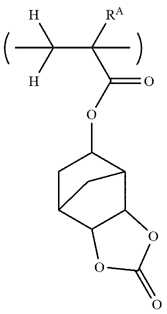

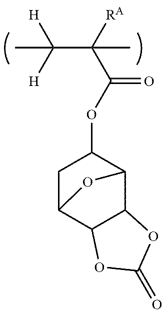

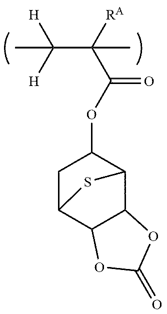

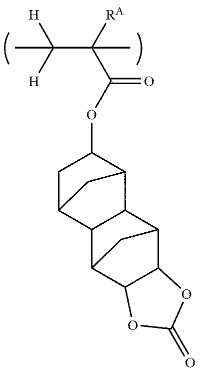

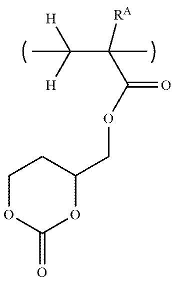

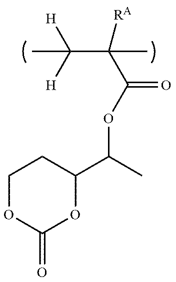

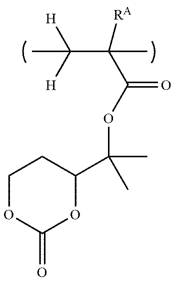

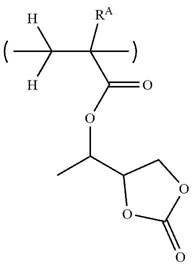

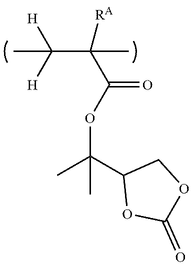

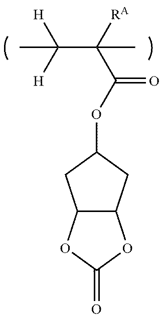

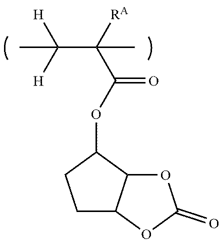

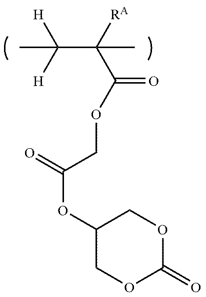

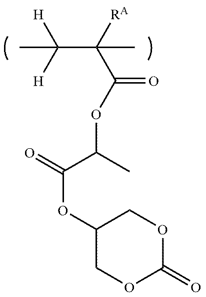

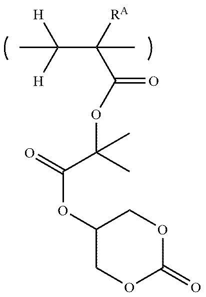

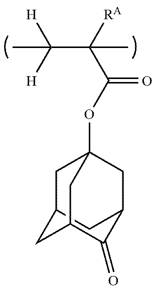

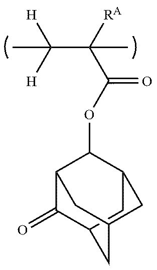

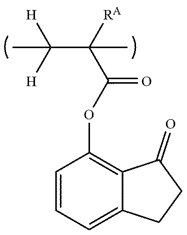

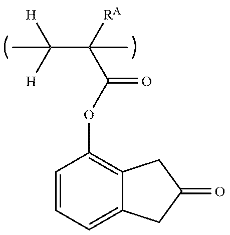

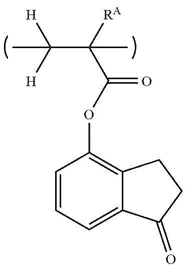

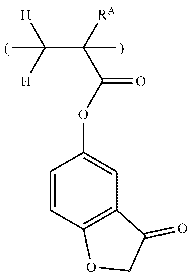

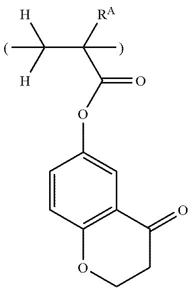

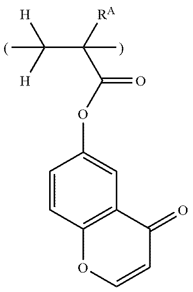

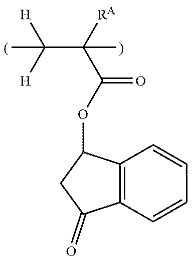

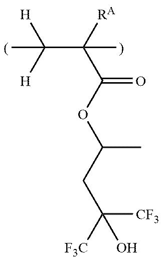

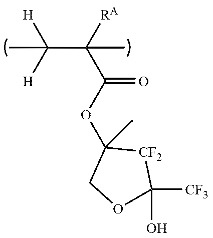

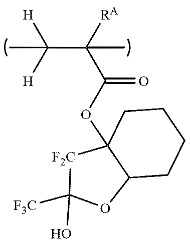

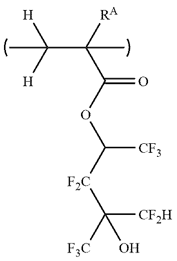

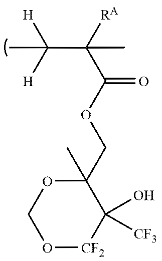

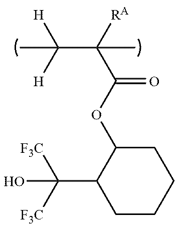

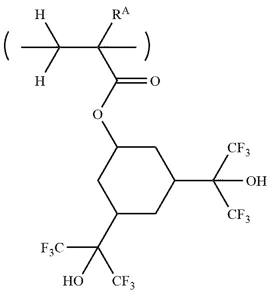

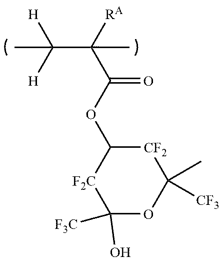

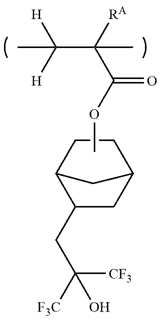

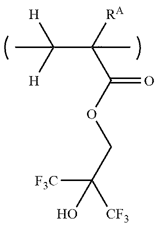

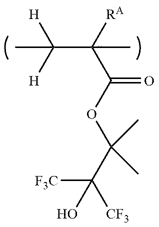

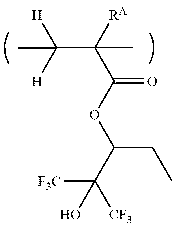

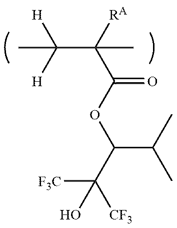

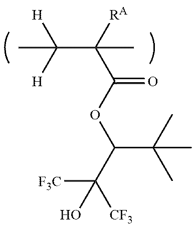

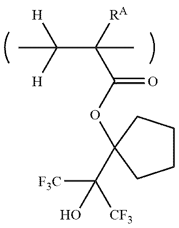

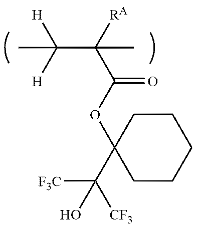

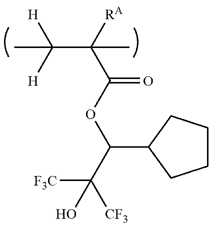

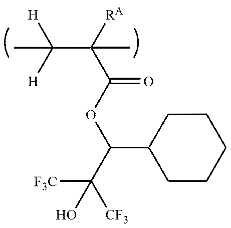

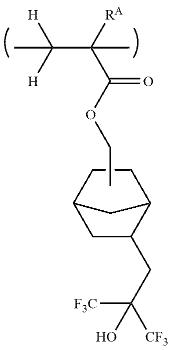

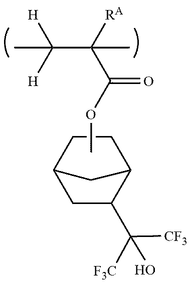

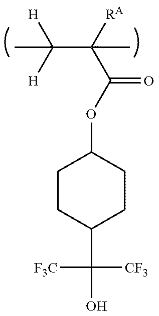

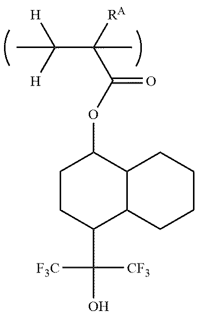

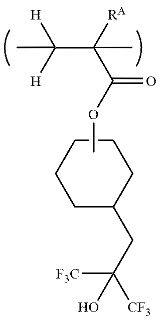

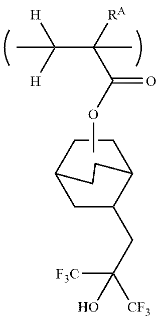

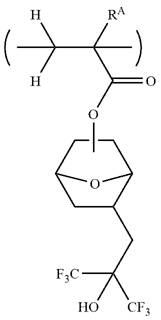

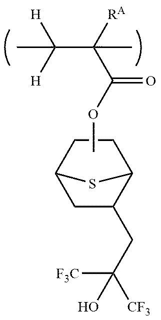

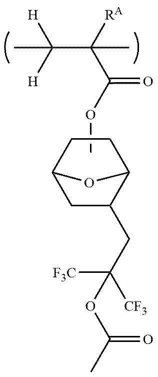

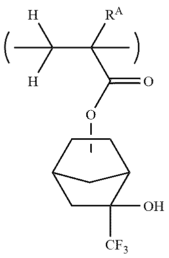

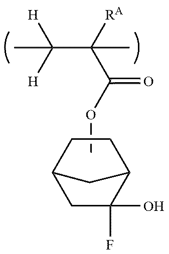

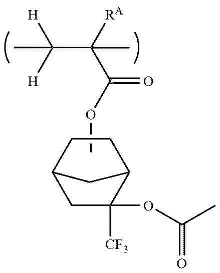

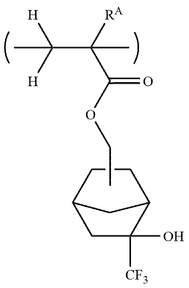

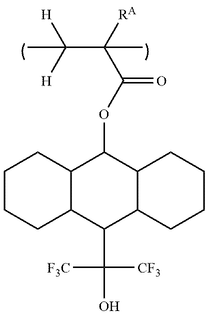

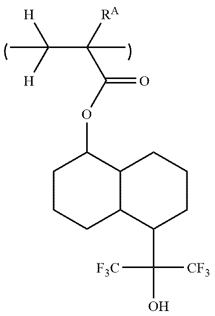

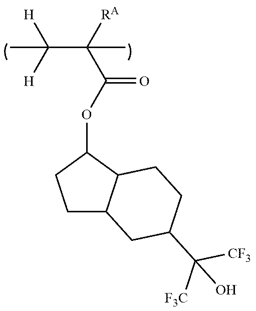

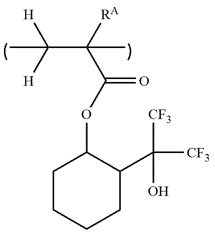

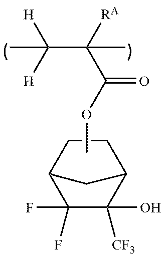

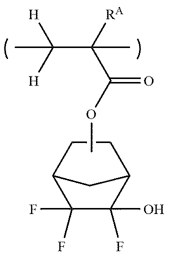

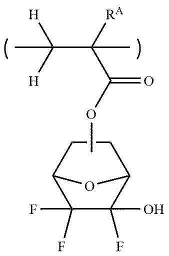

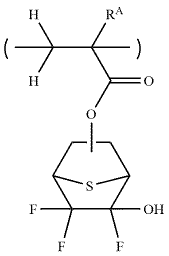

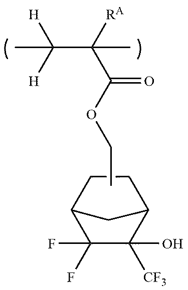

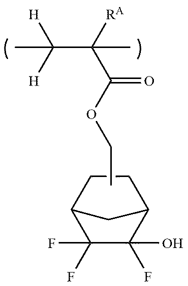

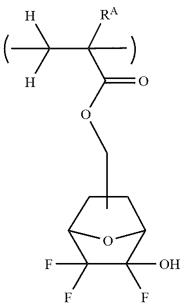

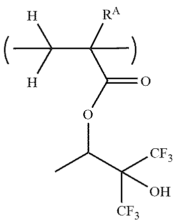

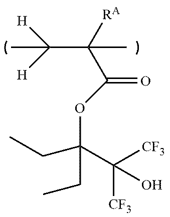

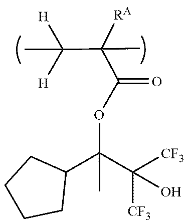

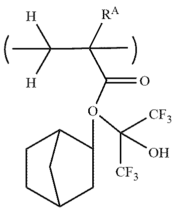

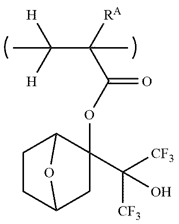

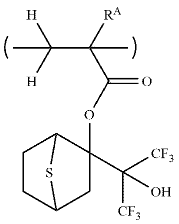

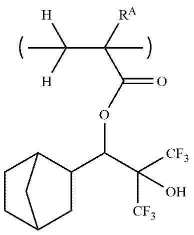

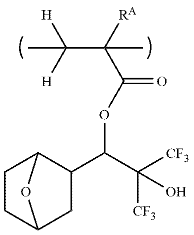

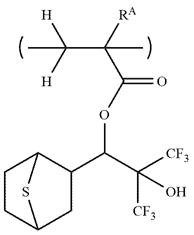

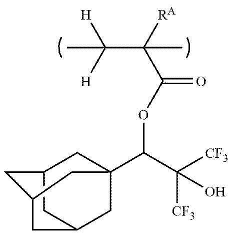

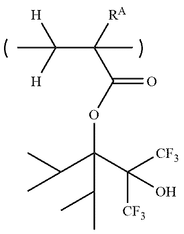

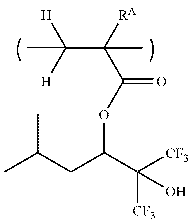

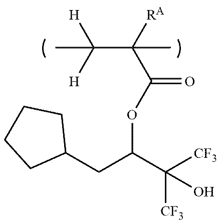

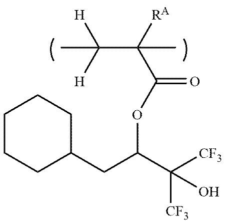

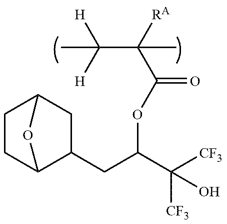

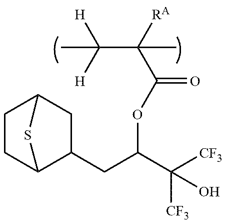

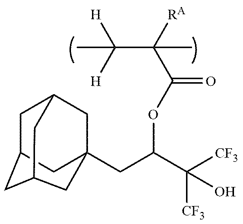

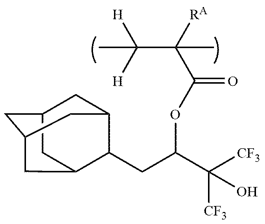

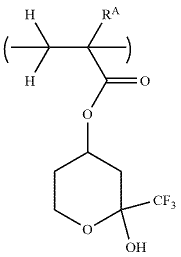

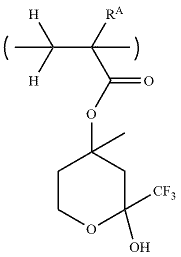

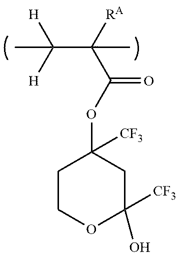

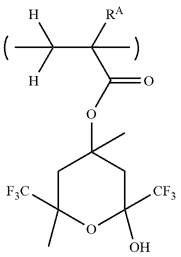

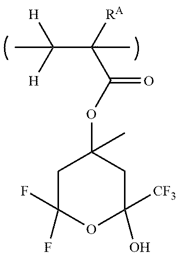

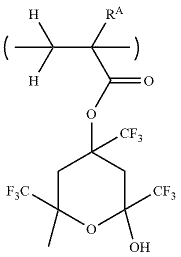

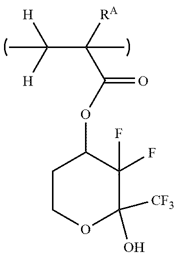

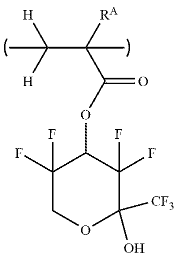

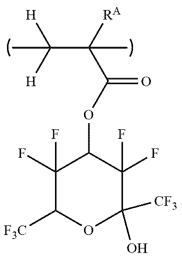

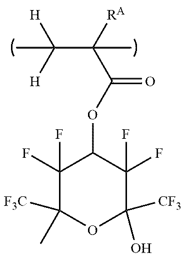

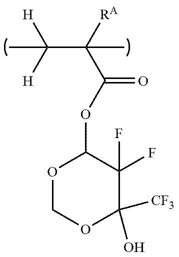

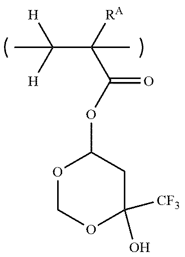

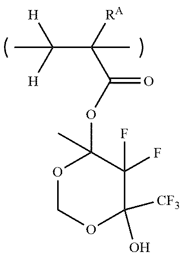

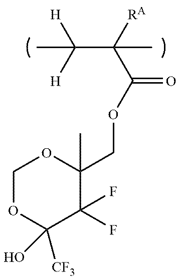

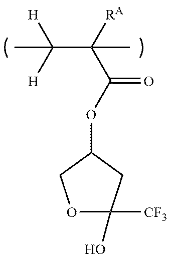

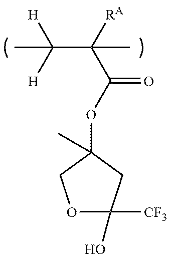

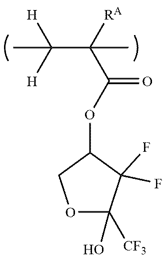

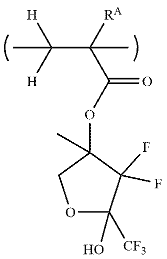

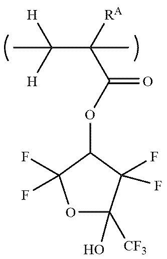

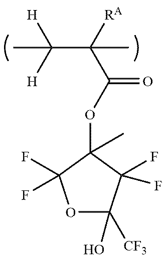

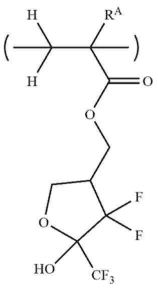

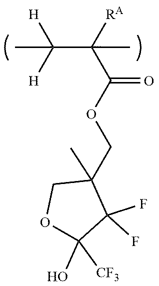

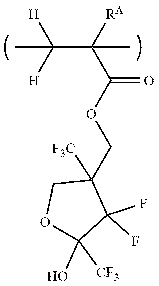

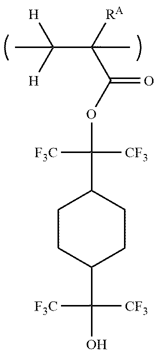

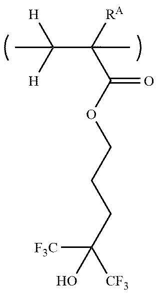

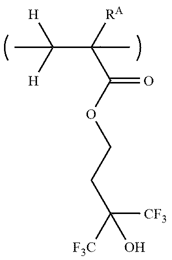

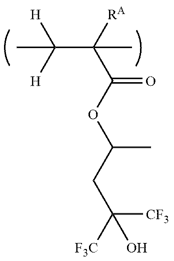

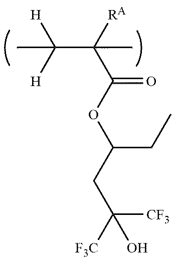

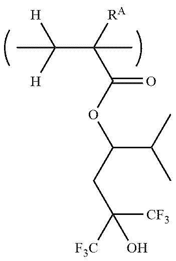

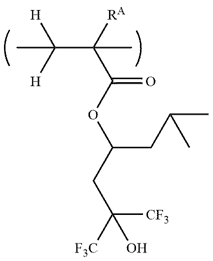

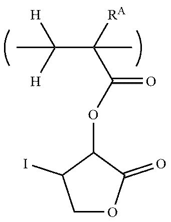

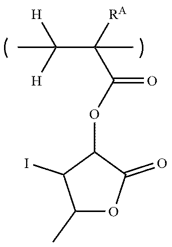

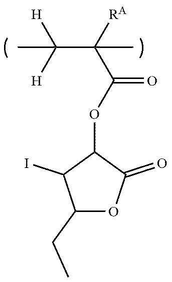

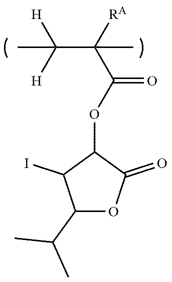

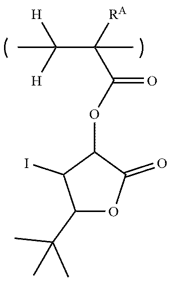

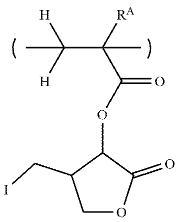

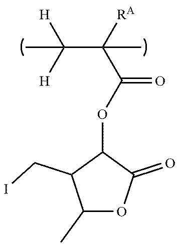

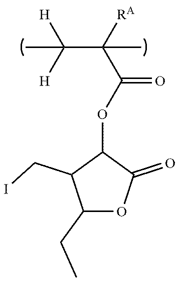

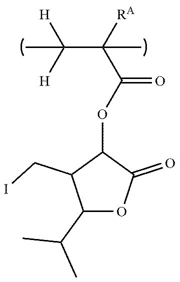

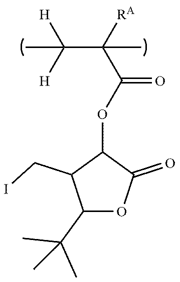

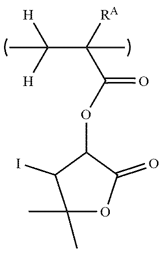

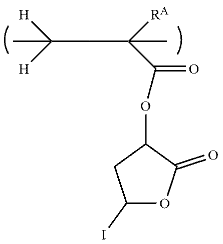

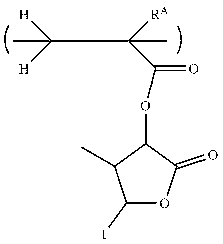

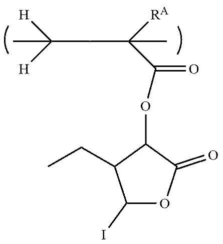

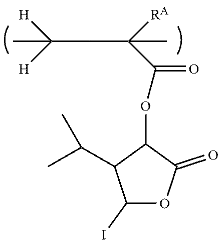

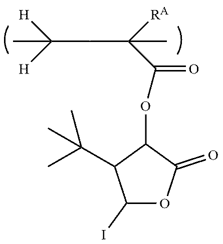

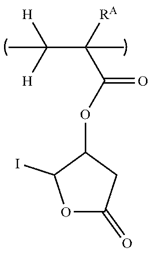

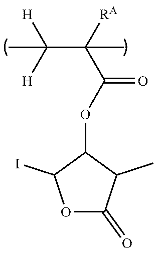

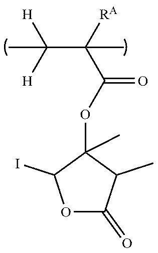

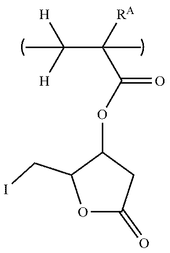

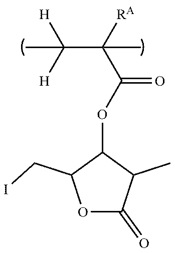

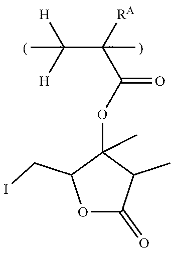

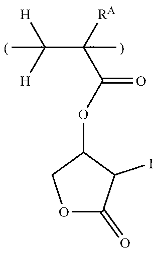

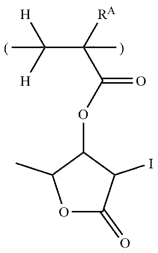

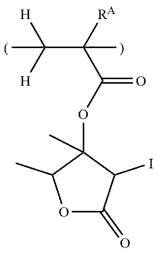

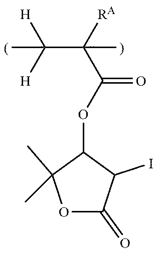

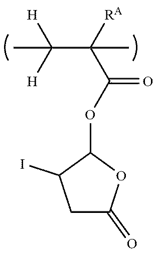

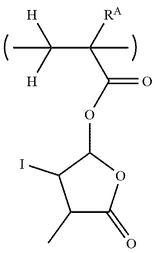

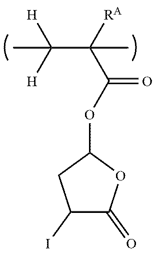

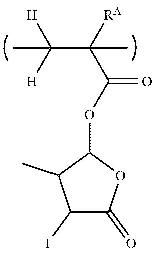

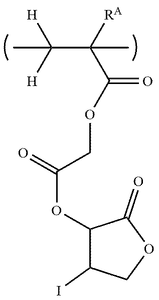

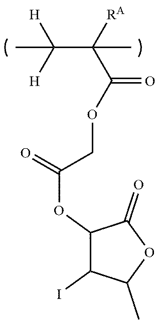

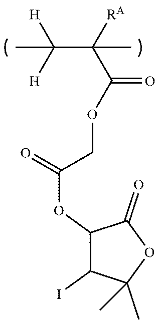

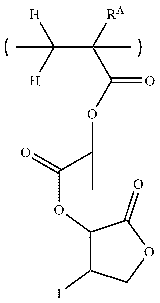

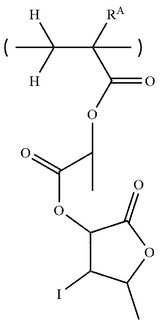

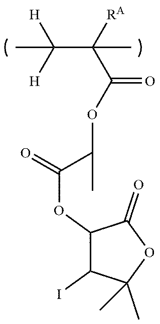

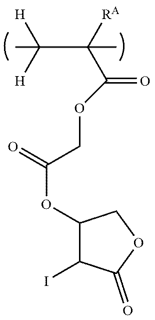

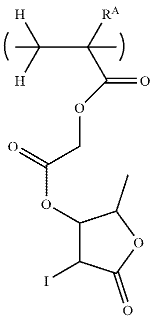

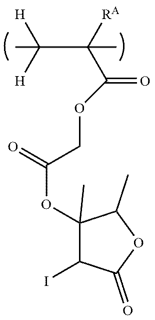

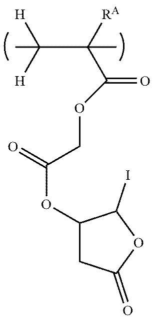

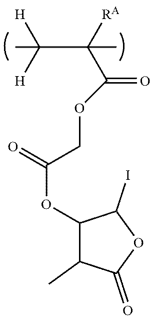

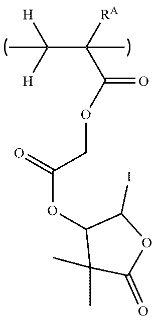

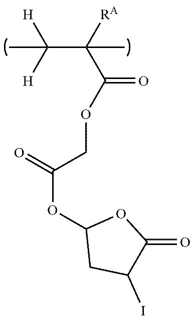

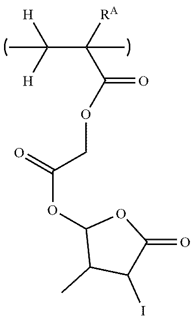

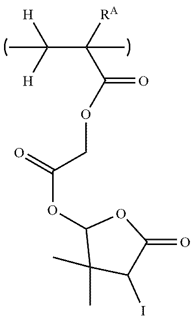

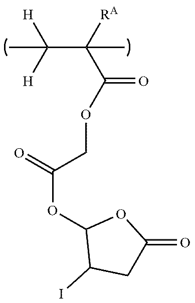

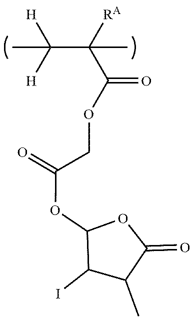

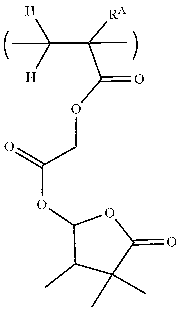

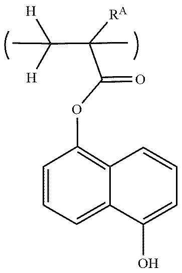

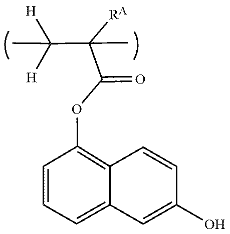

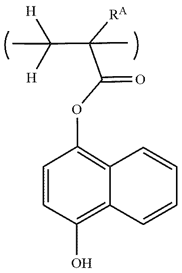

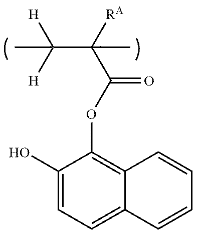

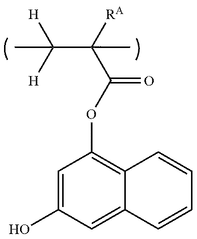

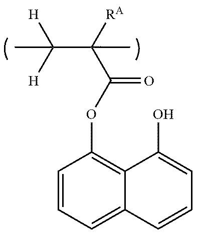

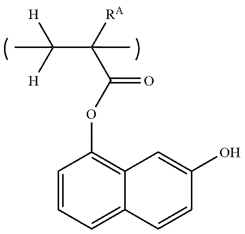

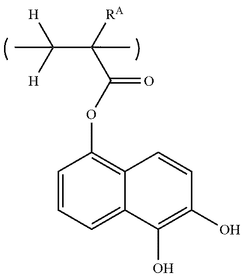

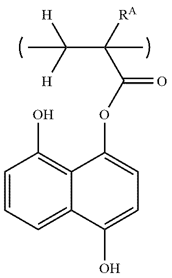

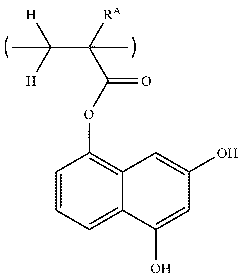

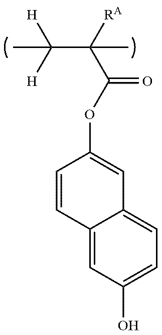

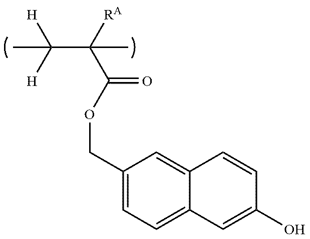

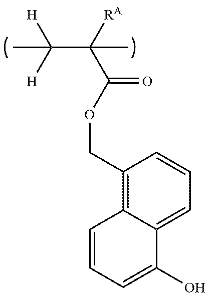

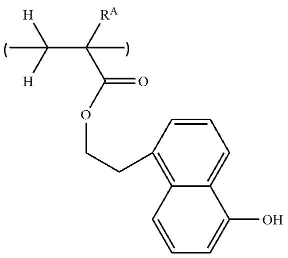

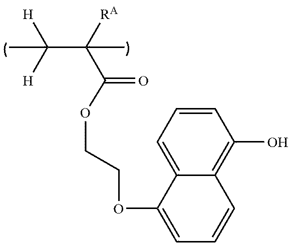

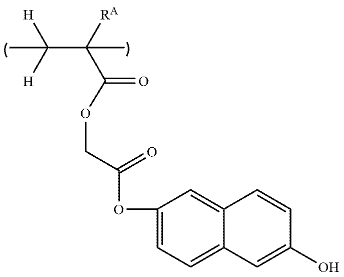

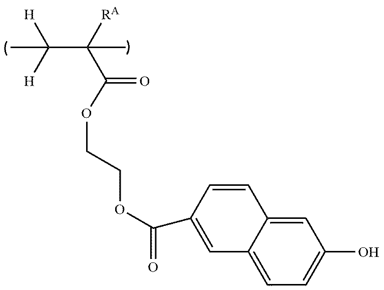

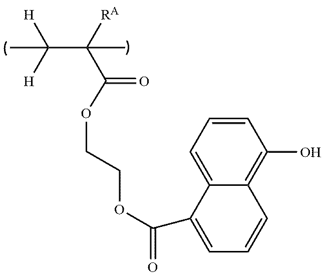

Examples of the repeat unit (b2) are shown below, but not limited thereto. Herein, R^{A} is as defined above.

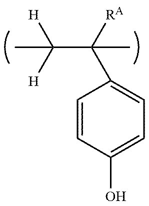

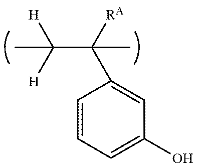

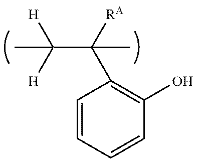

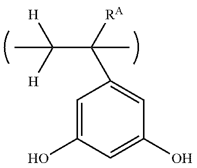

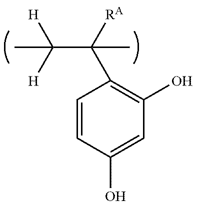

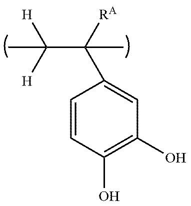

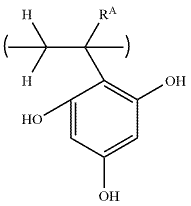

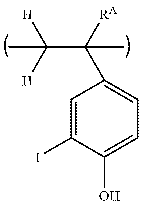

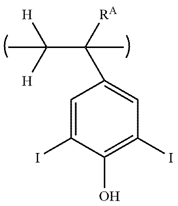

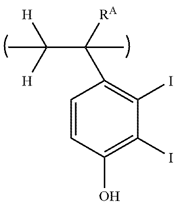

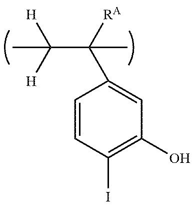

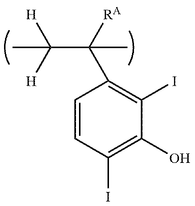

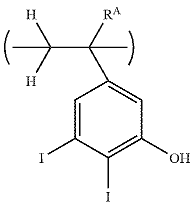

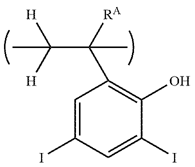

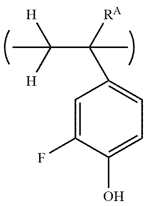

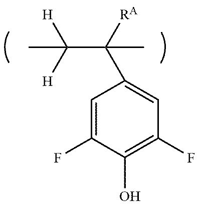

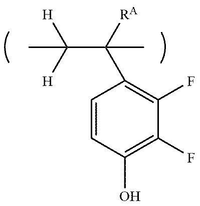

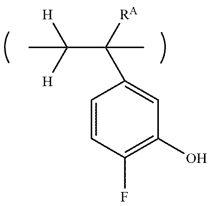

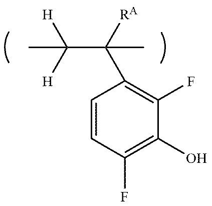

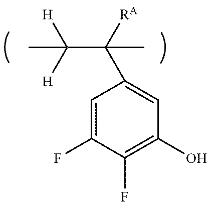

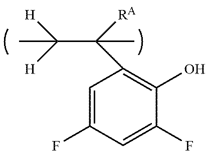

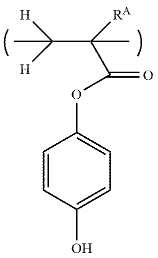

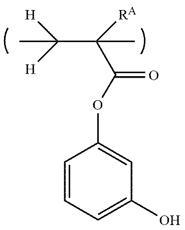

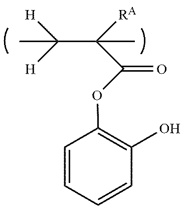

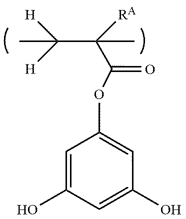

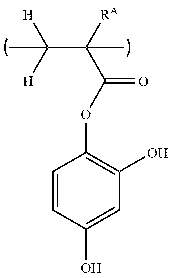

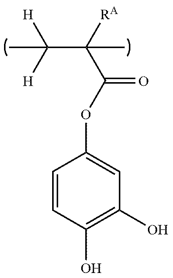

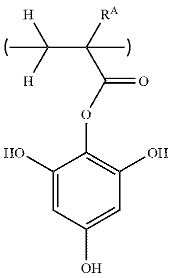

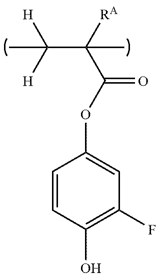

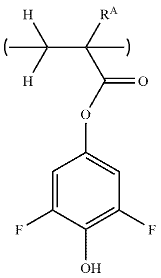

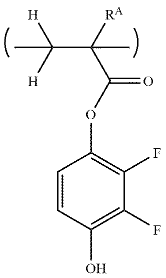

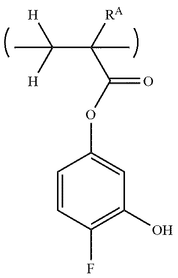

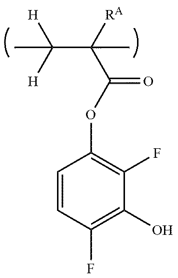

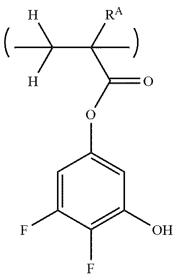

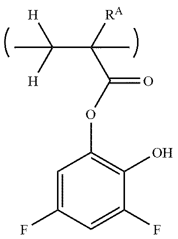

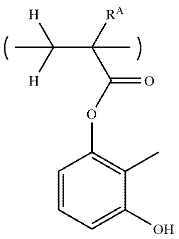

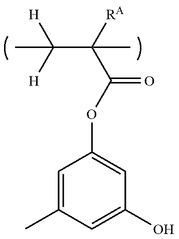

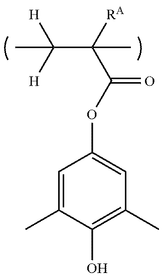

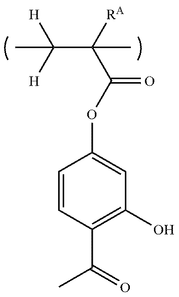

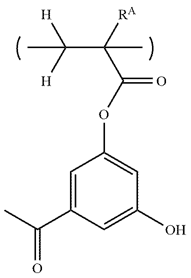

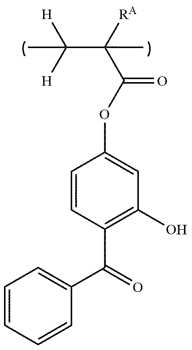

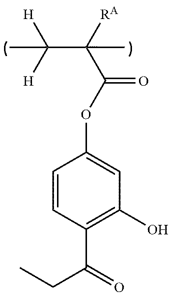

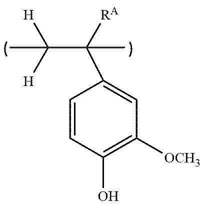

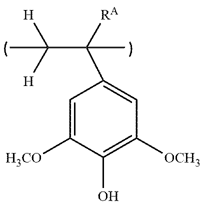

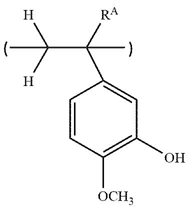

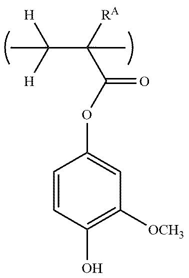

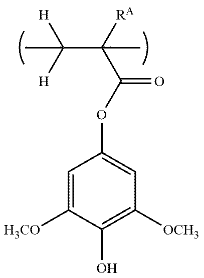

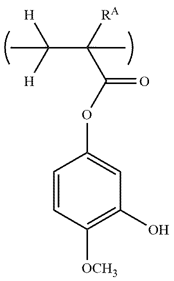

Of the repeat units (b1) and (b2), those units having a lactone ring as the polar group are preferred in the ArF lithography and those units having a phenolic site are preferred in the KrF, EB and EUV lithography.

In addition to the foregoing units, the polymer A may further comprise repeat units derived from other monomers, for example, substituted acrylic acid esters such as methyl methacrylate, methyl crotonate, dimethyl maleate and dimethyl itaconate, unsaturated carboxylic acids such as maleic acid, fumaric acid, and itaconic acid, cyclic olefins such as norbomene, norbomene derivatives, and tetracyclo[6.2. 1.1^{3,6}0.0^{2,7}]dodecene derivatives, and unsaturated acid anhydrides such as itaconic anhydride.

The polymer A preferably has a weight average molecular weight (Mw) of 1,000 to 500,000, and more preferably 3,000 to 100,000, as measured versus polystyrene standards by GPC using tetrahydrofuran (THF) solvent. The above range of Mw ensures satisfactory etch resistance and eliminates the risk of resolution being reduced due to difficulty to gain a dissolution rate difference before and after exposure.

If a polymer has a wide molecular weight distribution or dispersity (Mw/Mn), which indicates the presence of lower and higher molecular weight polymer fractions, there is a possibility that foreign matter is left on the pattern or the pattern profile is degraded. The influence of Mw/Mn becomes stronger as the pattern rule becomes finer. Therefore, the polymer A should preferably have a narrow dispersity (Mw/Mn) of 1.0 to 2.0 in order to provide a resist composition suitable for micropatterning to a small feature size.

The polymer A may be synthesized, for example, by dissolving a monomer or monomers corresponding to the above-mentioned repeat units in an organic solvent, adding a radical polymerization initiator, and heating for polymerization.

One exemplary method of synthesizing the polymer A is by dissolving one or more unsaturated bond-bearing monomers in an organic solvent, adding a radical initiator, and heating for polymerization. Examples of the organic solvent which can be used for polymerization include toluene, benzene, THF, diethyl ether, dioxane, cyclohexane, cyclopentane, methyl ethyl ketone (MEK), propylene glycol monomethyl ether acetate (PGMEA), and γ-butyrolactone (GBL). Examples of the polymerization initiator used herein include 2,2′-azobisisobutyronitrile (AIBN), 2,2′-azobis(2,4-dimethylvaleronitrile), dimethyl 2,2-azobis(2-methylpropionate), 1,1′-aiobis(1-acetoxy-1-phenylelhane), benzoyl peroxide, and lauroyl peroxide. The initiator is preferably added in an amount of 0.01 to 25 mol% based on the total of monomers to be polymerized. The reaction temperature is preferably 50 to 150° C., more preferably 60 to 100° C. The reaction time is preferably 2 to 24 hours, more preferably 2 to 12 hours in view of production efficiency.

The polymerization initiator may be fed to the reactor either by adding the initiator to the monomer solution and feeding the solution to the reactor, or by dissolving the initiator in a solvent to form an initiator solution and feeding the initiator solution and the monomer solution independently to the reactor. Because of a possibility that in the standby duration, the initiator generates a radical which triggers polymerization reaction to form a ultra-high-molecular-weight polymer, it is preferred from the standpoint of quality control to prepare the monomer solution and the initiator solution separately and add them dropwise. The acid labile group that has been incorporated in the monomer may be kept as such, or polymerization may be followed by protection or partial protection. During the polymer synthesis, any known chain transfer agent such as dodecyl mercaptan or 2-mercaptoethanol may be added for molecular weight control purpose. The amount of chain transfer agent added is preferably 0.01 to 20 mol% based on the total of monomers.

When hydroxystyrene or hydroxyvinylnaphthalene is copolymerized, one method is by dissolving hydroxystyrene or hydroxyvinylnaphthalene and other monomers in an organic solvent adding a radical polymerization initiator thereto, and heating the solution for polymerization. In an alternative method, acetoxystyrene or acetoxyvinylnaphthalene is used instead, and after polymerization, the acetoxy group is deprotected by alkaline hydrolysis, for thereby converting the polymer product to polyhydroxystyrene or polyhydroxyvinylnaphthalene. For alkaline hydrolysis, a base such as aqueous ammonia or triethylamine may be used. Preferably the reaction temperature is -20° C. to 100° C., more preferably 0° C. to 60° C., and the reaction time is 0.2 to 100 hours, more preferably 0.5 to 20 hours.

The amounts of monomers in the monomer solution may be determined appropriate so as to provide the preferred fractions of repeat units.

It is now described how to use the polymer obtained by the above preparation method. The reaction solution resulting from polymerization reaction may be used as the final product. Alternatively, the polymer may be recovered in powder form through a purifying step such as re-precipitation step of adding the polymerization solution to a poor solvent and letting the polymer precipitate as powder, after which the polymer powder is used as the final product. It is preferred from the standpoints of operation efficiency and consistent quality to handle a polymer solution which is obtained by dissolving the powder polymer resulting from the purifying step in a solvent, as the final product. The solvents which can be used herein are described in JP-A 2008-111103, paragraphs [0144]-[0145] (USP 7,537,880). Exemplary solvents include ketones such as cyclohexanone and methyl-2-n-pentyl ketone; alcohols such as 3-methoxvbutanol, 3-methyl-3-methoxybutanol, 1-methoxy-2-propanol, and 1-ethoxy-2-propanol; keto-alcohols such as diacetone alcohol (DAA); ethers such as propylene glycol monomethyl ether (PGME), ethylene glycol monomethyl ether, propylene glycol monoethyl ether, ethylene glycol monoethyl ether, propylene glycol dimethyl ether, and diethylene glycol dimethyl ether; esters such as propylene glycol monomethyl ether acetate (PGMEA), propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, and propylene glycol mono-tert-butyl ether acetate; lactones such as γ-butyrolactone (GBL); and high-boiling alcohols such as diethylene glycol, propylene glycol, glycerol, 1,4-butanediol, and 1.3-butanediol, which may be used alone or in admixture.

The polymer solution preferably has a polymer concentration of 0.01 to 30% by weight, more preferably 0.1 to 20% by weight.

Prior to use, the reaction solution or polymer solution is preferably filtered through a filter. Filtration is effective for consistent quality because foreign particles and gel which can cause defects are removed.

Suitable materials of which the filter is made include fluorocarbon, cellulose, nylon, polyester, and hydrocarbon base materials. Preferred for the filtration of a resist composition are filters made of fluorocarbons commonly known as Teflon®, hydrocarbons such as polyethylene and polypropylene, and nylon. While the pore size of the filter may be selected appropriate to comply with the desired cleanness, the filter preferably has a pore size of up to 100 nm, more preferably up to 20 nm. A single filter may be used or a plurality of filters may be used in combination. Although the filtering method may be single pass of the solution, preferably the filtering step is repeated by flowing the solution in a circulating manner. In the polymer preparation process, the filtering step may be carried out any times, in any order and in any stage. The reaction solution as polymerized or the polymer solution may be filtered, preferably both are filtered.

The proportion (mol%) of various repeat units in the polymer A is in the following range, but not limited thereto:
(I) preferably 5 to 99 mol%, more preferably 10 to 95 mol%, even more preferably 10 to 90 mol% of repeat units of at least one type selected from repeat units (a1) and (a2):
(II) preferably 5 to 99 mol%, more preferably 10 to 95 mol%, even more preferably 15 to 90 mol% of repeat units of at least one type selected from repeat units (b1) and (b2); and
(III) preferably 0 to 80 mol%, more preferably 0 to 70 mol%, even more preferably 0 to 50 mol% of repeat units of at least one type derived from other monomers.

The polymer A may be used alone or as a blend of two or more polymers which differ in compositional ratio, Mw and/or Mw/Mn.

### (B) Photoacid generator

The chemically amplified resist composition also contains (B) a photoacid generator capable of generating an acid upon exposure to KrF excimer laser radiation, ArF excimer laser radiation, EB or EUV. The photoacid generator (B) has the formula (1a) or (1b).

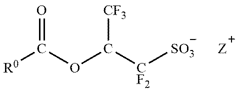

In formula (1a), R⁰ is hydrogen or a C₁-C₅₀ hydrocarbyl group. In the hydrocarbyl group, some or all of the hydrogen atoms may be substituted by halogen and any constituent —CH₂— may be replaced by —O— or —C(═O)—. Z⁺ is an organic cation.

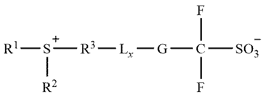

In formula (1b), R¹ and R² are each independently a C₁-C₂₀ hydrocarbyl group which may contain a heteroatom. R¹ and R² may bond together to form a ring with the sulfur atom to which they are attached. R³ is a C₁-C₂₀ hydrocarbylene group which may contain a heteroatom. G is a single bond or a C₁-C₂₀ hydrocarbylene group which may contain a heteroatom. Lx is a divalent linking group.

The C₁-C₅₀ hydrocarbyl group R⁰ may be saturated or unsaturated and straight, branched or cyclic. Examples thereof include C₁-C₅₀ alkyl groups such as methyl, ethyl, n-propyl, isopropyl, n-butyl, and tert-butyl; C₃-C₅₀ cyclic saturated hydrocarbyl groups such as cyclopropyl, cyclopentyl, cyclohexyl, cyclopropylmethyl, 4-methylcyclohexyl, cyclohexylmethyl, norbornyl, and adamantyl; C₂-C₅₀ alkenyl groups such as vinyl, allyl, propenyl, butenyl, and hexenyl; C₃-C₅₀ cyclic unsaturated hydrocarbyl groups such as cyclohexenyl; C₆-C₅₀ aryl groups such as phenyl and naphthyl; C₇-C₅₀ aralkyl groups such as benzyl. 1-phenylethyl and 2-phenylethyl; and combinations thereof. In the hydrocarbyl group, some or all of the hydrogen atoms may be substituted by a moiety containing a heteroatom such as oxygen, sulfur, nitrogen or halogen, and any constituent —CH₂— may be replaced by a moiety containing a heteroatom such as oxygen, sulfur or nitrogen, so that the group may contain a hydroxy moiety, fluorine, chlorine, bromine, iodine, cyano moiety, carbonyl moiety, ether bond, ester bond, sulfonic ester bond, carbonate bond, lactone ring, sultone ring, carboxylic anhydride (—C(═O)—O—C(═O)—) or haloalkyl moiety.

Examples of the anion in the PAG having formula (1a) are shown below, but not limited thereto.

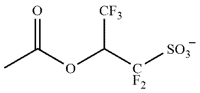

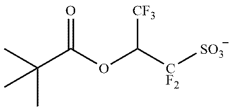

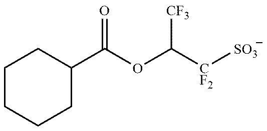

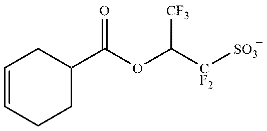

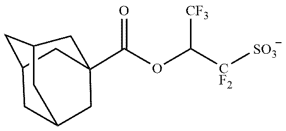

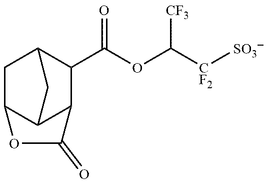

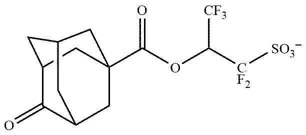

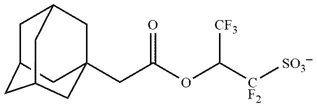

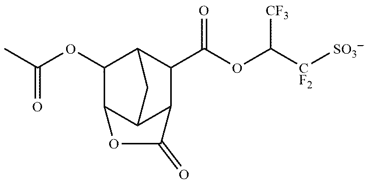

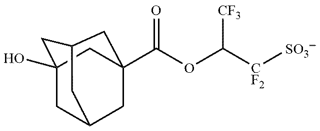

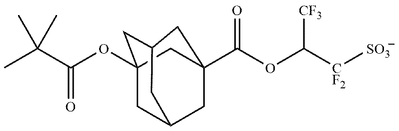

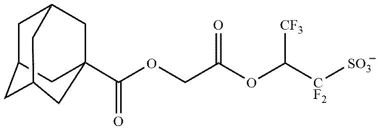

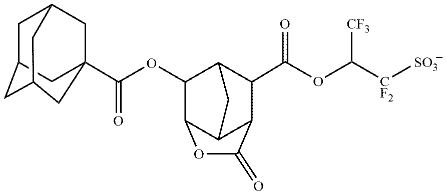

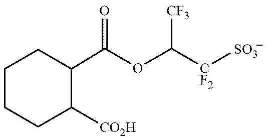

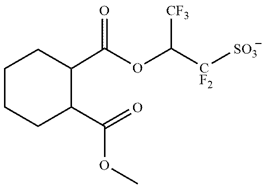

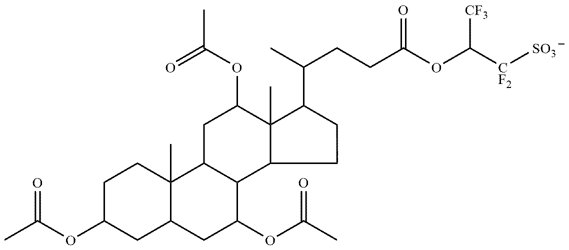

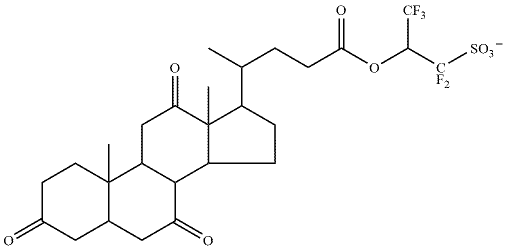

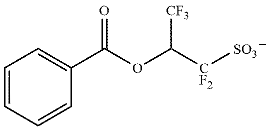

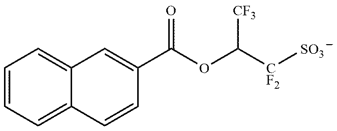

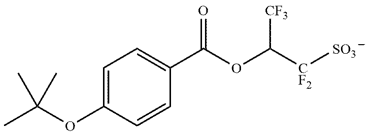

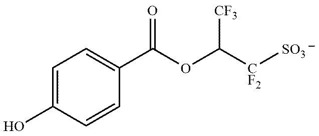

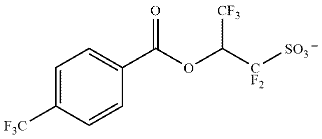

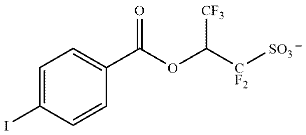

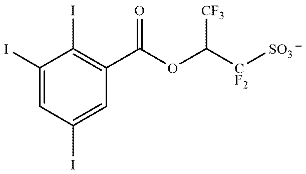

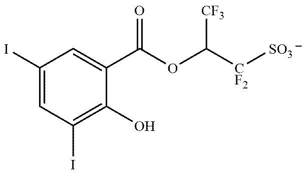

In formula (1a), Z⁺ is an organic cation, which is preferably a sulfonium or iodonium cation.

Typical of the sulfonium cation is a cation having the formula (Z1).

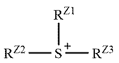

In formula (Z1), R^{Z1}, R^{Z2}, and R^{Z3} are each independently a C₁-C₂₀ hydrocarbyl group which may contain a heteroatom. Any two of R^{Z1},R^{Z2},and R^{Z3} may bond together to form a ring with the sulfur atom to which they are attached. The hydrocarbyl groups R^{Z1}, R^{Z2}, and R^{Z3} may be saturated or unsaturated and straight, branched or cyclic. Examples thereof include C₁-C₂₀ alkyl groups such as methyl, ethyl, n-propyl, isopropyl, n-butyl, sec-butyl, tert-butyl, tert-pentyl, n-pentyl, n-hexyl, n-octyl, 2-ethylhexyl, n-nonyl, and n-decyl; C₃-C₂₀ cyclic saturated hydrocarbyl groups such as cyclopentyl, cyclohexyl, cyclopentylmethyl, cyclopentylethyl, cyclopentylbutyl, cyclohexylmethyl, cyclohexylethyl, cyclohexylbutyl, norbornyl, tricyclo[5.2.1.0^{2,6}]decanyl, adamantyl, and adamantylmethyl; C₆-C₂₀ aryl groups such as phenyl, naphthyl and anthracenyl; and combinations thereof. In these hydrocarbyl groups, some or all of the hydrogen atoms may be substituted by a moiety containing a heteroatom such as oxygen, sulfur, nitrogen or halogen, or any constituent —CH₂— may be replaced by a moiety containing a heteroatom such as oxygen, sulfur or nitrogen, so that the group may contain a hydroxy, fluorine, chlorine, bromine, iodine, cyano, carbonyl, ether bond, thioether bond, ester bond, sulfonic ester bond, carbonate bond, carbamate bond, lactone ring, sultone ring, carboxylic anhydride (—C(═O)—O—C(═O)—) or haloalkyl moiety.

Examples of the sulfonium cation include triphenylsulfonium, 4-hydroxyphenyldiphenylsulfonium, bis(4-hydroxyphenyl)phenylsulfonium, tris(4-hydroxyphenyl)sulfonium, 4-tert-butoxyphenyldiphenylsulfonium, bis(4-tert-butoxyphenyl)phenylsulfonium, tris(4-tert-butoxyphenyl)sulfonium, 3-tert-butoxyphenyldiphenylsulfonium, bis(3-tert-butoxyphenyl)phenylsulfonium, tris(3-tert-butoxyphenyl)sulfoniuna, 3,4-di-tert-butoxyphenyldiphenylsulfonium, bis(3,4-di-tert-butoxyphenyl)phenylsulfonium, tris(3.4-di-tert-butoxyphenyl)sulfonium, diphenyl(4-thiophenoxyphenyl)sulfonium, 4-tert-butoxycarbonylmethyloxyphenyldiphenylsulfonium, tris(4-tert-butoxycarbonylmethyloxyphenyl)sulfonium, (4-tert-butoxyphenyl)bis(4-dimethylaminophenyl)sulfonium, tris(4-dimethylaminophenyl)sulfonium, 2-naphthyldiphenylsulfonium, (4-hydroxy-3,5-dimethylphenyl)diphenylsulfonium, (4-n-hexyloxy-3,5-dimethylphenyl)diphenylsulfonium, dimethyl(2-naphthyl)sulfonium, 4-hydroxyphenyldimethylsulfonium, 4-methoxyphenyldimethylsulfonium, trimethylsulfonium, 2-oxocyclohexylcyclohexylmethylsulfonium, trinaphthylsulfonium, tribenzylsulfonium, diphenylmethylsulfonium, dimethylphenylsulfonium, 2-oxo-2-phenylethylthiacyclopentanium, diphenyl-2-thienylsulfonium, 4-n-butoxynaphthyl-1-thiacyclopentanium. 2-n-butoxynaphthyl-1-thiacyclopentanium, 4-methoxynaphthyl-1-thiacyclopentanium, and 2-methoxynaphthyl-1-thiacyclopentanium cations. Of these, triphenylsulfonium, 4-tert-butylphenyldiphenylsulfonium, 4-tert-butoxyphenyldiphenylsulfonium, tris(4-tert-butylphenyl)sulfonium, tris(4-tert-butoxyphenyl)sulfonium, and dimethylphenylsulfonium cations are more preferred.

Other examples of the sulfonium cation include those of the following formulae.

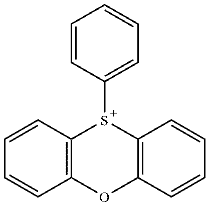 [SMILES: c1ccc([S+]2c3ccccc3Oc3ccccc32)cc1]

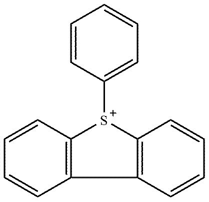 [SMILES: c1ccc(-[s+]2c3ccccc3c3ccccc32)cc1]

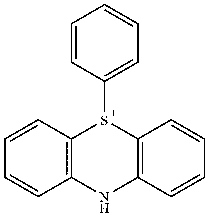 [SMILES: c1ccc([S+]2c3ccccc3Nc3ccccc32)cc1]

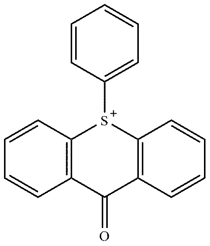 [SMILES: O=c1c2ccccc2[s+](-c2ccccc2)c2ccccc12]

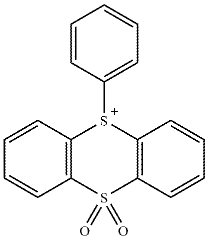 [SMILES: O=S1(=O)c2ccccc2[S+](c2ccccc2)c2ccccc21]

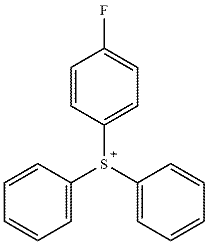 [SMILES: Fc1ccc([S+](c2ccccc2)c2ccccc2)cc1]

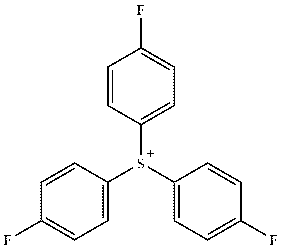 [SMILES: Fc1ccc([S+](c2ccc(F)cc2)c2ccc(F)cc2)cc1]

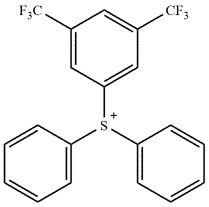 [SMILES: FC(F)(F)c1cc([S+](c2ccccc2)c2ccccc2)cc(C(F)(F)F)c1]

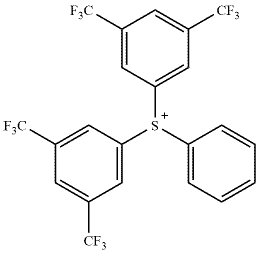 [SMILES: FC(F)(F)c1cc([S+](c2ccccc2)c2cc(C(F)(F)F)cc(C(F)(F)F)c2)cc(C(F)(F)F)c1]

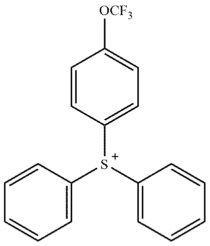 [SMILES: FC(F)(F)Oc1ccc([S+](c2ccccc2)c2ccccc2)cc1]

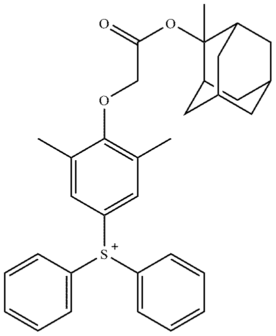 [SMILES: Cc1cc([S+](c2ccccc2)c2ccccc2)cc(C)c1OCC(=O)OC1(C)C2CC3CC(C2)CC1C3]

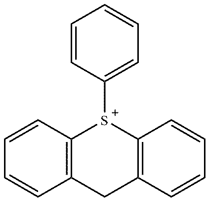 [SMILES: c1ccc([S+]2c3ccccc3Cc3ccccc32)cc1]

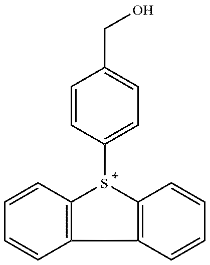 [SMILES: OCc1ccc(-[s+]2c3ccccc3c3ccccc32)cc1]

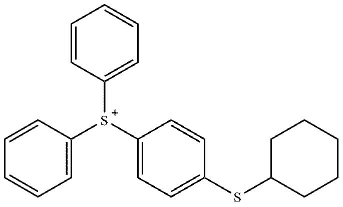 [SMILES: c1ccc([S+](c2ccccc2)c2ccc(SC3CCCCC3)cc2)cc1]

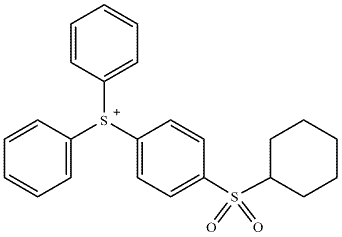 [SMILES: O=S(=O)(c1ccc([S+](c2ccccc2)c2ccccc2)cc1)C1CCCCC1]

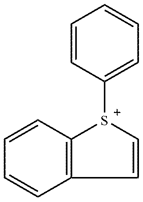 [SMILES: c1ccc(-[s+]2ccc3ccccc32)cc1]

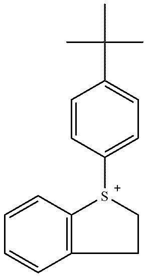 [SMILES: CC(C)(C)c1ccc([S+]2CCc3ccccc32)cc1]

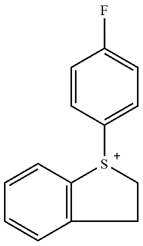 [SMILES: Fc1ccc([S+]2CCc3ccccc32)cc1]

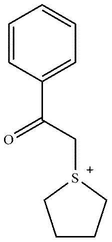 [SMILES: O=C(C[S+]1CCCC1)c1ccccc1]

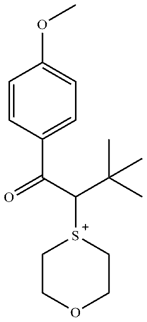 [SMILES: COc1ccc(C(=O)C([S+]2CCOCC2)C(C)(C)C)cc1]

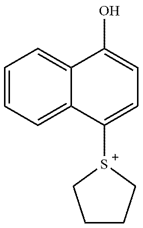 [SMILES: Oc1ccc([S+]2CCCC2)c2ccccc12]

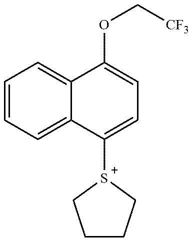 [SMILES: FC(F)(F)COc1ccc([S+]2CCCC2)c2ccccc12]

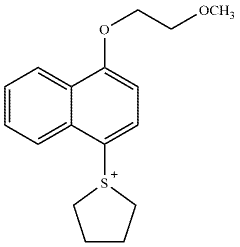 [SMILES: COCCOc1ccc([S+]2CCCC2)c2ccccc12]

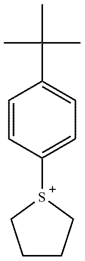

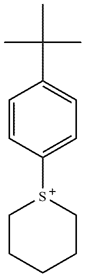 [SMILES: CC(C)(C)c1ccc([S+]2CCCCC2)cc1]

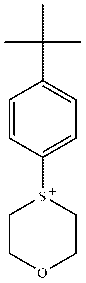 [SMILES: CC(C)(C)c1ccc([S+]2CCOCC2)cc1]

Typical of the iodonium cation is a cation having the formula (Z2).

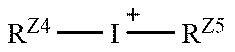

In formula (Z2), R^{Z4} and R^{Z5} are each independently a C₁-C₂₀ hydrocarbyl group which may contain a heteroatom. Examples of the groups R^{Z4} and R^{Z5} are as exemplified above for the hydrocarbyl groups R^{Z1}, R^{Z2} and R^{Z3}.

Examples of the iodonium cation include diphenyliodonium, bis(4-methylphenyl)iodonium, bis(4-ethylphenyl)iodonium, bis(4-tert-butylphenyl)iodonium, bis(4-(1,1-dimethylpropyl)phenyl)iodonium, bis(4-methoxyphenyl)iodonium, 4-methoxyphenylphenyliodonium, 4-tert-butoxyphenylphenyliodonium, 4-acryloyloxyphenylphenyliodonium, and 4-methacryloyloxyphenylphenyliodonium cations.

Examples of the PAG having formula (1a) include arbitrary combinations of any of the aforementioned examples of the anion with any of the aforementioned examples of the cation.

In formula (1b), the C₁-C₂₀ hydrocarbyl groups R¹ and R² may be saturated or unsaturated and straight, branched or cyclic. Examples thereof include C₁-C₂₀ alkyl groups such as methyl, ethyl, propyl, isopropyl, n-butyl, sec-butyl, tert-butyl, n-pentyl, tert-pentyl, n-hexyl, n-octyl, and 2-ethylhexyl. C₃-C₂₀ cyclic saturated hydrocarbyl groups such as cyclopentyl, cyclohexyl, cyclopentylmethyl, cyclopentylethyl, cyclohexylmethyl, cyclohexylethyl, norbornyl, oxanorbornyl, tricyclo[5.2.1.0^{2,6}]decanyl, and adamantyl; C₆-C₂₀ aryl groups such as phenyl and naphthyl; and combinations thereof. In these hydrocarbyl groups, some or all of the hydrogen atoms may be substituted by a moiety containing a heteroatom such as oxygen, sulfur, nitrogen or halogen, and any constituent —CH₂— may be replaced by a moiety containing a heteroatom such as oxygen, sulfur or nitrogen, so that the group may contain a hydroxy, cyano, fluorine, chlorine, bromine, iodine, carbonyl, ether bond, ester bond, sulfonic ester bond, carbonate bond, lactone ring, sultone ring, carboxylic anhydride (—C(═O)—O—C(═O)—) or haloalkyl moiety. Inter alia, R¹ and R² are preferably optionally substituted aryl groups.

The hydrocarbylene group R³ may be saturated or unsaturated and straight, branched or cyclic. Examples thereof include C₁-C₂₀ alkanediyl groups such as methanediyl, ethane-1,2-diyl, propane-1,3-diyl, butane-1,4-diyl, pentane-1,5-diyl, hexane-1,6-diyl, heptane-1,7-diyl, octane-1,8-diyl, nonane-1,9-diyl, decane-1,10-diyl, undecane-1,11-diyl, dodecane-1,12-diyl, tridecane-1,13-diyl, tetradecane-1,14-diyl, pentadecane-1,15-diyl, hexadecane-1,16-diyl, and heptadecane-1,17-diyl; C₃-C₂₀ cyclic saturated hydrocarbylene groups such as cyclopentanediyl, cyclohexanediyl, norbornanediyl and adamantanediyl; C₆-C₂₀ arylene groups such as phenylene, methylphenylene, ethylphenylene, n-propylphenylene, isopropylphenylene, n-butylphenylene, isobutylphenylene, sec-butylphenylene, tert-butylphenylene, naphthylene, methylnaphthylene, ethylnaphthylene, n-propylnaphthylene, isopropylnaphthylene, n-butylnaphthylene, isobutylnaphthylene, sec-butylnaphthylene, and tert-butylnaphthylene; and combinations thereof. In these hydrocarbylene groups, some or all of the hydrogen atoms may be substituted by a moiety containing a heteroatom such as oxygen, sulfur, nitrogen or halogen, or any constituent —CH₂— may be replaced by a moiety containing a heteroatom such as oxygen, sulfur or nitrogen, so that the group may contain a hydroxy, fluorine, chlorine, bromine, iodine, cyano, carbonyl, ether bond, ester bond, sulfonic ester bond, carbonate bond, lactone ring, sultone ring, carboxylic anhydride (—C(═O)—O—C(═O)—) or haloalkyl moiety. Inter alia, R³ is preferably an optionally substituted aryl group.

The hydrocarbylene group G may be saturated or unsaturated and straight, branched or cyclic. Examples thereof are as exemplified above for the hydrocarbylene group R³. In these hydrocarbylene groups, some or all of the hydrogen atoms may be substituted by a moiety containing a heteroatom such as oxygen, sulfur, nitrogen or halogen, or any constituent —CH₂— may be replaced by a moiety containing a heteroatom such as oxygen, sulfur or nitrogen, so that the group may contain a hydroxy, fluorine, chlorine, bromine, iodine, cyano, carbonyl, ether bond, ester bond, sulfonic ester bond, carbonate bond, lactone ring, sultone ring, carboxylic anhydride (—C(═O)—O—C(═O)—) or haloalkyl moiety. Inter alia, G is preferably a methanediyl group or a methanediyl group whose hydrogen is substituted by fluorine or trifluoromethyl.

Examples of the divalent linking group Lx include an ether bond, ester bond, thioether bond, sulfinic ester bond, sulfonic ester bond, carbonate bond, and carbamate bond.

Examples of the PAG having formula (1b) are shown below, but not limited thereto. Herein, G′ is hydrogen, fluorine or trifluoromethyl.

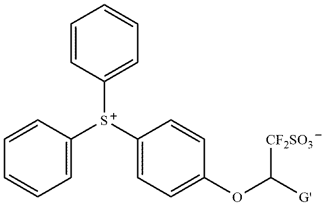

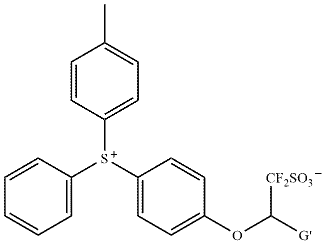

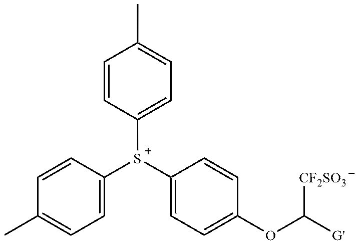

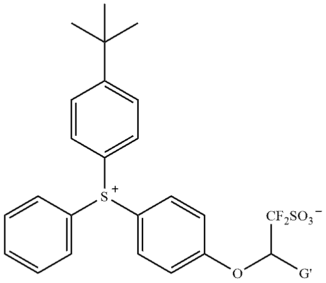

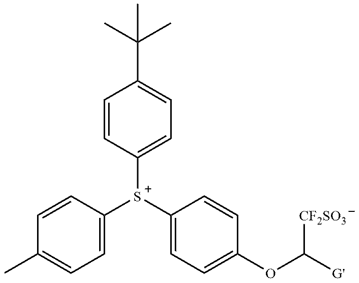

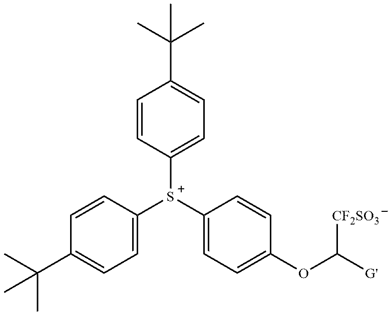

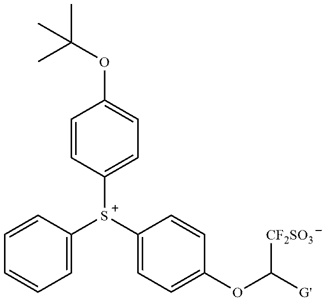

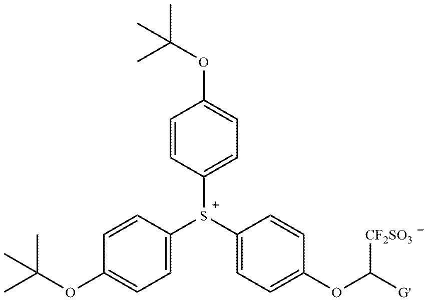

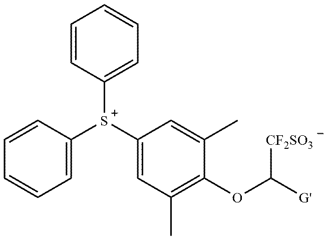

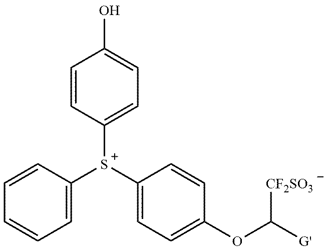

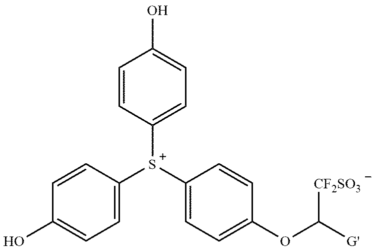

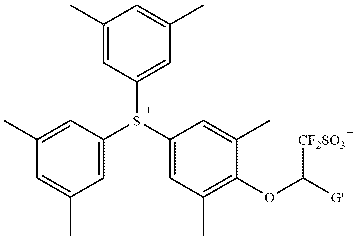

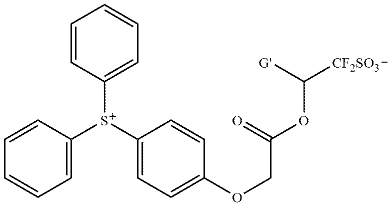

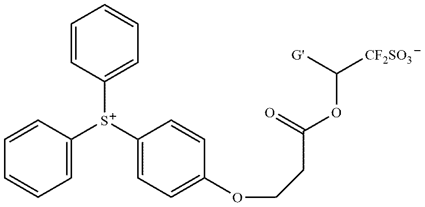

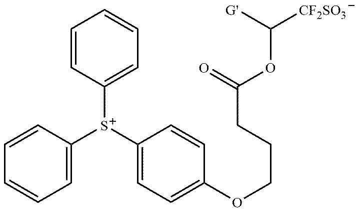

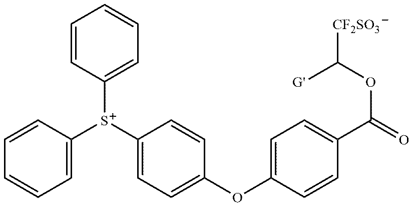

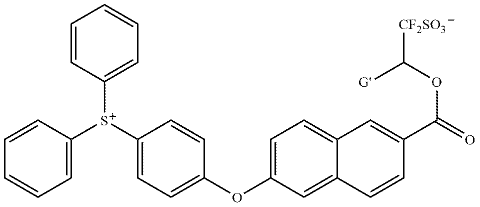

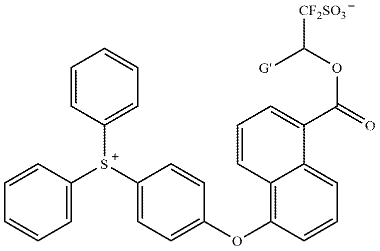

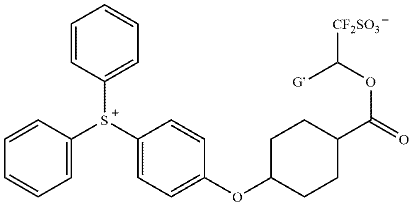

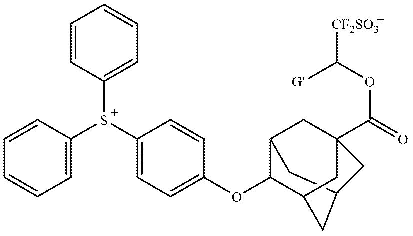

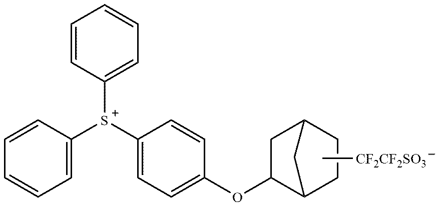

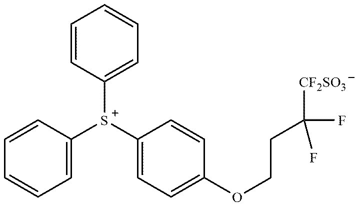

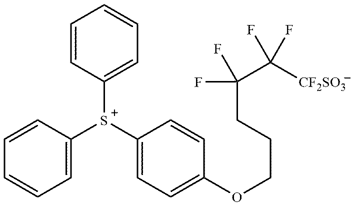

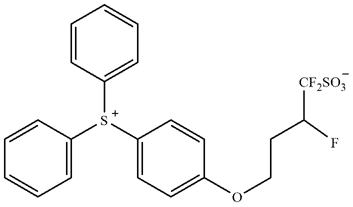

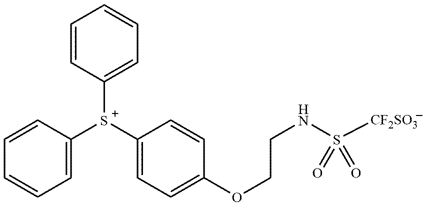

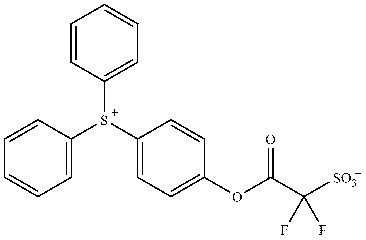

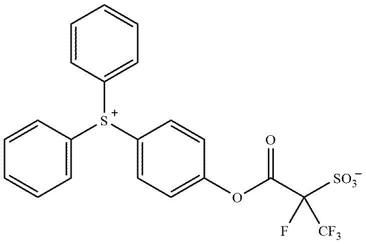

The PAG (B) is preferably added in an amount of 1 to 50 parts, more preferably 5 to 40 parts, and even more preferably 5 to 30 parts by weight per 80 parts by weight of the polymer A. As long as the amount of the PAG (B) is in the range, good resolution is achievable and the risk of foreign particles being formed after development or during stripping of resist film is avoided. The PAG may be used alone or in admixture.

### (C) Amine compound

The chemically amplified resist composition also comprises (C) a quencher in the form of an amine compound having the formula (2). As used herein, the “quencher” refers to a compound capable of trapping an acid generated from a photoacid generator in the resist composition to prevent the acid from diffusing to the unexposed region for thereby forming the desired pattern.

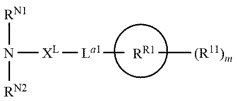

In formula (2), m is an integer of 0 to 10.

In formula (2), R^{N1} and R^{N2} are each independently hydrogen or a C₁-C₂₀ hydrocarbyl group. In the hydrocarbyl group, some or all of the hydrogen atoms may be substituted by halogen and any constituent —CH₂— may be replaced by —O— or —C(═O)—. R^{N1} and R^{N2} may bond together to form a ring with the nitrogen atom to which they are attached, the ring optionally containing —O— or —S—. It is noted that R^{N1} and R^{N2} are not hydrogen at the same time.

The hydrocarbyl groups R^{N1} and R^{N2} may be saturated or unsaturated and straight, branched or cyclic. Examples thereof include C₁-C₂₀ alkyl groups such as methyl, ethyl, n-propyl, isopropyl, n-butyl, sec-butyl, and tert-butyl; C₃-C₂₀ cyclic saturated hydrocarbyl groups such as cyclopropyl, cyclopentyl, cyclohexyl, cyclopropylmethyl, 4-methylcyclohexyl, cyclohexylmethyl, norbornyl, and adamantyl; C₂-C₂₀ alkenyl groups such as vinyl, allyl, propenyl, butenyl and hexenyl; C₃-C₂₀ cyclic unsaturated hydrocarbyl groups such as cyclohexenyl: C₆-C₂₀ aryl groups such as phenyl and naphthyl; C₇-C₂₀ aralkyl groups such as benzyl, 1-phenylethyl, and 2-phenylethyl: and combinations thereof.

The ring that R^{N1} and R^{N2}, taken together, form with the nitrogen atom to which they are attached, is preferably alicyclic. Examples of the ring include aziridine, azetidine, pyrrolidine, and piperidine rings, but are not limited thereto. Any constituent —CH₂— in the nitrogen-containing heterocycle may be replaced by —O— or —S—.

In formula (2), X^{L} is a C₁-C₄₀ hydrocarbylene group which may contain a heteroatom. Examples thereof are shown below, but not limited thereto. In the formulae, the asterisks (*) designate points of attachment to L^{a1} and the nitrogen atom, respectively.

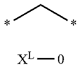

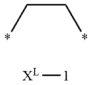

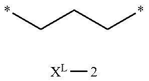

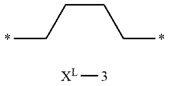

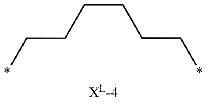

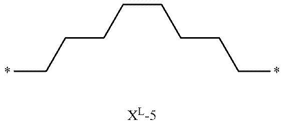

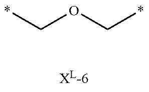

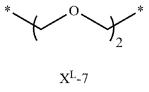

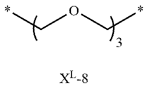

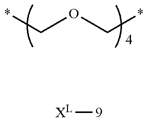

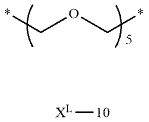

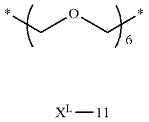

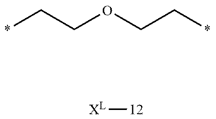

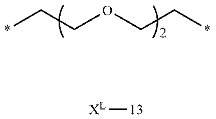

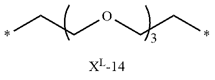

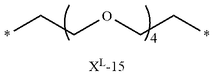

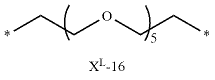

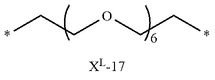

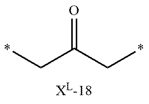

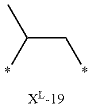

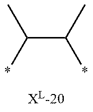

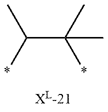

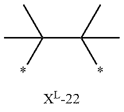

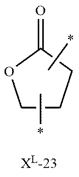

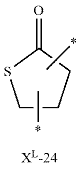

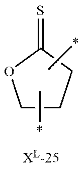

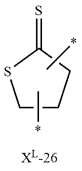

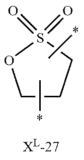

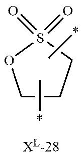

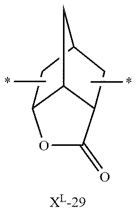

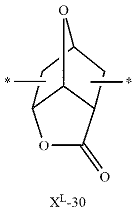

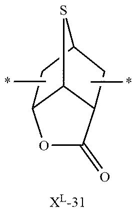

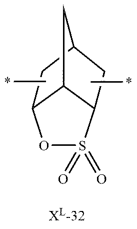

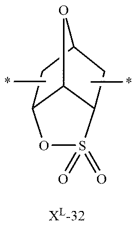

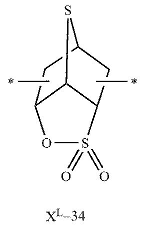

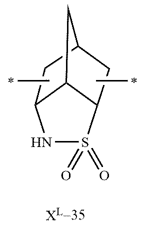

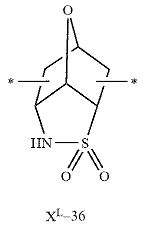

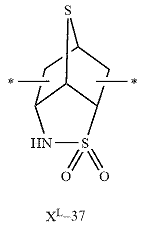

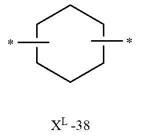

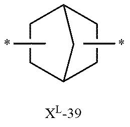

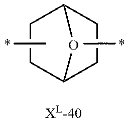

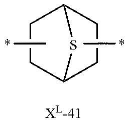

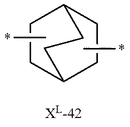

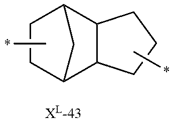

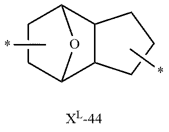

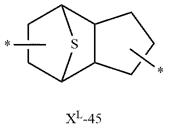

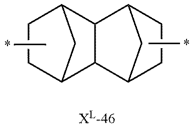

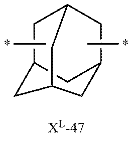

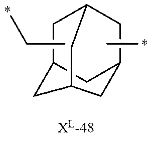

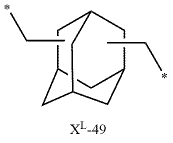

Of these, X^{L}-0 to X^{L}-22 and X^{L}-47 to X^{L}-49 are preferred, with X^{L}-0 to X^{L}-17 being more preferred.

In formula (2), L^{a1} is a single bond, ether bond, ester bond, sulfonic ester bond, carbonate bond or carbamate bond. Inter alia, a single bond, ether bond and ester bond are preferred, with the ether bond and ester bond being more preferred.

In formula (2), the ring R^{R1} is a C₂-C₂₀ (m+1)-valent heterocyclic group having a lactone, lactam, sultone or sultam structure. The heterocyclic group may be either monocyclic or fused ring although the fused ring is preferred from the standpoints of available reactants and the compound having a high boiling point.

Examples of the heterocyclic group wherein m=0 are shown below, but not limited thereto. In the formulae, the asterisk (*) designates a point of attachment to L^{a1}.

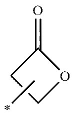

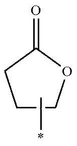

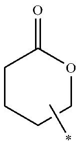

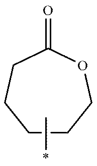

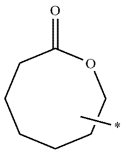

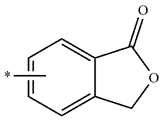

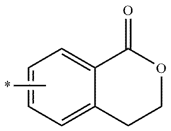

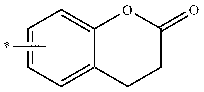

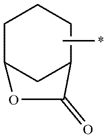

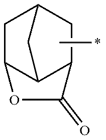

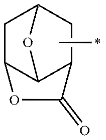

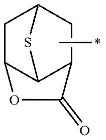

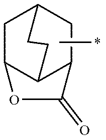

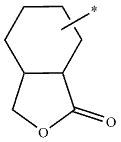

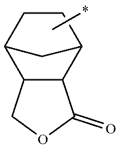

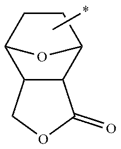

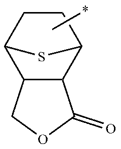

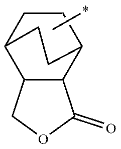

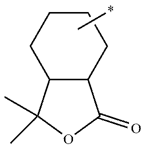

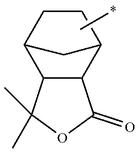

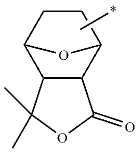

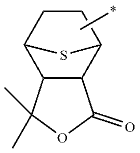

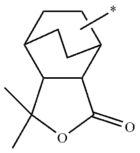

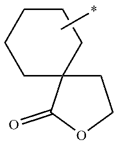

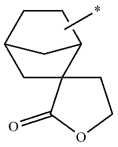

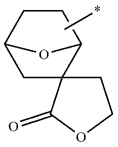

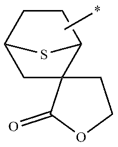

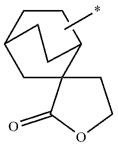

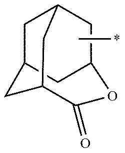

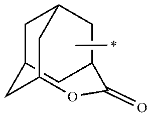

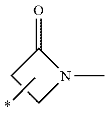

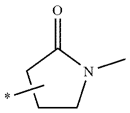

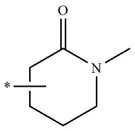

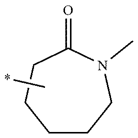

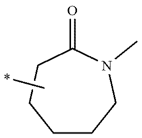

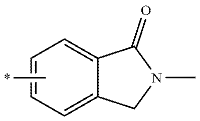

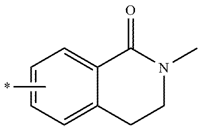

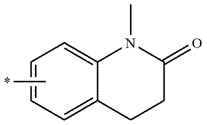

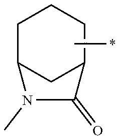

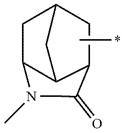

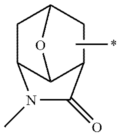

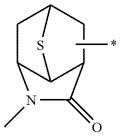

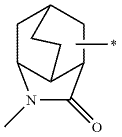

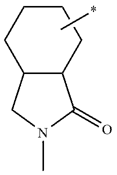

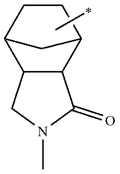

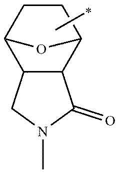

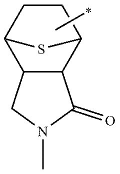

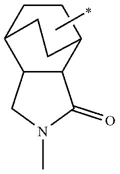

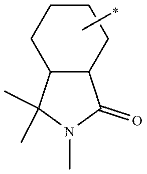

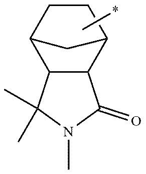

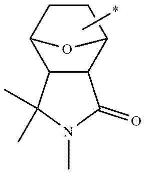

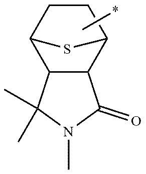

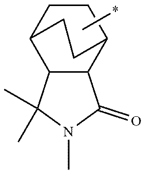

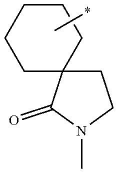

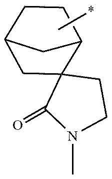

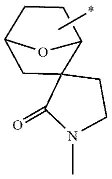

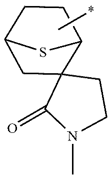

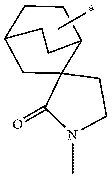

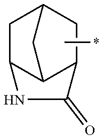

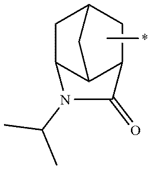

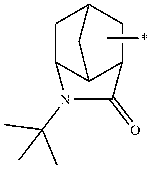

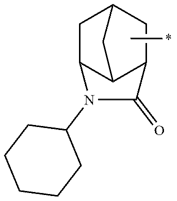

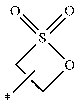

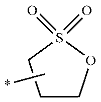

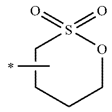

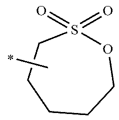

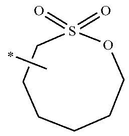

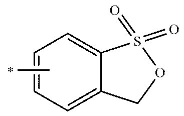

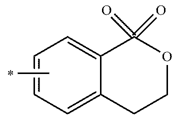

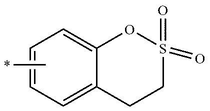

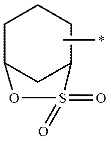

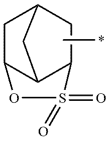

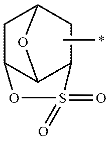

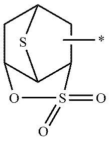

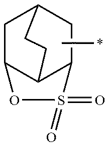

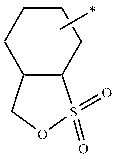

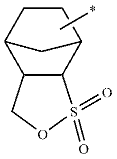

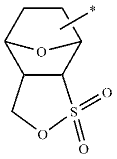

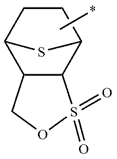

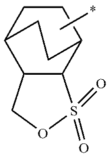

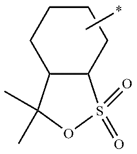

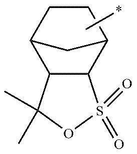

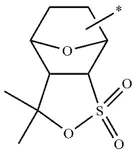

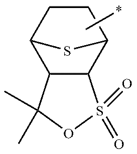

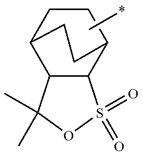

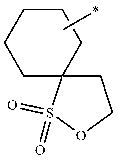

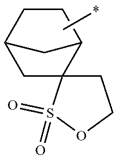

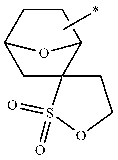

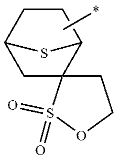

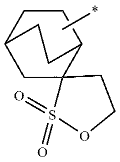

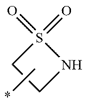

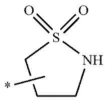

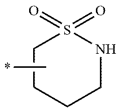

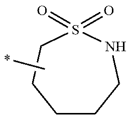

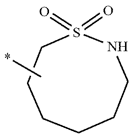

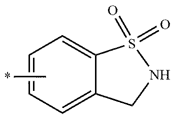

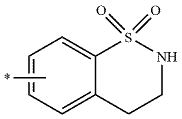

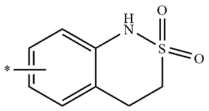

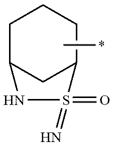

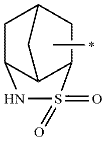

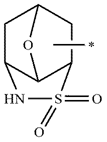

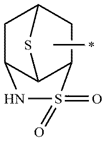

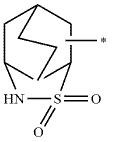

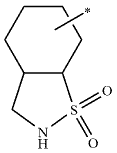

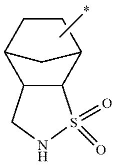

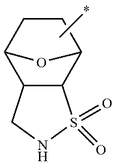

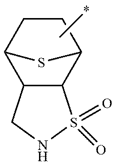

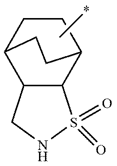

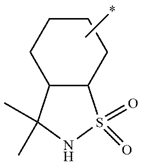

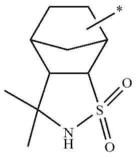

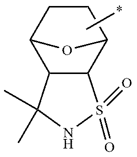

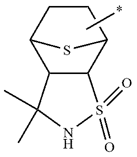

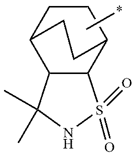

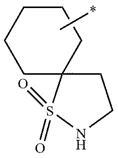

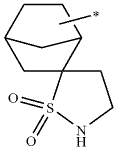

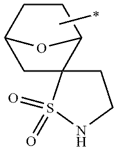

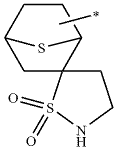

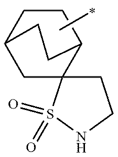

In formula (2), R¹¹ is a C ₁-C₂₀ hydrocarbyl group which may contain a heteroatom. The hydrocarbyl group may be saturated or unsaturated and straight, branched or cyclic. Examples thereof include C₁-C₂₀ alkyl groups such as methyl, ethyl, propyl, isopropyl, n-butyl, sec-butyl, tert-butyl, tert-pentyl, n-pentyl, n-hexyl, n-octyl, 2-ethylhexyl, n-nonyl, and n-decyl; C₃-C₂₀ cyclic saturated hydrocarbyl groups such as cyclopentyl, cyclohexyl, cyclopentylmethyl, cyclopentylethyl, cyclopentylbutyl, cyclohexylmethyl, cyclohexylethyl, cyclohexylbutyl, norbornyl, tricyclo[5.2.1.0^{2,6}]decanyl, adamantyl, and adamantylmethyl; C₆-C₂₀ aryl groups such as phenyl, naphthyl, and anthracenyl; and combinations thereof. In the hydrocarbyl group, some or all of the hydrogen atoms may be substituted by a moiety containing a heteroatom such as oxygen, sulfur, nitrogen or halogen, and any constituent —CH₂— may be replaced by a moiety containing a heteroatom such as oxygen, sulfur or nitrogen, so that the group may contain a hydroxy moiety, fluorine, chlorine, bromine, iodine, cyano moiety, carbonyl moiety, ether bond, ester bond, sulfonic ester bond, carbonate bond, carbamate bond, amide bond, imide bond, lactone ring, sultone ring, thiolactone ring, lactam ring, sultam ring, carboxylic anhydride (—C(═O)—O—C(═O)—) or haloalkyl moiety.

When m is 2 or more, a plurality of R¹¹ may be the same or different, and a plurality of R¹¹ may bond together to form a ring with the atoms on R^{R1} to which they are attached. Examples of the ring thus formed include cyclopropane, cyclobutane, cyclopentane, cyclohexane, norbornane, and adamantane rings. Two R¹¹ bonded to a common atom in the ring R^{R1} may bond together to form a ring, i.e., spiro ring,

Of the amine compounds having formula (2), those having the formula (2A) are preferred.

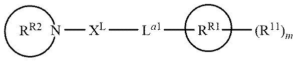

Herein m. X^{L}, L^{a1}, R^{R1}, and R¹¹ are as defined above.

In formula (2A), a C₃-C₂₀ alicyclic hydrocarbon group forms the ring R^{R2} with the nitrogen atom in the formula, and any constituent —CH₂— in the ring may be replaced by —O— or —S—. Preferred as the ring R^{R2} are C₃-C₂₀ alicyclic hydrocarbon groups in which —CH₂— is replaced by —O— or —S—.

Examples of the amine compound having formula (2) are shown below, but not limited thereto.

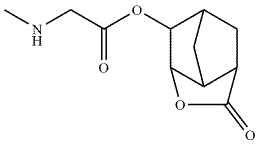 [SMILES: CNCC(=O)OC1C2CC3C(=O)OC1C3C2]

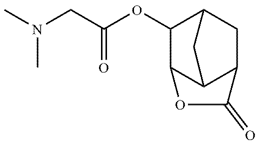 [SMILES: CN(C)CC(=O)OC1C2CC3C(=O)OC1C3C2]

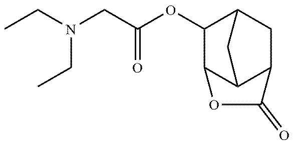 [SMILES: CCN(CC)CC(=O)OC1C2CC3C(=O)OC1C3C2]

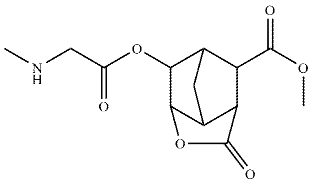

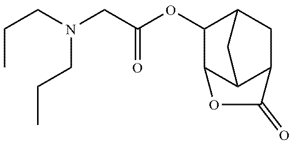 [SMILES: CCCN(CCC)CC(=O)OC1C2CC3C(=O)OC1C3C2]

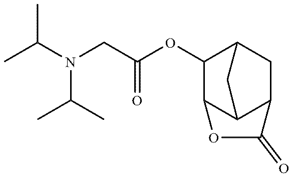 [SMILES: CC(C)N(CC(=O)OC1C2CC3C(=O)OC1C3C2)C(C)C]

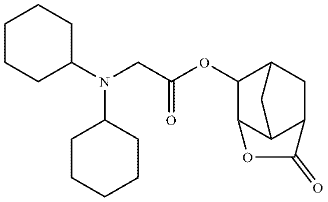 [SMILES: O=C(CN(C1CCCCC1)C1CCCCC1)OC1C2CC3C(=O)OC1C3C2]

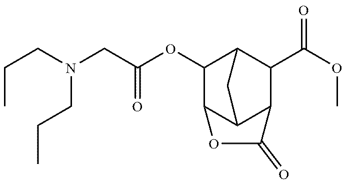 [SMILES: CCCN(CCC)CC(=O)OC1C2CC3C1OC(=O)C3C2C(=O)OC]

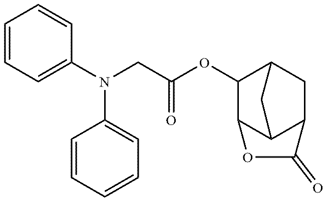 [SMILES: O=C(CN(c1ccccc1)c1ccccc1)OC1C2CC3C(=O)OC1C3C2]

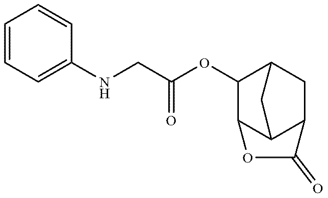 [SMILES: O=C(CNc1ccccc1)OC1C2CC3C(=O)OC1C3C2]

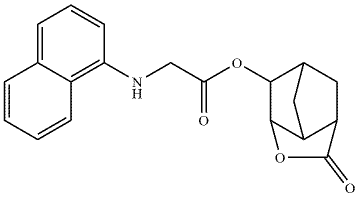 [SMILES: O=C(CNc1cccc2ccccc12)OC1C2CC3C(=O)OC1C3C2]

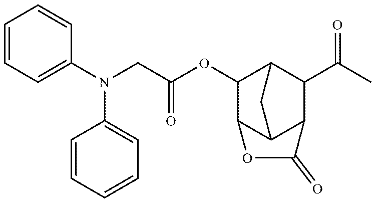 [SMILES: CC(=O)C1C2CC3C(OC(=O)C31)C2OC(=O)CN(c1ccccc1)c1ccccc1]

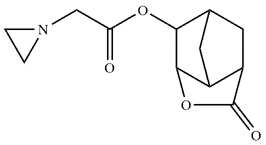 [SMILES: O=C(CN1CC1)OC1C2CC3C(=O)OC1C3C2]

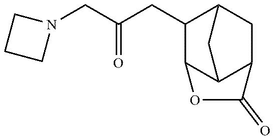 [SMILES: O=C(CC1C2CC3C(=O)OC1C3C2)CN1CCC1]

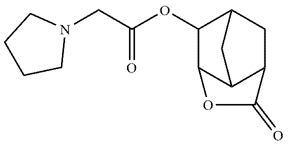 [SMILES: O=C(CN1CCCC1)OC1C2CC3C(=O)OC1C3C2]

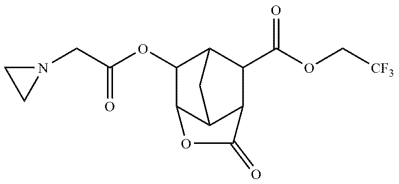 [SMILES: O=C(CN1CC1)OC1C2CC3C1OC(=O)C3C2C(=O)OCC(F)(F)F]

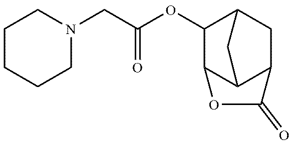 [SMILES: O=C(CN1CCCCC1)OC1C2CC3C(=O)OC1C3C2]

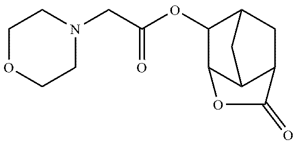 [SMILES: O=C(CN1CCOCC1)OC1C2CC3C(=O)OC1C3C2]

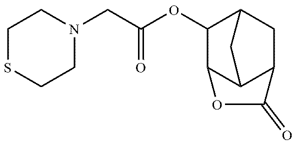 [SMILES: O=C(CN1CCSCC1)OC1C2CC3C(=O)OC1C3C2]

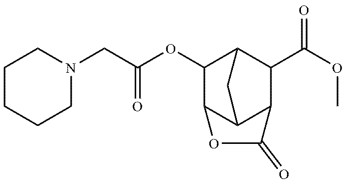 [SMILES: COC(=O)C1C2CC3C(OC(=O)C31)C2OC(=O)CN1CCCCC1]

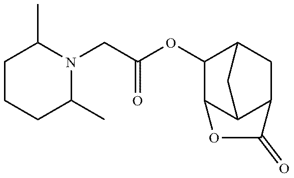 [SMILES: CC1CCCC(C)N1CC(=O)OC1C2CC3C(=O)OC1C3C2]

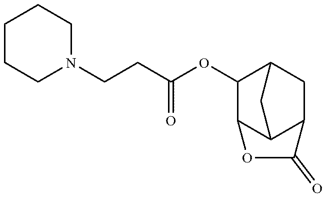 [SMILES: O=C(CCN1CCCCC1)OC1C2CC3C(=O)OC1C3C2]

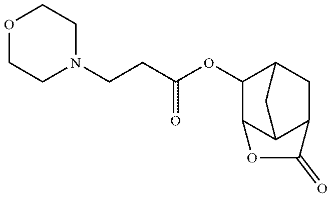 [SMILES: O=C(CCN1CCOCC1)OC1C2CC3C(=O)OC1C3C2]

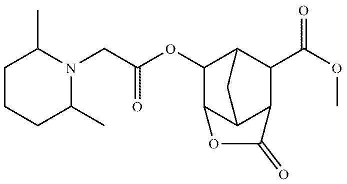 [SMILES: COC(=O)C1C2CC3C(OC(=O)C31)C2OC(=O)CN1C(C)CCCC1C]

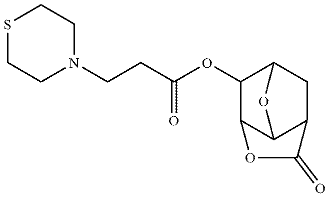 [SMILES: O=C(CCN1CCSCC1)OC1C2CC3C(=O)OC1C3O2]

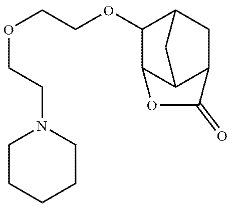 [SMILES: O=C1OC2C3CC(CC13)C2OCCOCCN1CCCCC1]

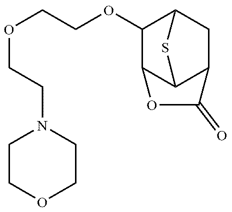 [SMILES: O=C1OC2C(OCCOCCN3CCOCC3)C3CC1C2S3]

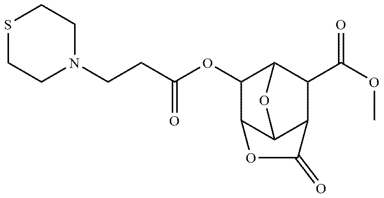 [SMILES: COC(=O)C1C2OC3C(OC(=O)C31)C2OC(=O)CCN1CCSCC1]

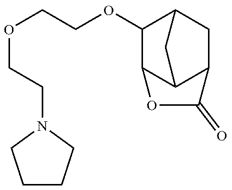 [SMILES: O=C1OC2C3CC(CC13)C2OCCOCCN1CCCC1]

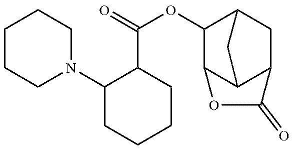 [SMILES: O=C1OC2C3CC(CC13)C2OC(=O)C1CCCCC1N1CCCCC1]

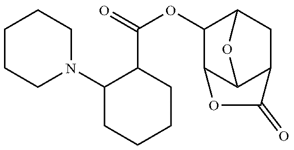 [SMILES: O=C1OC2C(OC(=O)C3CCCCC3N3CCCCC3)C3CC1C2O3]

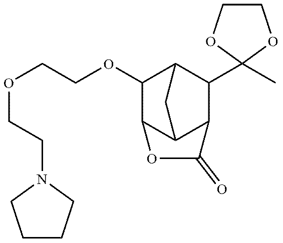 [SMILES: CC1(C2C3CC4C(OC(=O)C42)C3OCCOCCN2CCCC2)OCCO1]

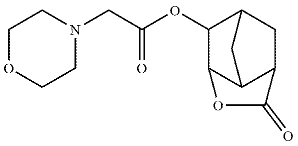 [SMILES: O=C(CN1CCOCC1)OC1C2CC3C(=O)OC1C3C2]

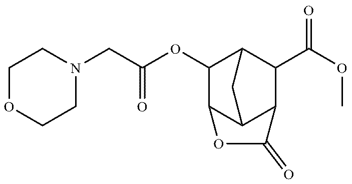 [SMILES: COC(=O)C1C2CC3C(OC(=O)C31)C2OC(=O)CN1CCOCC1]

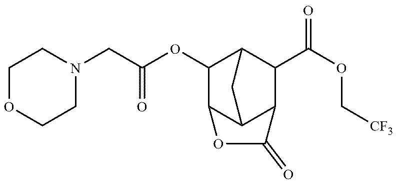 [SMILES: O=C(CN1CCOCC1)OC1C2CC3C1OC(=O)C3C2C(=O)OCC(F)(F)F]

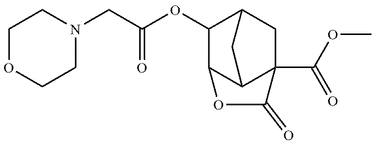 [SMILES: COC(=O)C12CC3CC1C(OC2=O)C3OC(=O)CN1CCOCC1]

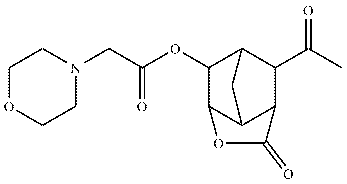 [SMILES: CC(=O)C1C2CC3C(OC(=O)C31)C2OC(=O)CN1CCOCC1]

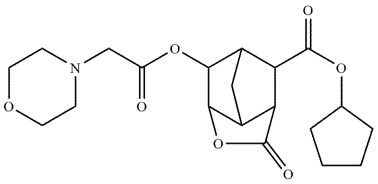 [SMILES: O=C(CN1CCOCC1)OC1C2CC3C1OC(=O)C3C2C(=O)OC1CCCC1]

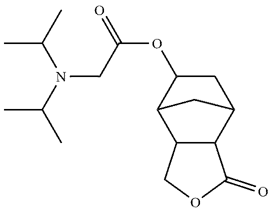 [SMILES: CC(C)N(CC(=O)OC1CC2CC1C1COC(=O)C21)C(C)C]

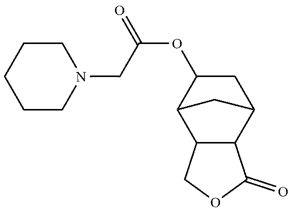 [SMILES: O=C(CN1CCCCC1)OC1CC2CC1C1COC(=O)C21]

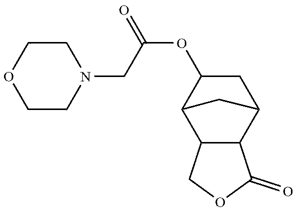 [SMILES: O=C(CN1CCOCC1)OC1CC2CC1C1COC(=O)C21]

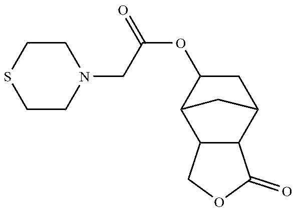 [SMILES: O=C(CN1CCSCC1)OC1CC2CC1C1COC(=O)C21]

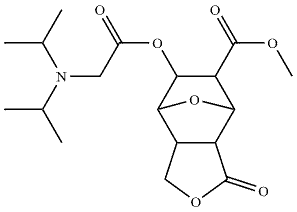 [SMILES: COC(=O)C1C(OC(=O)CN(C(C)C)C(C)C)C2OC1C1C(=O)OCC21]

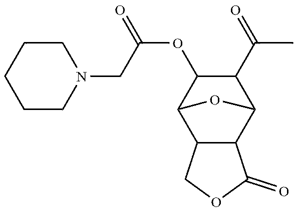 [SMILES: CC(=O)C1C(OC(=O)CN2CCCCC2)C2OC1C1C(=O)OCC21]

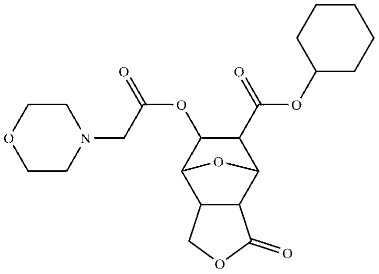 [SMILES: O=C(CN1CCOCC1)OC1C2OC(C3C(=O)OCC23)C1C(=O)OC1CCCCC1]

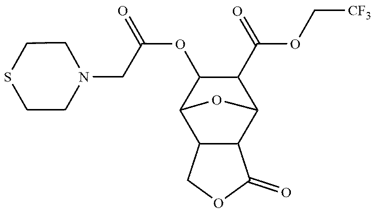 [SMILES: O=C(CN1CCSCC1)OC1C2OC(C3C(=O)OCC23)C1C(=O)OCC(F)(F)F]

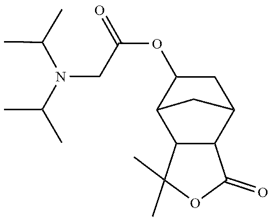 [SMILES: CC(C)N(CC(=O)OC1CC2CC1C1C2C(=O)OC1(C)C)C(C)C]

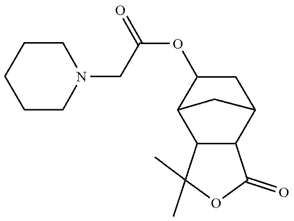 [SMILES: CC1(C)OC(=O)C2C3CC(OC(=O)CN4CCCCC4)C(C3)C21]

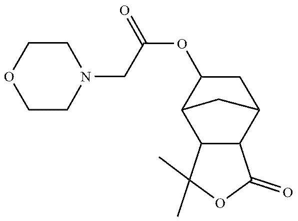 [SMILES: CC1(C)OC(=O)C2C3CC(OC(=O)CN4CCOCC4)C(C3)C21]

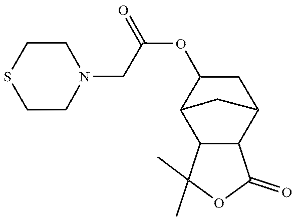 [SMILES: CC1(C)OC(=O)C2C3CC(OC(=O)CN4CCSCC4)C(C3)C21]

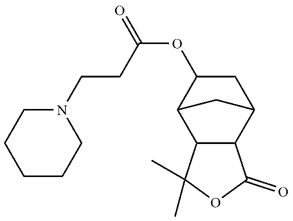 [SMILES: CC1(C)OC(=O)C2C3CC(OC(=O)CCN4CCCCC4)C(C3)C21]

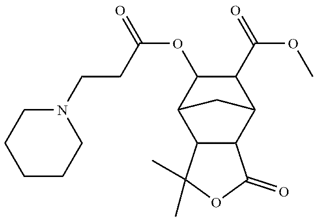 [SMILES: COC(=O)C1C2CC(C1OC(=O)CCN1CCCCC1)C1C2C(=O)OC1(C)C]

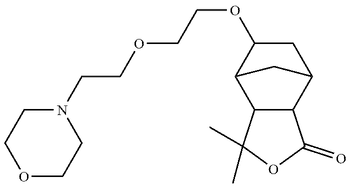 [SMILES: CC1(C)OC(=O)C2C3CC(OCCOCCN4CCOCC4)C(C3)C21]

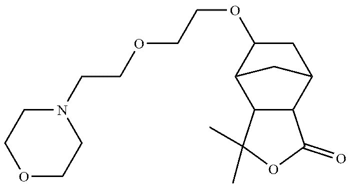 [SMILES: CC1(C)OC(=O)C2C3CC(OCCOCCN4CCOCC4)C(C3)C21]

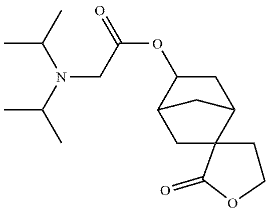 [SMILES: CC(C)N(CC(=O)OC1CC2CC1CC21CCOC1=O)C(C)C]

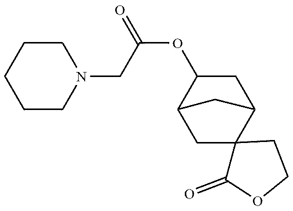 [SMILES: O=C(CN1CCCCC1)OC1CC2CC1CC21CCOC1=O]

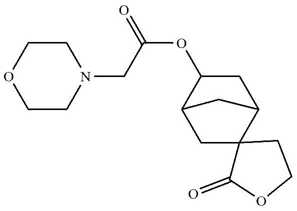 [SMILES: O=C(CN1CCOCC1)OC1CC2CC1CC21CCOC1=O]

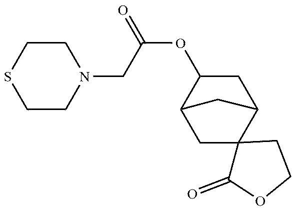 [SMILES: O=C(CN1CCSCC1)OC1CC2CC1CC21CCOC1=O]

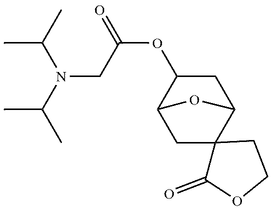 [SMILES: CC(C)N(CC(=O)OC1CC2OC1CC21CCOC1=O)C(C)C]

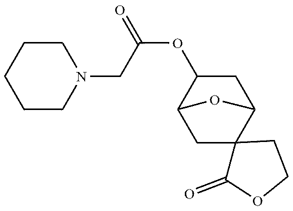 [SMILES: O=C(CN1CCCCC1)OC1CC2OC1CC21CCOC1=O]

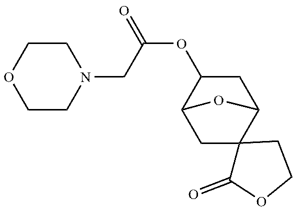 [SMILES: O=C(CN1CCOCC1)OC1CC2OC1CC21CCOC1=O]

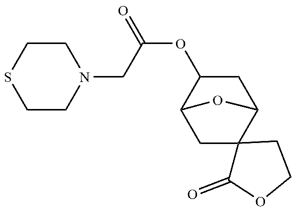 [SMILES: O=C(CN1CCSCC1)OC1CC2OC1CC21CCOC1=O]

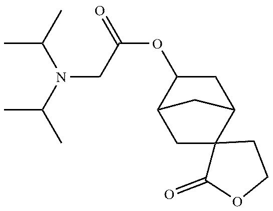 [SMILES: CC(C)N(CC(=O)OC1CC2CC1CC21CCOC1=O)C(C)C]

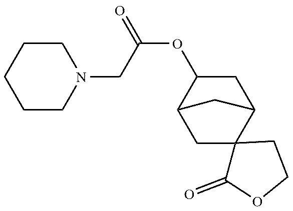 [SMILES: O=C(CN1CCCCC1)OC1CC2CC1CC21CCOC1=O]

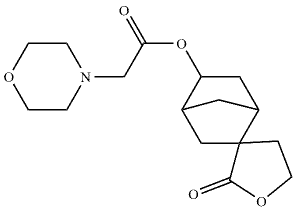 [SMILES: O=C(CN1CCOCC1)OC1CC2CC1CC21CCOC1=O]

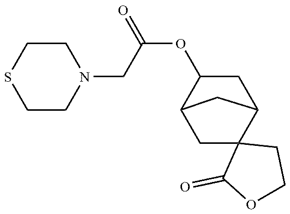 [SMILES: O=C(CN1CCSCC1)OC1CC2CC1CC21CCOC1=O]

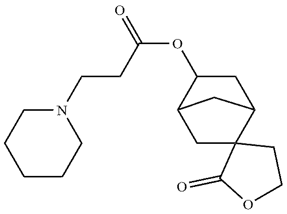 [SMILES: O=C(CCN1CCCCC1)OC1CC2CC1CC21CCOC1=O]

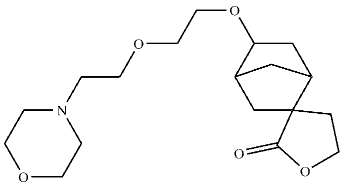 [SMILES: O=C1OCCC12CC1CC2CC1OCCOCCN1CCOCC1]

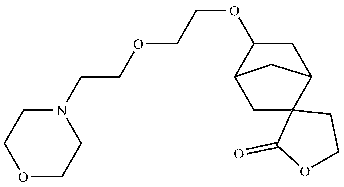 [SMILES: O=C1OCCC12CC1CC2CC1OCCOCCN1CCOCC1]

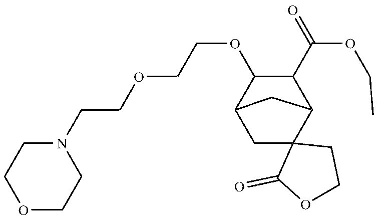 [SMILES: CCOC(=O)C1C(OCCOCCN2CCOCC2)C2CC1C1(CCOC1=O)C2]

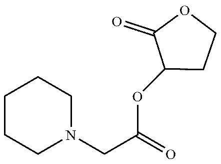 [SMILES: O=C(CN1CCCCC1)OC1CCOC1=O]

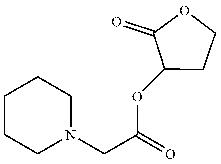 [SMILES: O=C(CN1CCCCC1)OC1CCOC1=O]

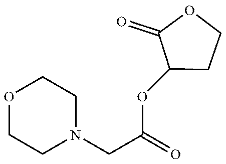 [SMILES: O=C(CN1CCOCC1)OC1CCOC1=O]

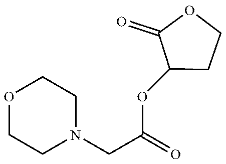 [SMILES: O=C(CN1CCOCC1)OC1CCOC1=O]

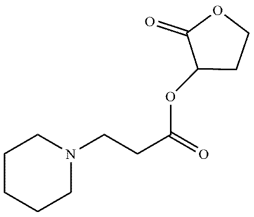 [SMILES: O=C(CCN1CCCCC1)OC1CCOC1=O]

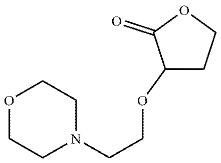 [SMILES: O=C1OCCC1OCCN1CCOCC1]

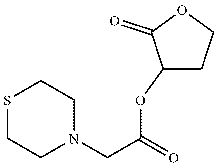 [SMILES: O=C(CN1CCSCC1)OC1CCOC1=O]

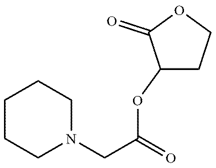 [SMILES: O=C(CN1CCCCC1)OC1CCOC1=O]

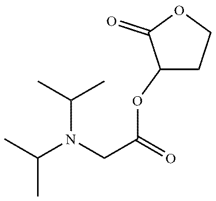 [SMILES: CC(C)N(CC(=O)OC1CCOC1=O)C(C)C]

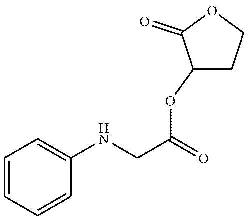 [SMILES: O=C(CNc1ccccc1)OC1CCOC1=O]

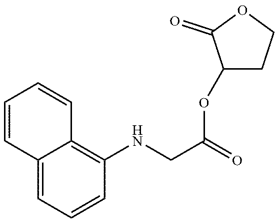 [SMILES: O=C(CNc1cccc2ccccc12)OC1CCOC1=O]

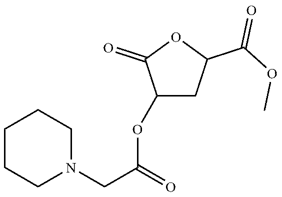 [SMILES: COC(=O)C1CC(OC(=O)CN2CCCCC2)C(=O)O1]

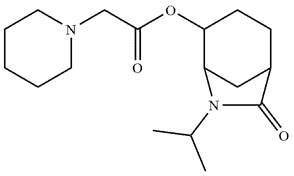 [SMILES: CC(C)N1C(=O)C2CCC(OC(=O)CN3CCCCC3)C1C2]

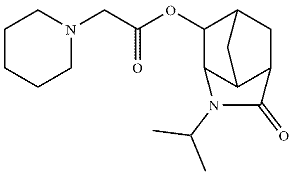 [SMILES: CC(C)N1C(=O)C2CC3CC2C1C3OC(=O)CN1CCCCC1]

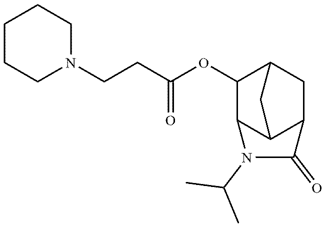 [SMILES: CC(C)N1C(=O)C2CC3CC2C1C3OC(=O)CCN1CCCCC1]

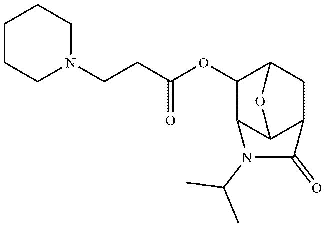 [SMILES: CC(C)N1C(=O)C2CC3OC2C1C3OC(=O)CCN1CCCCC1]

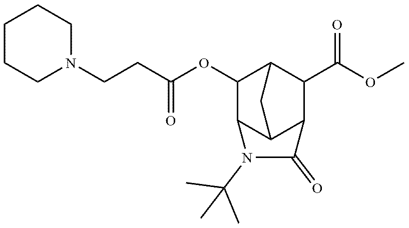 [SMILES: COC(=O)C1C2CC3C1C(=O)N(C(C)(C)C)C3C2OC(=O)CCN1CCCCC1]

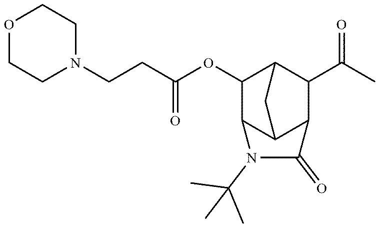 [SMILES: CC(=O)C1C2CC3C1C(=O)N(C(C)(C)C)C3C2OC(=O)CCN1CCOCC1]

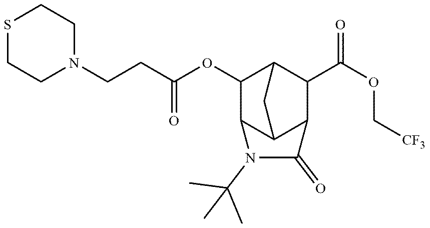 [SMILES: CC(C)(C)N1C(=O)C2C3CC(C(OC(=O)CCN4CCSCC4)C31)C2C(=O)OCC(F)(F)F]

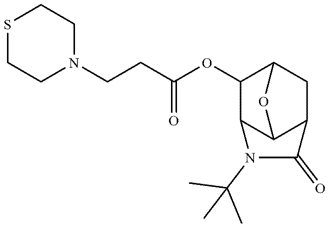 [SMILES: CC(C)(C)N1C(=O)C2CC3OC2C1C3OC(=O)CCN1CCSCC1]

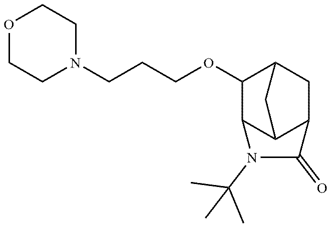 [SMILES: CC(C)(C)N1C(=O)C2CC3CC2C1C3OCCCN1CCOCC1]

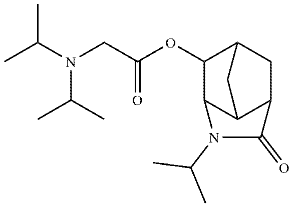 [SMILES: CC(C)N(CC(=O)OC1C2CC3C(=O)N(C(C)C)C1C3C2)C(C)C]

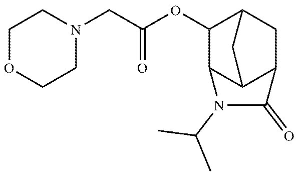 [SMILES: CC(C)N1C(=O)C2CC3CC2C1C3OC(=O)CN1CCOCC1]

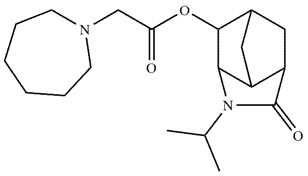 [SMILES: CC(C)N1C(=O)C2CC3CC2C1C3OC(=O)CN1CCCCCC1]

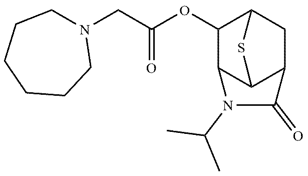 [SMILES: CC(C)N1C(=O)C2CC3SC2C1C3OC(=O)CN1CCCCCC1]

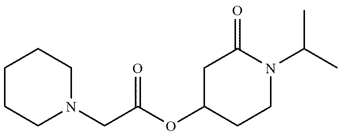 [SMILES: CC(C)N1CCC(OC(=O)CN2CCCCC2)CC1=O]

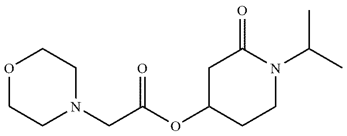 [SMILES: CC(C)N1CCC(OC(=O)CN2CCOCC2)CC1=O]

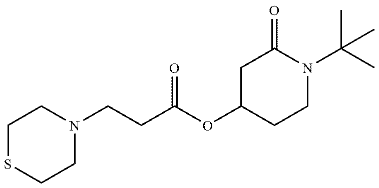 [SMILES: CC(C)(C)N1CCC(OC(=O)CCN2CCSCC2)CC1=O]

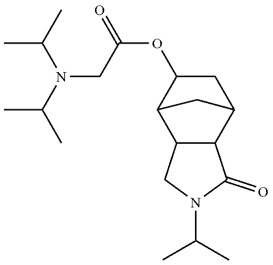 [SMILES: CC(C)N1CC2C3CC(CC3OC(=O)CN(C(C)C)C(C)C)C2C1=O]

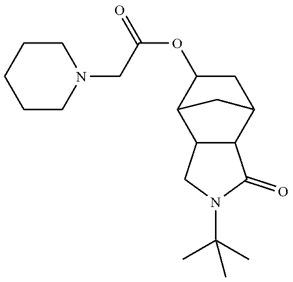 [SMILES: CC(C)(C)N1CC2C3CC(CC3OC(=O)CN3CCCCC3)C2C1=O]

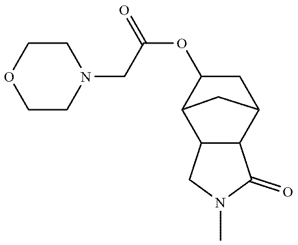 [SMILES: CN1CC2C3CC(CC3OC(=O)CN3CCOCC3)C2C1=O]

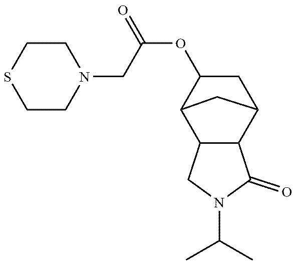 [SMILES: CC(C)N1CC2C3CC(CC3OC(=O)CN3CCSCC3)C2C1=O]

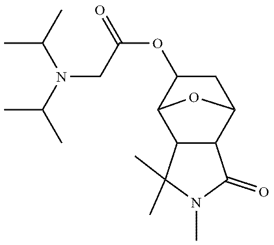 [SMILES: CC(C)N(CC(=O)OC1CC2OC1C1C2C(=O)N(C)C1(C)C)C(C)C]

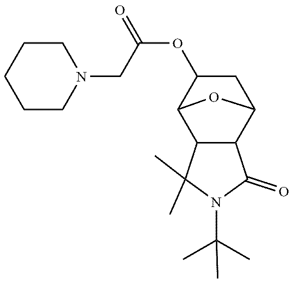 [SMILES: CC(C)(C)N1C(=O)C2C3CC(OC(=O)CN4CCCCC4)C(O3)C2C1(C)C]

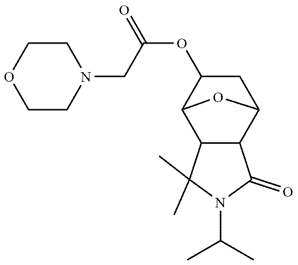 [SMILES: CC(C)N1C(=O)C2C3CC(OC(=O)CN4CCOCC4)C(O3)C2C1(C)C]

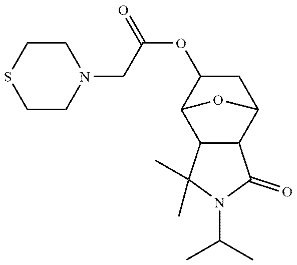 [SMILES: CC(C)N1C(=O)C2C3CC(OC(=O)CN4CCSCC4)C(O3)C2C1(C)C]

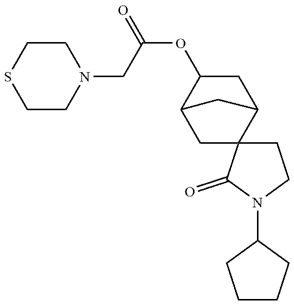 [SMILES: O=C(CN1CCSCC1)OC1CC2CC1CC21CCN(C2CCCC2)C1=O]

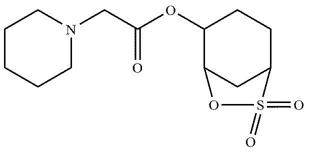 [SMILES: O=C(CN1CCCCC1)OC1CCC2CC1OS2(=O)=O]

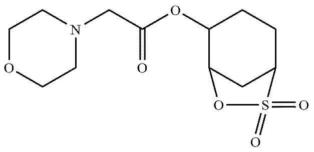 [SMILES: O=C(CN1CCOCC1)OC1CCC2CC1OS2(=O)=O]

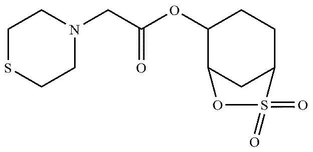 [SMILES: O=C(CN1CCSCC1)OC1CCC2CC1OS2(=O)=O]

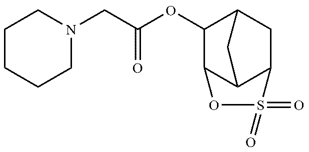 [SMILES: O=C(CN1CCCCC1)OC1C2CC3C1OS(=O)(=O)C3C2]

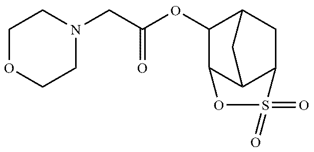 [SMILES: O=C(CN1CCOCC1)OC1C2CC3C1OS(=O)(=O)C3C2]

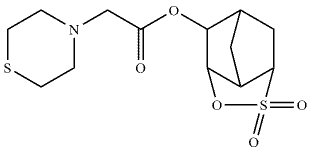 [SMILES: O=C(CN1CCSCC1)OC1C2CC3C1OS(=O)(=O)C3C2]

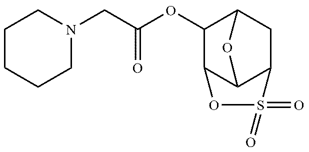 [SMILES: O=C(CN1CCCCC1)OC1C2CC3C(O2)C1OS3(=O)=O]

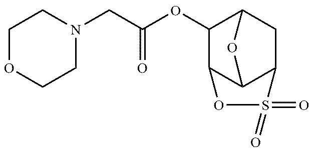 [SMILES: O=C(CN1CCOCC1)OC1C2CC3C(O2)C1OS3(=O)=O]

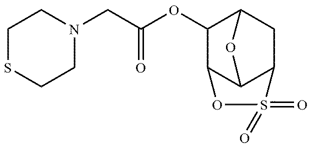 [SMILES: O=C(CN1CCSCC1)OC1C2CC3C(O2)C1OS3(=O)=O]

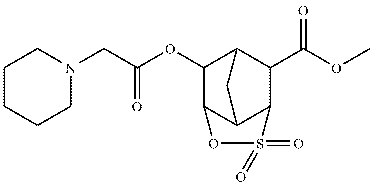 [SMILES: COC(=O)C1C2CC3C(OS(=O)(=O)C31)C2OC(=O)CN1CCCCC1]

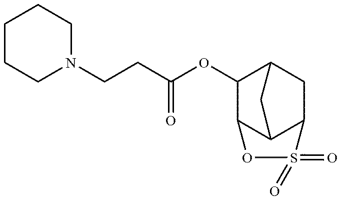 [SMILES: O=C(CCN1CCCCC1)OC1C2CC3C1OS(=O)(=O)C3C2]

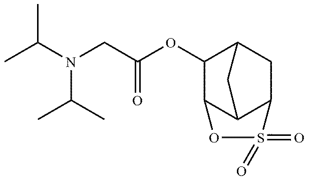 [SMILES: CC(C)N(CC(=O)OC1C2CC3C1OS(=O)(=O)C3C2)C(C)C]

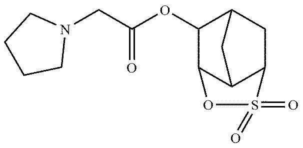 [SMILES: O=C(CN1CCCC1)OC1C2CC3C1OS(=O)(=O)C3C2]

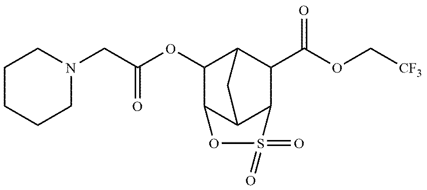 [SMILES: O=C(CN1CCCCC1)OC1C2CC3C1OS(=O)(=O)C3C2C(=O)OCC(F)(F)F]

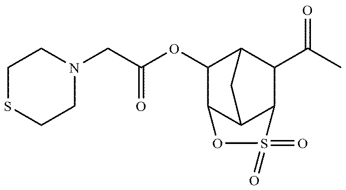 [SMILES: CC(=O)C1C2CC3C(OS(=O)(=O)C31)C2OC(=O)CN1CCSCC1]

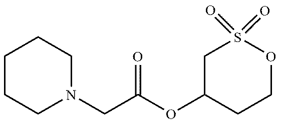 [SMILES: O=C(CN1CCCCC1)OC1CCOS(=O)(=O)C1]

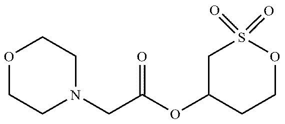 [SMILES: O=C(CN1CCOCC1)OC1CCOS(=O)(=O)C1]

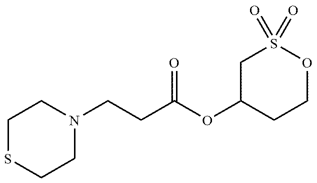 [SMILES: O=C(CCN1CCSCC1)OC1CCOS(=O)(=O)C1]

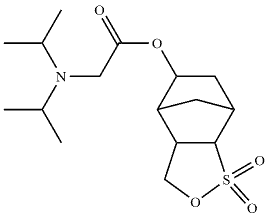 [SMILES: CC(C)N(CC(=O)OC1CC2CC1C1COS(=O)(=O)C21)C(C)C]

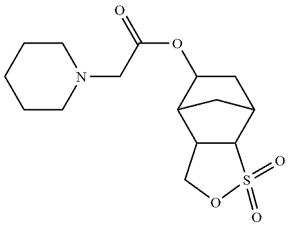 [SMILES: O=C(CN1CCCCC1)OC1CC2CC1C1COS(=O)(=O)C21]

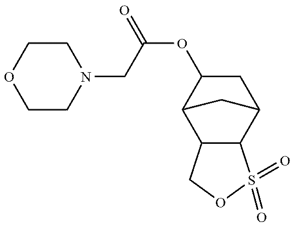 [SMILES: O=C(CN1CCOCC1)OC1CC2CC1C1COS(=O)(=O)C21]

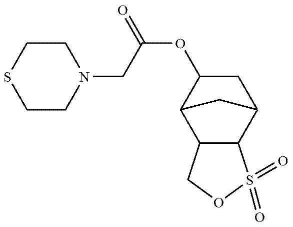 [SMILES: O=C(CN1CCSCC1)OC1CC2CC1C1COS(=O)(=O)C21]

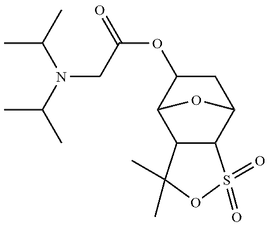 [SMILES: CC(C)N(CC(=O)OC1CC2OC1C1C2S(=O)(=O)OC1(C)C)C(C)C]

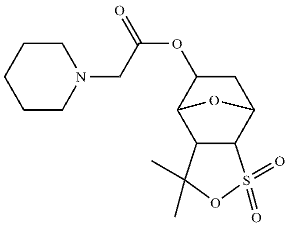 [SMILES: CC1(C)OS(=O)(=O)C2C3CC(OC(=O)CN4CCCCC4)C(O3)C21]

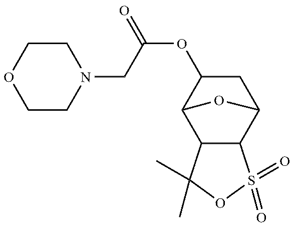 [SMILES: CC1(C)OS(=O)(=O)C2C3CC(OC(=O)CN4CCOCC4)C(O3)C21]

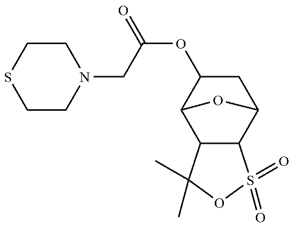 [SMILES: CC1(C)OS(=O)(=O)C2C3CC(OC(=O)CN4CCSCC4)C(O3)C21]

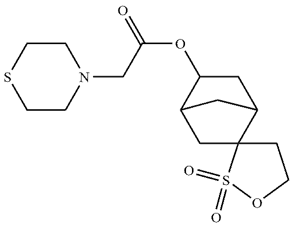 [SMILES: O=C(CN1CCSCC1)OC1CC2CC1CC21CCOS1(=O)=O]

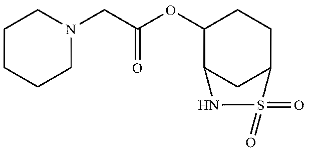 [SMILES: O=C(CN1CCCCC1)OC1CCC2CC1NS2(=O)=O]

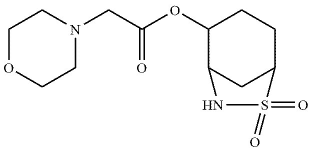 [SMILES: O=C(CN1CCOCC1)OC1CCC2CC1NS2(=O)=O]

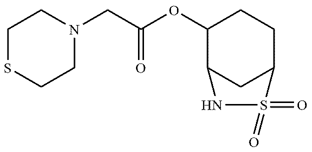 [SMILES: O=C(CN1CCSCC1)OC1CCC2CC1NS2(=O)=O]

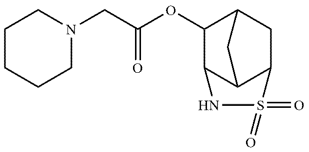 [SMILES: O=C(CN1CCCCC1)OC1C2CC3C1NS(=O)(=O)C3C2]

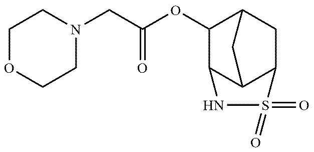 [SMILES: O=C(CN1CCOCC1)OC1C2CC3C1NS(=O)(=O)C3C2]

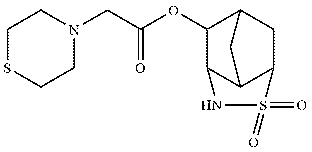 [SMILES: O=C(CN1CCSCC1)OC1C2CC3C1NS(=O)(=O)C3C2]

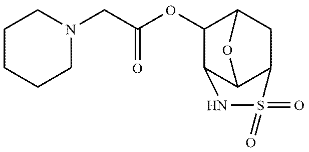 [SMILES: O=C(CN1CCCCC1)OC1C2CC3C(O2)C1NS3(=O)=O]

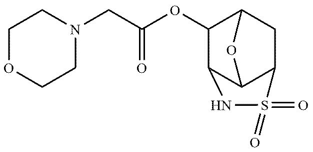 [SMILES: O=C(CN1CCOCC1)OC1C2CC3C(O2)C1NS3(=O)=O]

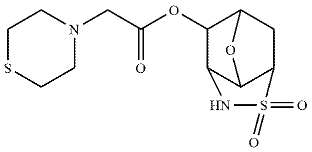 [SMILES: O=C(CN1CCSCC1)OC1C2CC3C(O2)C1NS3(=O)=O]

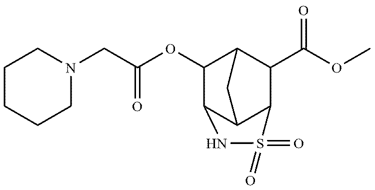 [SMILES: COC(=O)C1C2CC3C(NS(=O)(=O)C31)C2OC(=O)CN1CCCCC1]

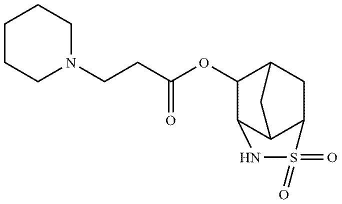 [SMILES: O=C(CCN1CCCCC1)OC1C2CC3C1NS(=O)(=O)C3C2]

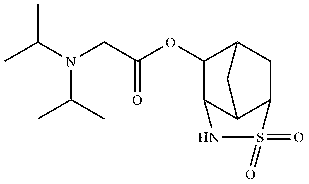 [SMILES: CC(C)N(CC(=O)OC1C2CC3C1NS(=O)(=O)C3C2)C(C)C]

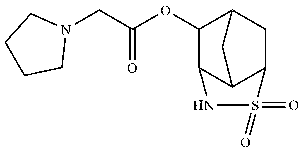 [SMILES: O=C(CN1CCCC1)OC1C2CC3C1NS(=O)(=O)C3C2]

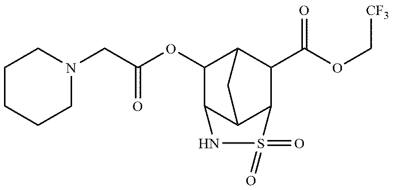 [SMILES: O=C(CN1CCCCC1)OC1C2CC3C1NS(=O)(=O)C3C2C(=O)OCC(F)(F)F]

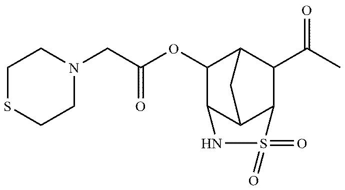 [SMILES: CC(=O)C1C2CC3C(NS(=O)(=O)C31)C2OC(=O)CN1CCSCC1]

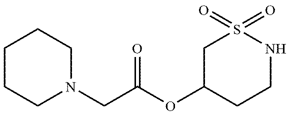 [SMILES: O=C(CN1CCCCC1)OC1CCNS(=O)(=O)C1]

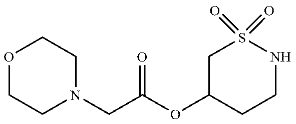 [SMILES: O=C(CN1CCOCC1)OC1CCNS(=O)(=O)C1]

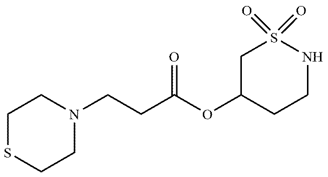 [SMILES: O=C(CCN1CCSCC1)OC1CCNS(=O)(=O)C1]

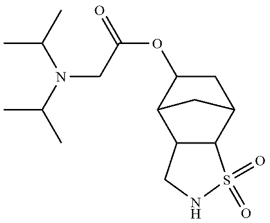 [SMILES: CC(C)N(CC(=O)OC1CC2CC1C1CNS(=O)(=O)C21)C(C)C]

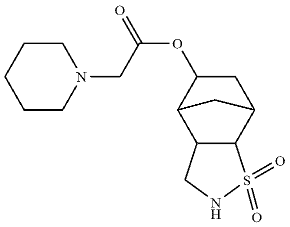 [SMILES: O=C(CN1CCCCC1)OC1CC2CC1C1CNS(=O)(=O)C21]

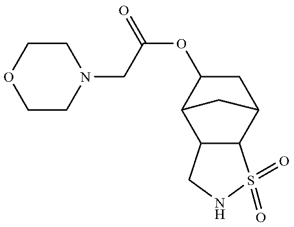 [SMILES: O=C(CN1CCOCC1)OC1CC2CC1C1CNS(=O)(=O)C21]

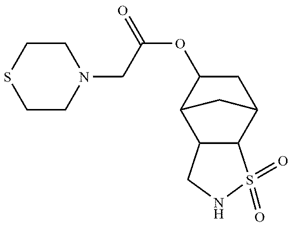 [SMILES: O=C(CN1CCSCC1)OC1CC2CC1C1CNS(=O)(=O)C21]

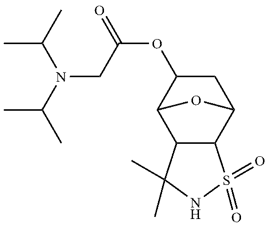 [SMILES: CC(C)N(CC(=O)OC1CC2OC1C1C2S(=O)(=O)NC1(C)C)C(C)C]

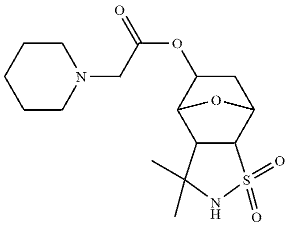 [SMILES: CC1(C)NS(=O)(=O)C2C3CC(OC(=O)CN4CCCCC4)C(O3)C21]

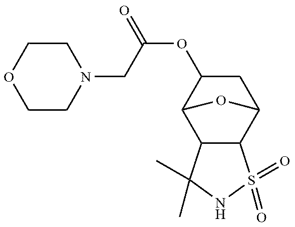 [SMILES: CC1(C)NS(=O)(=O)C2C3CC(OC(=O)CN4CCOCC4)C(O3)C21]

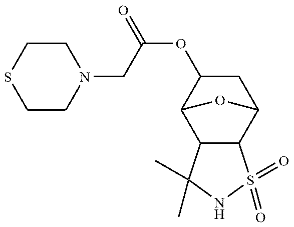 [SMILES: CC1(C)NS(=O)(=O)C2C3CC(OC(=O)CN4CCSCC4)C(O3)C21]

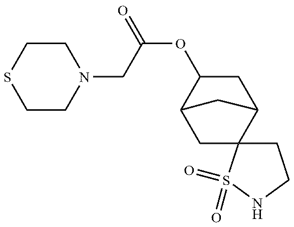 [SMILES: O=C(CN1CCSCC1)OC1CC2CC1CC21CCNS1(=O)=O]

The amine compound may be prepared, for example, according to the following scheme.

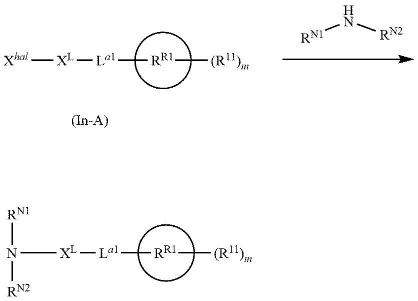

Herein R^{N1}, R^{N2}, m, X^{L}, L^{a1}, R^{R1}, and R¹¹ are as defined above, and X^{hal} is chlorine, bromine or iodine.

That is, the amine compound having formula (2) may be synthesized by substitution reaction of an intermediate In-A. which can be synthesized by any well-known method, with a primary or secondary amine.

The synthesis can be carried out by any well-known organic synthesis methods. Specifically, reaction is carried out by dissolving intermediate In-A in a polar aprotic solvent such as acetone, acetonitrile, dimethylformamide or dimethyl sulfoxide, and adding a primary or secondary amine to the solution. In the case of intermediate In-A wherein X^{hal} is chlorine or bromine, the reaction may be accelerated by adding a catalytic amount of an alkali metal iodide. Suitable alkali metal iodides include sodium iodide and potassium iodide. The reaction temperature is preferably from room temperature to nearly the boiling point of the solvent used. While it is desirable from the aspect of yield to monitor the reaction by gas chromatography (GC) or silica gel thin layer chromatography (TLC) until the reaction is complete, the reaction time is typically 30 minutes to 20 hours. The amine compound having formula (2) may be collected from the reaction mixture by standard aqueous work-up. If necessary, the amine compound is purified by a standard technique such as chromatography or recrystallization.

The above preparation method is merely exemplary and the method of preparing the amine compound is not limited thereto.

In the chemically amplified resist composition, the amount of the quencher (C) in the form of the amine compound having formula (2) blended is preferably 0.1 to 20 parts by weight, more preferably 0.5 to 15 parts by weight per 80 parts by weight of the polymer A. With the amount of quencher (C) in the range, sensitivity and resolution are good, and there is no risk of raising the problem of foreign particles after development or stripping of the resist film. The quencher (C) may be used alone or in admixture of two or more.

The chemically amplified resist composition of the invention is characterized by comprising (A) polymer A, (B) PAG, and (C) an amine compound having formula (2) This ensures to formulate a chemically amplified resist composition exhibiting a reduced value of LWR, improved CDU, and a high resolution. Though not well understood, the following reason is considered.

It is believed that the PAG as component (B) is characterized by a short distance of acid diffusion, has a least possibility to react with polymer A in the unexposed region and thus maintains satisfactory resolution performance. In the case of a compound of formula (1a) having a trifluoromethyl group in the vicinity of the sulfo group, the acid diffusion distance is shortened by this steric hindrance. In the case of a compound of formula (1b) having a betaine structure or highly polar structure, the acid diffusion is restricted by its interaction with the surrounding compounds.

Further, the chemically amplified resist composition is adapted to control acid diffusion to a full extent by using an amine compound of specific structure as component (C). Generally, when an amine compound is used as an acid diffusion controlling agent, the amine compound volatilizes in part during the bake step, failing to exert the desired performance. In contrast, the amine compound having formula (2) possesses a heterocyclic structural site such as a highly polar lactone, lactam, sultone or sultam structure. The highly polar heterocyclic structure serves to elevate the boiling point of the molecule, which prevents the amine compound from volatilization during the step of heating the resist composition after coating.

High-boiling amine compounds include amine compounds having a long-chain alkyl group and amine compounds having an aromatic group such as benzimidazole and 2,6-diisopropylaniline. Either of them, however, are difficultly soluble in alkaline developer. When such an amine compound is used in a positive tone resist composition adapted for alkaline development, for example, substantially insoluble sites are created in the exposed region, inviting a degradation of resolution. In contrast, the amine compound of formula (2) possesses a highly polar structure so that it has not only a high boiling point, but also a high solubility in alkaline developer, ensuring that the exposed region of resist film is dissolved away. A chemically amplified resist composition exhibiting a high resolution is thus provided. Inversely, the amine compound of formula (2) is substantially insoluble in organic solvents so that when used in a negative tone resist composition adapted for organic solvent development, the amine compound serves to accelerate insolubilization of exposed region. As a consequence, a high contrast and improved resolution are achieved without a loss of sensitivity as in the case of positive tone resist composition adapted for alkaline development. The quencher of onium salt type, for example, the quencher described in WO 2008/066011 volatilizes little during bake because of its salt structure, but is yet insufficient in resolution, as viewed from developer solubility.

Although JP-A 2012-008551 describes a resist composition comprising a photoacid generator of specific structure and an amine compound, the photoacid generator described therein does not possess a bulky substituent such as trifluoromethyl in the vicinity to the sulfo group, indicating least steric hindrance. This allows for a long distance of acid diffusion, failing to improve LWR or CDU.

It is thus believed that a chemically amplified resist composition having significantly improved LWR, CDU and resolution can be designed by combining polymer A with a PAG providing a short distance of acid diffusion and an amine compound having low volatility and high alkaline solubility.

### (D) Organic solvent

The resist composition may further comprise (D) an organic solvent. The organic solvent used herein is not particularly limited as long as the foregoing and other components are soluble therein. Suitable solvents are described in JP-A 2008-111103, paragraphs [0144]-[0145], for example, and include ketones such as cyclopentanone, cyclohexanone, and methyl-2-n-pentyl ketone; alcohols such as 3-methoxybutanol, 3-methyl-3-methoxybutanol, 1-methoxy-2-propanol, and 1-ethoxy-2-propanol: keto-alcohols such as diacetone alcohol (DAA); ethers such as propylene glycol monomethyl ether (PGME), ethylene glycol monomethyl ether, propylene glycol monoethyl ether, ethylene glycol monoethyl ether, propylene glycol dimethyl ether, and diethylene glycol dimethyl ether; esters such as propylene glycol monomethyl ether acetate (PGMEA), propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, and propylene glycol mono-tert-butyl ether acetate; and lactones such as γ-butyrolactone (GBL), and mixtures thereof. When acid labile groups of acetal type are used, high-boiling alcoholic solvents may be added for accelerating deprotection reaction of acetal, for example, diethylene glycol, propylene glycol, glycerin, 1,4-butanediol and 1,3-butanediol.

Of the foregoing organic solvents, it is recommended to use 1-ethoxy-2-propanol, PGMEA. cyclohexanone, GBL. DAA and mixtures thereof.

The organic solvent (D) is preferably added in an amount of 200 to 5,000 parts by weight, and more preferably 400 to 3,000 parts by weight per 80 parts by weight of the polymer A. The organic solvent may be used alone or in admixture.

### (E) Other quencher

The resist composition may further comprise (E) a quencher other than the amine compound having formula (2). Onium salts having the formulae (3-1) and (3-2) are useful as the other quencher (E).

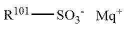

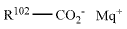

In formula (3-1). R¹⁰¹ is hydrogen or a C₁-C₄₀ hydrocarbyl group which may contain a heteroatom, exclusive of the hydrocarbyl group in which the hydrogen atom bonded to the carbon atom at α-position of the sulfo group is substituted by fluorine or fluoroalkyl.

The hydrocarbyl group R¹⁰¹ may be saturated or unsaturated and straight, branched or cyclic. Examples thereof include C₁-C₄₀ alkyl groups such as methyl, ethyl, propyl, isopropyl, n-butyl, sec-butyl, tert-butyl, n-pentyl, tert-pentyl, n-hexyl, n-octyl, 2-ethylhexyl, n-nonyl, and n-decyl; C₃-C₄₀ cyclic saturated hydrocarbyl groups such as cyclopentyl, cyclohexyl, cyclopentylmethyl, cyclopentylethyl, cyclopentylbutyl, cyclohexylmethyl, cyclohexylethyl, cyclohexylbutyl, norbomyl, oxanorbornyl, tricyclo[5.2.1.0^{2,6}]decanyl, and adamantyl; C₆-C₄₀ aryl groups such as phenyl, naphthyl and anthracenyl, and combinations thereof. In these hydrocarbyl groups, some or all hydrogen atoms may be substituted by a moiety containing a heteroatom such as oxygen, sulfur, nitrogen or halogen, or any constituent —CH₂— may be replaced by a moiety containing a heteroatom such as oxygen, sulfur or nitrogen, so that the group may contain a hydroxy, fluorine, chlorine, bromine, iodine, cyano, carbonyl, ether bond, ester bond, sulfonic ester bond, carbonate bond, lactone ring, sultone ring, carboxylic anhydride (~C(═O)—O—C(═O)~) or haloalkyl moiety.

In formula (3-2). R¹⁰² is hydrogen or a C₁-C₄₀ hydrocarbyl group which may contain a heteroatom. Examples of the hydrocarbyl group R¹⁰² include those exemplified above for R¹⁰¹ and fluoroalkyl groups such as trifluoromethyl and trifluoroethyl, and fluorinated aryl groups such as pentafluorophenyl and 4-trifluoromethylphenyl.

Examples of the anion in the onium salt having formula (3-1) are shown below, but not limited thereto.

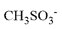

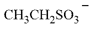

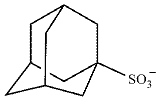

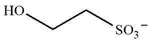

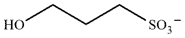

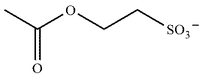

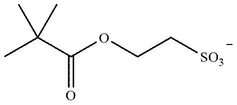

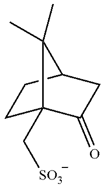

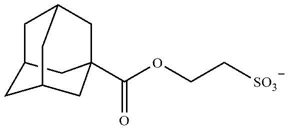

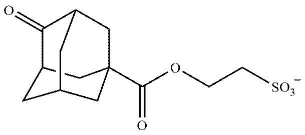

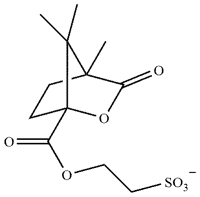

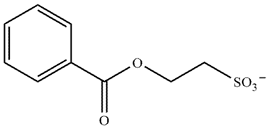

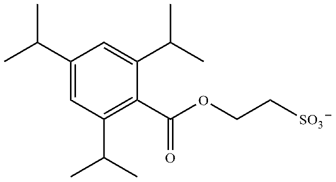

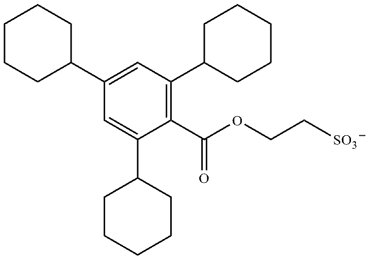

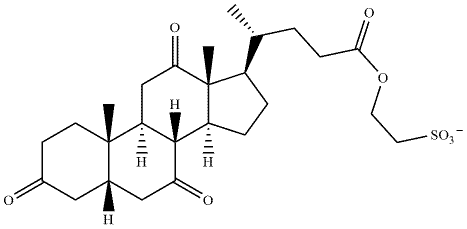

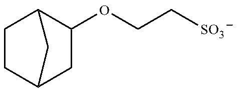

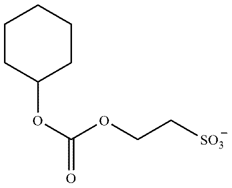

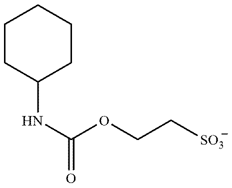

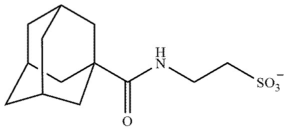

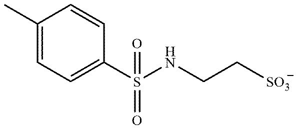

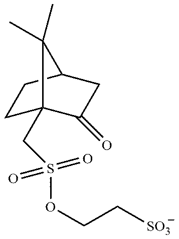

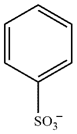

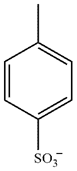

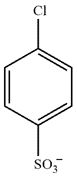

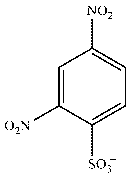

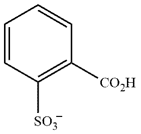

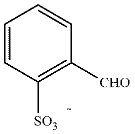

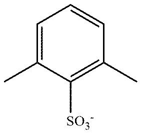

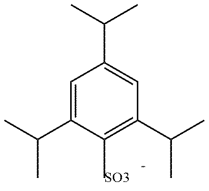

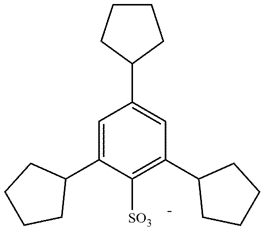

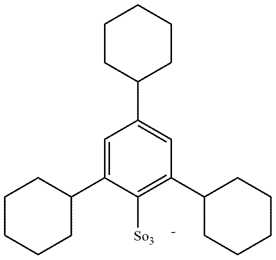

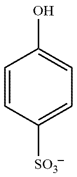

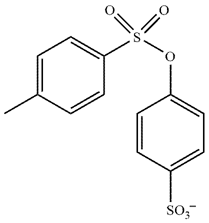

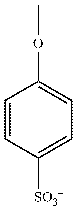

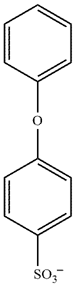

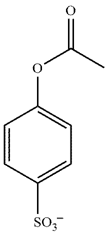

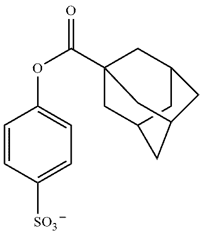

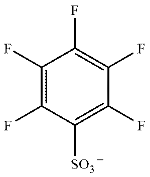

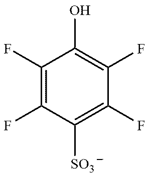

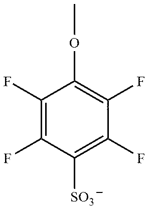

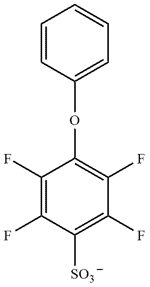

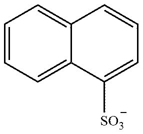

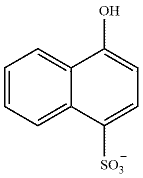

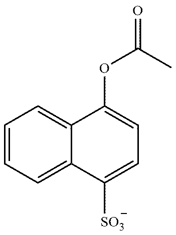

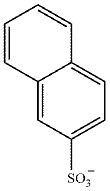

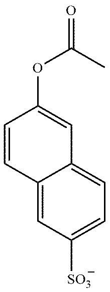

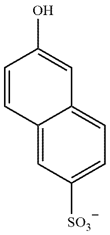

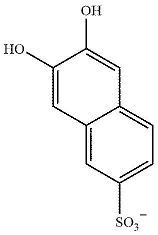

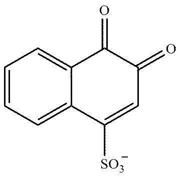

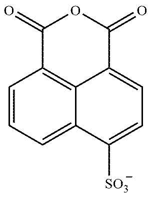

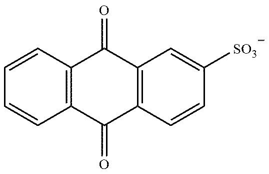

Examples of the anion in the onium salt having formula (3-2) are shown below, but not limited thereto.

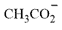

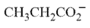

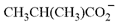

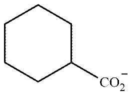

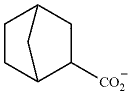

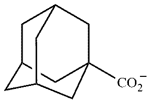

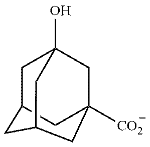

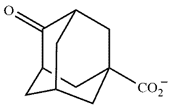

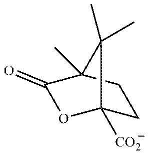

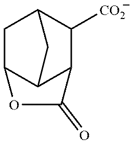

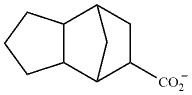

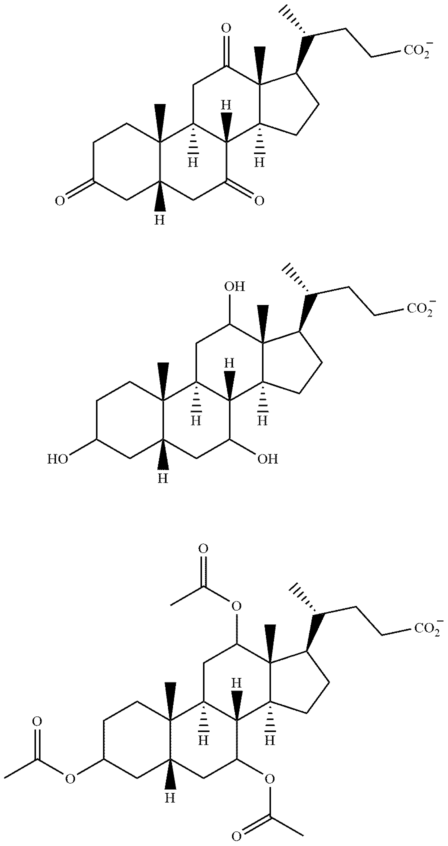

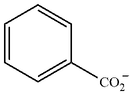

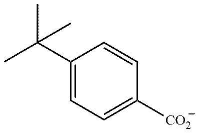

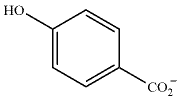

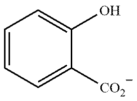

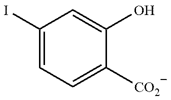

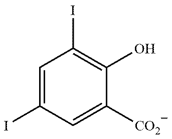

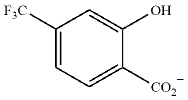

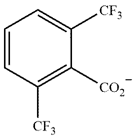

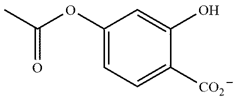

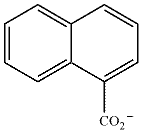

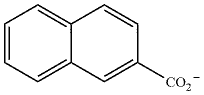

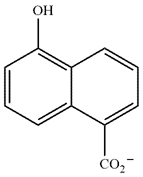

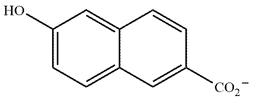

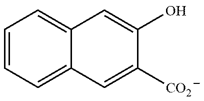

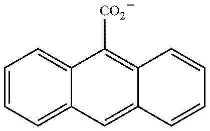

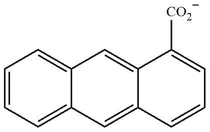

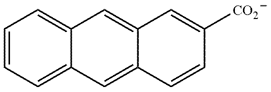

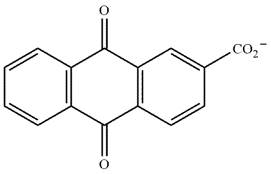

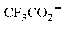

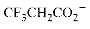

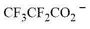

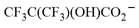

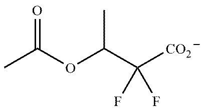

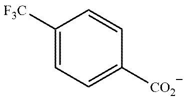

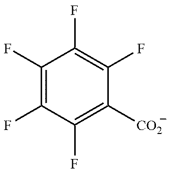

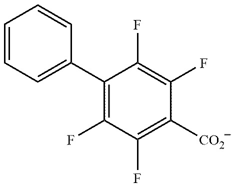

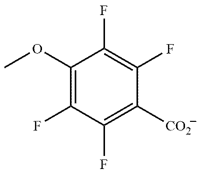

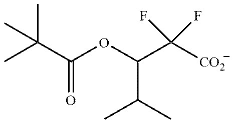

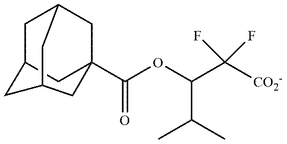

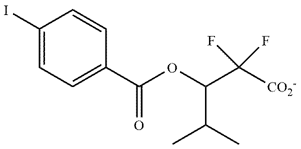

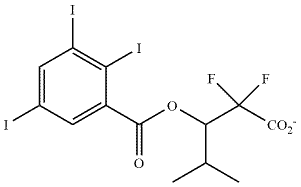

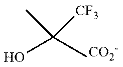

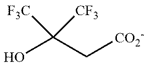

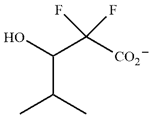

In formulae (3-1) and (3-2), Mq⁺ is an onium cation, which is preferably selected from cations having the formulae (3A), (3B) and (3C).

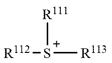

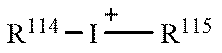

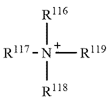

In formulae (3A) to (3C), R¹¹¹ to R¹¹⁹ are each independently a C₁-C₄₀ hydrocarbyl group which may contain a heteroatom. A pair of R¹¹¹ and R¹¹² may bond together to form a ring with the sulfur atom to which they are attached. A pair of R¹¹⁶ and R¹¹⁷ may bond together to form a ring with the nitrogen atom to which they are attached. Examples of the hydrocarbyl group are as exemplified above for the hydrocarbyl groups R^{Z1}. R^{Z2} and R^{Z3} in formula (Z1).

Examples of the onium cation represented by Mq⁺ are shown below, but not limited thereto.

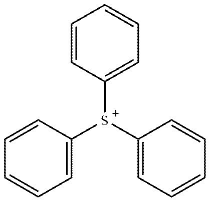 [SMILES: c1ccc([S+](c2ccccc2)c2ccccc2)cc1]

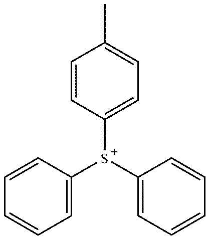 [SMILES: Cc1ccc([S+](c2ccccc2)c2ccccc2)cc1]

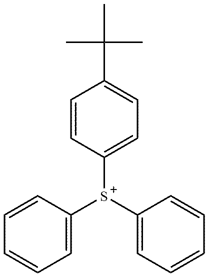 [SMILES: CC(C)(C)c1ccc([S+](c2ccccc2)c2ccccc2)cc1]

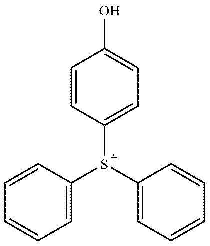 [SMILES: Oc1ccc([S+](c2ccccc2)c2ccccc2)cc1]

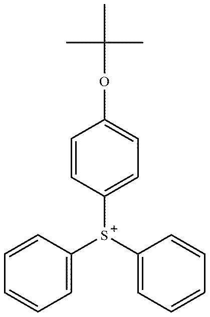 [SMILES: CC(C)(C)Oc1ccc([S+](c2ccccc2)c2ccccc2)cc1]

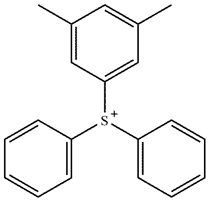 [SMILES: Cc1cc(C)cc([S+](c2ccccc2)c2ccccc2)c1]

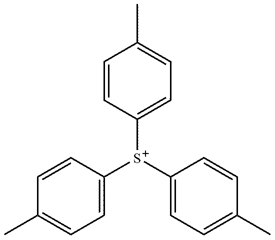

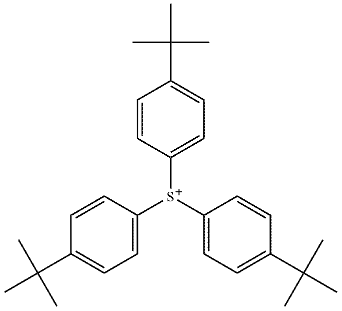 [SMILES: CC(C)(C)c1ccc([S+](c2ccc(C(C)(C)C)cc2)c2ccc(C(C)(C)C)cc2)cc1]

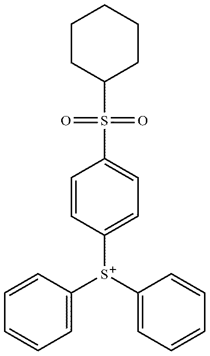 [SMILES: O=S(=O)(c1ccc([S+](c2ccccc2)c2ccccc2)cc1)C1CCCCC1]

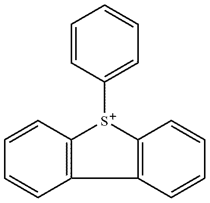 [SMILES: c1ccc(-[s+]2c3ccccc3c3ccccc32)cc1]

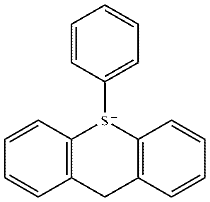 [SMILES: c1ccc([S-]2c3ccccc3Cc3ccccc32)cc1]

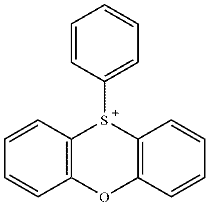 [SMILES: c1ccc([S+]2c3ccccc3Oc3ccccc32)cc1]

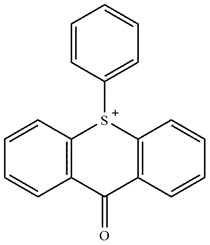 [SMILES: O=c1c2ccccc2[s+](-c2ccccc2)c2ccccc12]

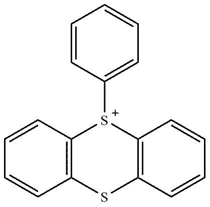 [SMILES: c1ccc([S+]2c3ccccc3Sc3ccccc32)cc1]

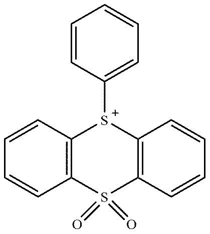 [SMILES: O=S1(=O)c2ccccc2[S+](c2ccccc2)c2ccccc21]

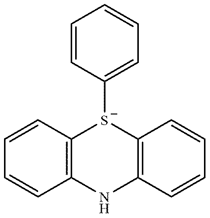 [SMILES: c1ccc([S-]2c3ccccc3Nc3ccccc32)cc1]

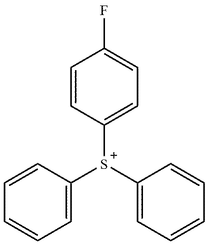 [SMILES: Fc1ccc([S+](c2ccccc2)c2ccccc2)cc1]

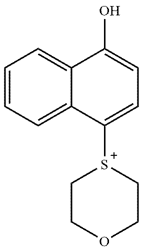 [SMILES: Oc1ccc([S+]2CCOCC2)c2ccccc12]

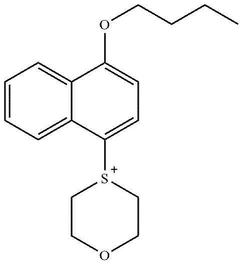 [SMILES: CCCCOc1ccc([S+]2CCOCC2)c2ccccc12]

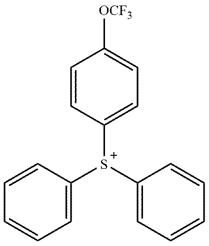 [SMILES: FC(F)(F)Oc1ccc([S+](c2ccccc2)c2ccccc2)cc1]

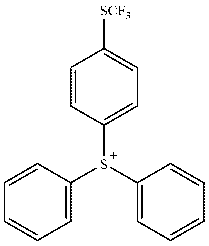

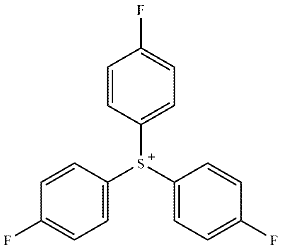 [SMILES: Fc1ccc([S+](c2ccc(F)cc2)c2ccc(F)cc2)cc1]

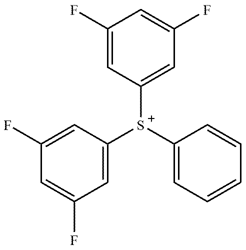 [SMILES: Fc1cc(F)cc([S+](c2ccccc2)c2cc(F)cc(F)c2)c1]

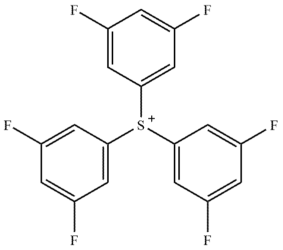 [SMILES: Fc1cc(F)cc([S+](c2cc(F)cc(F)c2)c2cc(F)cc(F)c2)c1]

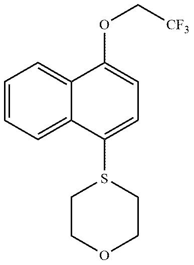

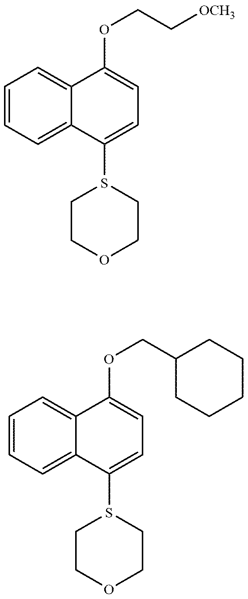

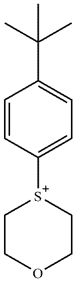 [SMILES: CC(C)(C)c1ccc([S+]2CCOCC2)cc1]

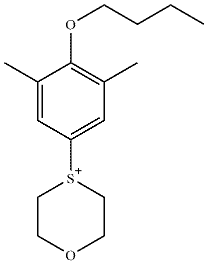 [SMILES: CCCCOc1c(C)cc([S+]2CCOCC2)cc1C]

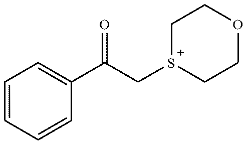 [SMILES: O=C(C[S+]1CCOCC1)c1ccccc1]

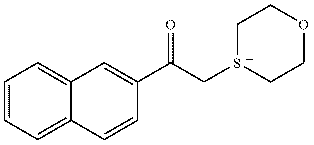 [SMILES: O=C(C[S-]1CCOCC1)c1ccc2ccccc2c1]

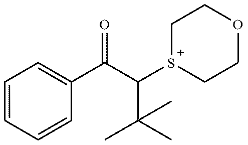 [SMILES: CC(C)(C)C(C(=O)c1ccccc1)[S+]1CCOCC1]

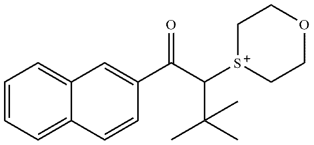 [SMILES: CC(C)(C)C(C(=O)c1ccc2ccccc2c1)[S+]1CCOCC1]

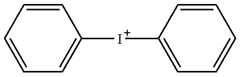 [SMILES: c1ccc([I+]c2ccccc2)cc1]

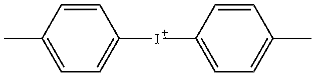

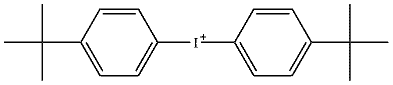 [SMILES: CC(C)(C)c1ccc([I+]c2ccc(C(C)(C)C)cc2)cc1]

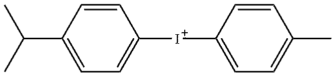 [SMILES: Cc1ccc([I+]c2ccc(C(C)C)cc2)cc1]

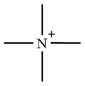

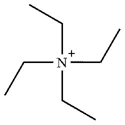

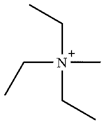

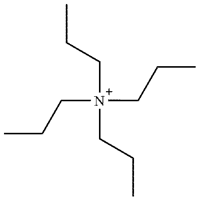

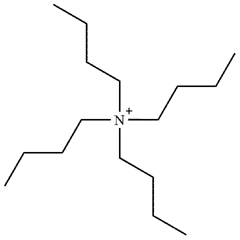 [SMILES: CCCC[N+](CCCC)(CCCC)CCCC]

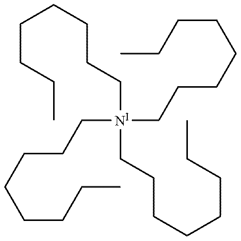

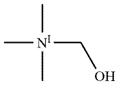

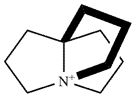

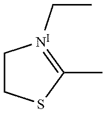

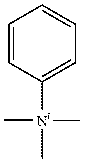

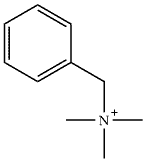

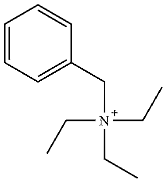

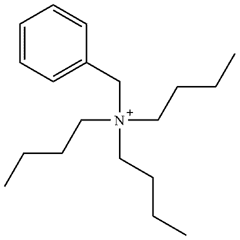 [SMILES: CCCC[N+](CCCC)(CCCC)Cc1ccccc1]

Examples of the onium salt having formula (3-1) or (3-2) include arbitrary combinations of anions with cations, both as exemplified above. These onium salts may be readily prepared by ion exchange reaction using any well-known organic chemistry technique. For the ion exchange reaction, reference may be made to JP-A 2007-145797, for example.

The onium salt having formula (3-1) or (3-2) functions as a quencher in the chemically amplified resist composition because the counter anion of the onium salt is a conjugated base of a weak acid. As used herein, the weak acid indicates an acidity insufficient to deprotect an acid labile group from an acid labile group-containing unit in the base polymer. The onium salt having formula (3-1) or (3-2) functions as a quencher when used in combination with an onium salt type PAG having a conjugated base of a strong acid (typically a sulfonic acid which is fluorinated at α-position) as the counter anion. In a system using a mixture of an onium salt capable of generating a strong acid (e.g., α-position fluorinated sulfonic acid) and an onium salt capable of generating a weak acid (e.g., non-fluorinated sulfonic acid or carboxylic acid), if the strong acid generated from the PAG upon exposure to high-energy radiation collides with the unreacted onium salt having a weak acid anion, then a salt exchange occurs whereby the weak acid is released and an onium salt having a strong acid anion is formed. In this course, the strong acid is exchanged into the weak acid having a low catalysis, incurring apparent deactivation of the acid for enabling to control acid diffusion.

If a PAG capable of generating a strong acid is an onium salt, an exchange from the strong acid generated upon exposure to high-energy radiation to a weak acid as above can take place, but it rarely happens that the weak acid generated upon exposure to high-energy radiation collides with the unreacted onium salt capable of generating a strong acid to induce a salt exchange. This is because of a likelihood of an onium cation forming an ion pair with a stronger acid anion.

When the onium salt having formula (3-1) or (3-2) is used as the other quencher (E), the amount of the onium salt used is preferably 0.1 to 10 parts by weight, more preferably 0.1 to 5 parts by weight per 80 parts by weight of the polymer A. The onium salt having formula (3-1) or (3-2) may be used alone or in admixture.

### (F) Surfactant

The resist composition may further include (F) a surfactant. It may be either a surfactant which is insoluble or substantially insoluble in water and soluble in alkaline developer, or a surfactant which is insoluble or substantially insoluble in water and alkaline developer. For the surfactant, reference should be made to those compounds described in JP-A 2010-215608 and JP-A 2011-016746.

While many examples of the surfactant which is insoluble or substantially insoluble in water and alkaline developer are described in the patent documents cited herein, preferred examples are surfactants FC-4430 (3 M), Olfine® E1004 (Nissin Chemical Co., Ltd.), Surflon® S-381, KH-20 and KH-30 (AGC Seimi Chemical Co., Ltd.). Partially fluorinated oxetane ring-opened polymers having the formula (surf-1) are also useful.

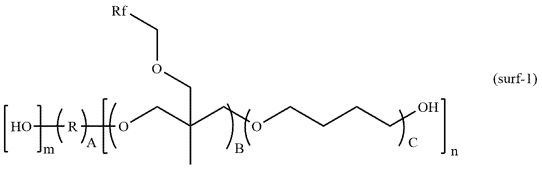

It is provided herein that R, Rf. A, B. C. m, and n are applied to only formula (surf-1), independent of their descriptions other than for the surfactant. R is a di- to tetra-valent C₂-C₅ aliphatic group. Exemplary divalent aliphatic groups include ethylene, 1,4-butylene, 1,2-propylene, 2.2-dimethyl-1,3-propylene and 1,5-pentylene. Exemplary tri- and tetra-valent groups are shown below.

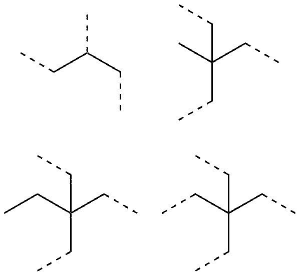

Herein the broken line denotes a valence bond. These formulae are partial structures derived from glycerol, trimethylol ethane, trimethylol propane, and pentaerythritol, respectively. Of these, 1,4-butylene and 2,2-dimethyl-1,3-propylene are preferably used.

Rf is trifluoromethyl or pentafluoroethyl, and preferably trifluoromethyl. The letter m is an integer of 0 to 3, n is an integer of 1 to 4, and the sum of m and n. which represents the valence of R, is an integer of 2 to 4. “A” is equal to 1, B is an integer of 2 to 25, and C is an integer of 0 to 10. Preferably, B is an integer of 4 to 20, and C is 0 or 1. Note that the formula (surf-1) does not prescribe the arrangement of respective constituent units while they may be arranged either blockwise or randomly. For the preparation of surfactants in the form of partially fluorinated oxetane ring-opened polymers, reference should be made to USP 5,650.483, for example.

The surfactant which is insoluble or substantially insoluble in water and soluble in alkaline developer is useful when ArF immersion lithography is applied to the resist composition in the absence of a resist protective film. In this embodiment, the surfactant has a propensity to segregate on the resist surface for achieving a function of minimizing water penetration or leaching. The surfactant is also effective for preventing water-soluble components from being leached out of the resist film for minimizing any damage to the exposure tool. The surfactant becomes solubilized during alkaline development following exposure and PEB. and thus forms few or no foreign particles which become defects. The preferred surfactant is a polymeric surfactant which is insoluble or substantially insoluble in water, but soluble in alkaline developer, also referred to as “hydrophobic resin” in this sense, and especially which is water repellent and enhances water sliding.

Suitable polymeric surfactants include those containing repeat units of at least one type selected from the formulae (4A) to (4E).

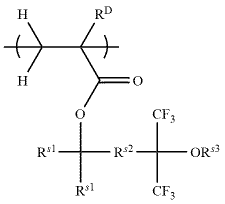

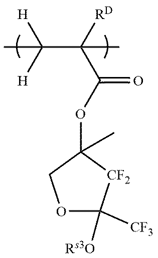

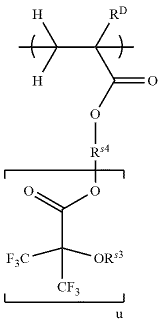

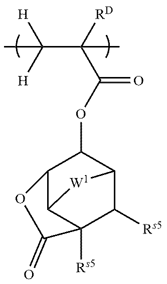

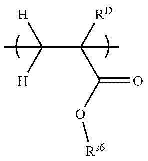

In formulae (4A) to (4E), R^{D} is hydrogen, fluorine, methyl or trifluoromethyl. W¹ is —CH₂—, —CH₂CH₂— or —O—, or two separate —H. R^{s1} is each independently hydrogen or a C₁-C₁₀ hydrocarbyl group. R^{s2} is a single bond or a C₁-C₅ straight or branched hydrocarbylene group. R^{s3} is each independently hydrogen, a C₁-C₁₅ hydrocarbyl or fluorinated hydrocarbyl group, or an acid labile group. When R^{s3} is a hydrocarbyl or fluorinated hydrocarbyl group, an ether bond or carbonyl moiety may intervene in a carbon-carbon bond. R^{s4} is a C₁-C₂₀ (u+1)-valent hydrocarbon or fluorinated hydrocarbon group, and u is an integer of 1 to 3. R^{s5} is each independently hydrogen or a group: —C(═O)—O—R^{s7} wherein R^{s7} is a C₁-C₂₀ fluorinated hydrocarbyl group. R^{s6} is a C₁-C₁₅ hydrocarbyl or fluorinated hydrocarbyl group in which an ether bond or carbonyl moiety may intervene in a carbon-carbon bond.

The hydrocarbyl group represented by R^{s1} may be straight, branched or cyclic. Examples thereof include methyl, ethyl, n-propyl, isopropyl, cyclopropyl, n-butyl, isobutyl, sec-butyl, tert-butyl, cyclobutyl, n-pentyl, cyclopentyl, n-hexyl, cyclohexyl, n-heptyl, n-octyl, n-nonyl, n-decyl, adamantyl, and norbornyl. Inter alia, C₁-C₆ hydrocarbyl groups are preferred.

The hydrocarbylene group represented by R^{s2} may be straight, branched or cyclic. Examples thereof include methylene, ethylene, propylene, butylene and pentylene.

The hydrocarbyl group represented by R^{s3} or R^{s6} may be straight, branched or cyclic. Examples thereof include alkyl, alkenyl and alkynyl groups, with the alkyl groups being preferred. Suitable alkyl groups include those exemplified for the hydrocarbyl group represented by R^{s1} as well as n-undecyl, n-dodecyl, tridecyl, tetradecyl, and pentadecyl. Examples of the fluorinated hydrocarbyl group represented by R^{s3} or R^{s6} include the foregoing hydrocarbyl groups in which some or all carbon-bonded hydrogen atoms are substituted by fluorine atoms. In these groups, an ether bond or carbonyl moiety may intervene in a carbon-carbon bond as mentioned above.

Examples of the acid labile group represented by R^{s3} include groups of the above formulae (L1) to (L4), C₄-C₂₀, preferably C₄-C₁₅ tertiary hydrocarbyl groups, trialkylsilyl groups in which each alkyl moiety has 1 to 6 carbon atoms, and C₄-C₂₀ oxoalkyl groups.

The (u+1)-valent hydrocarbon or fluorinated hydrocarbon group represented by R^{s4} may be straight, branched or cyclic and examples thereof include the foregoing hydrocarbyl or fluorinated hydrocarbyl groups from which the number (u) of hydrogen atoms are eliminated.

The fluorinated hydrocarbyl group represented by R^{s7} may be straight, branched or cyclic. Examples thereof include the foregoing hydrocarbyl groups in which some or all hydrogen atoms are substituted by fluorine atoms. Illustrative examples include trifluoromethyl, 2,2,2-trifluoroethyl, 3,3,3-trifluoro-1-propyl, 3,3,3-trifluoro-2-propyl, 2,2,3,3-tetrafluoropropyl, 1,1,1,3,3,3-hexafluoroisopropyl, 2,2,3,3,4,4,4-heptafluorobutyl, 2,2,3,3,4,4,5,5-octafluoropentyl, 2,2,3,3,4,4,5,5,6,6,7,7-dodecafluoroheptyl, 2-(perfluorobutyl)ethyl. 2-(perfluorohexyl)ethyl, 2-(perfluorooctyl)ethyl, and 2-(perfluorodecyl)ethyl.

Examples of the repeat units having formulae (4A) to (4E) are shown below, but not limited thereto. Herein R^{D} is as defined above.

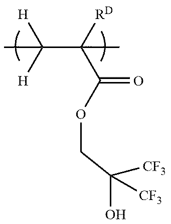

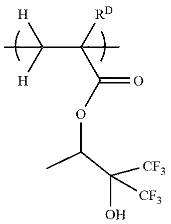

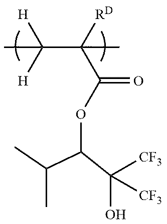

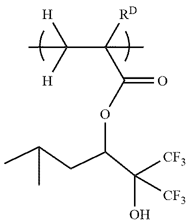

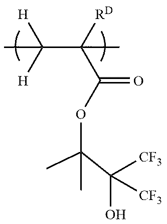

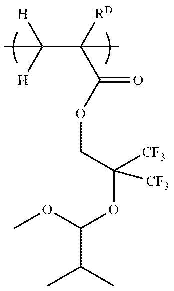

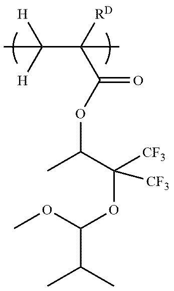

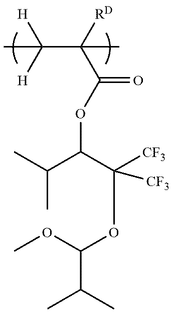

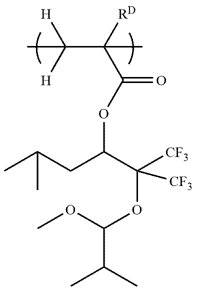

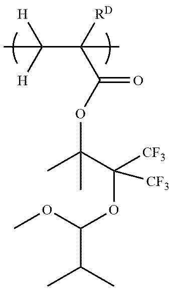

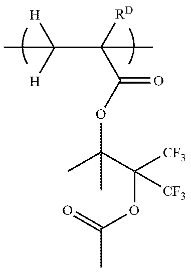

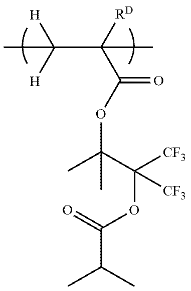

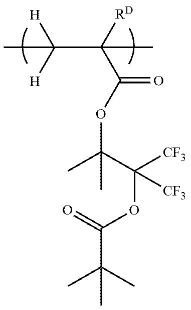

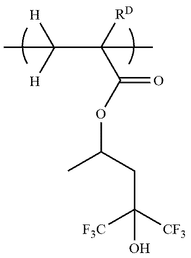

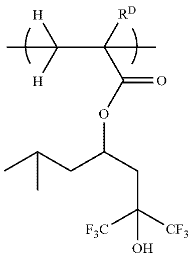

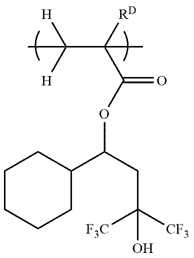

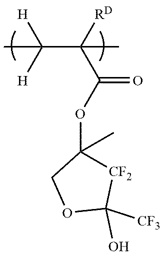

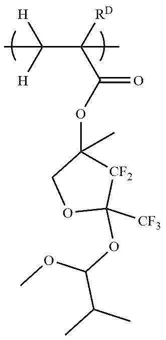

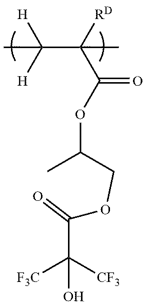

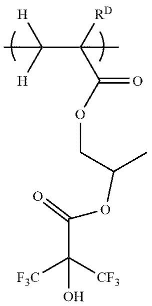

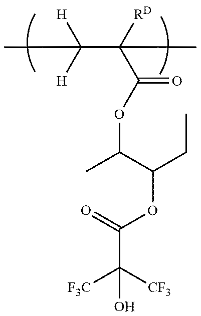

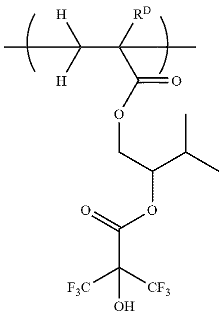

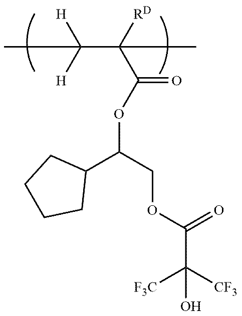

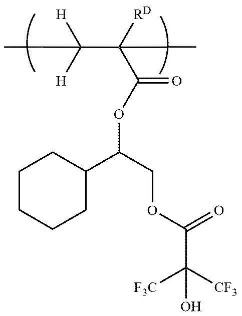

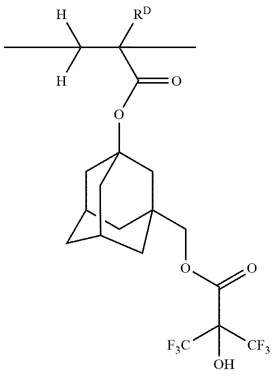

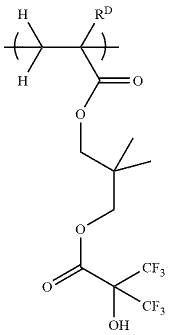

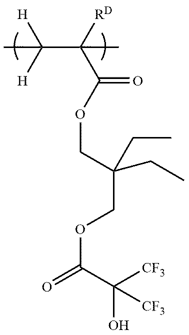

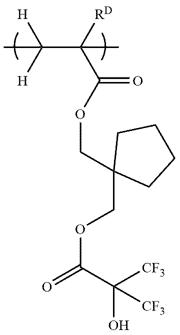

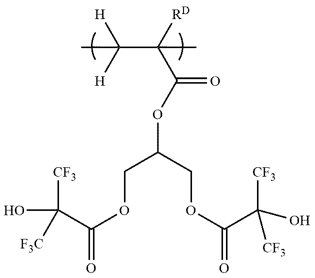

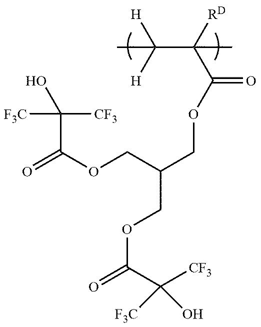

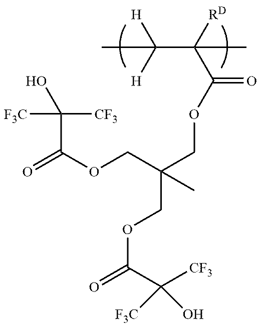

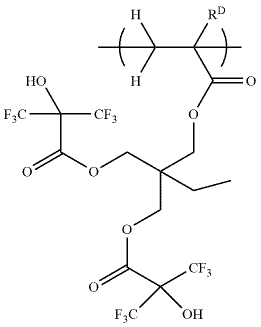

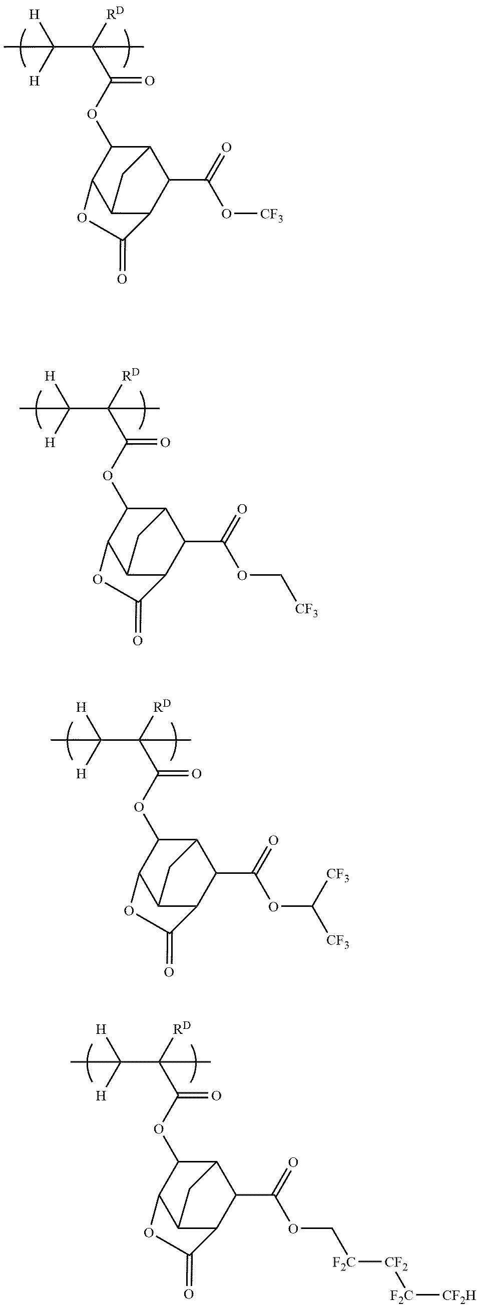

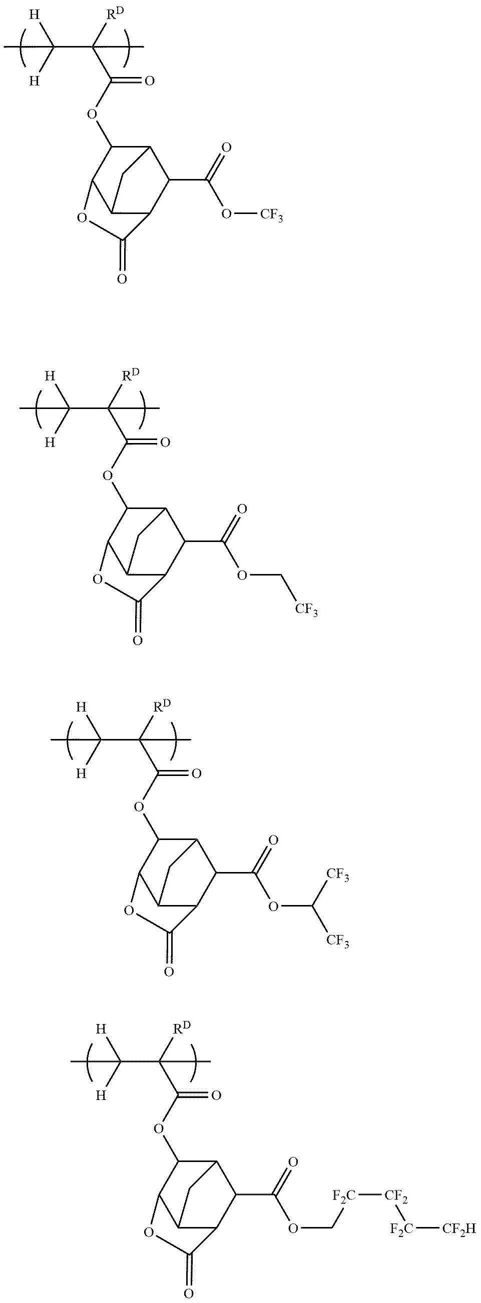

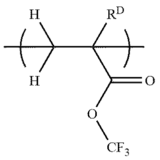

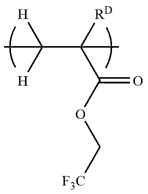

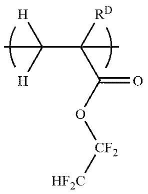

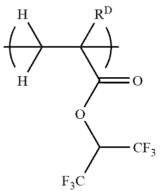

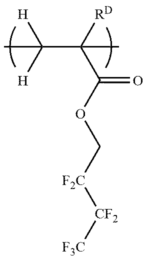

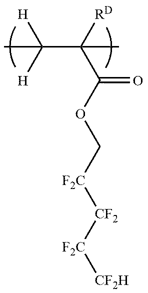

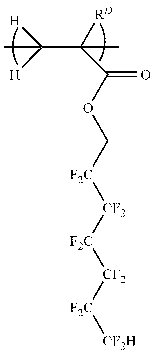

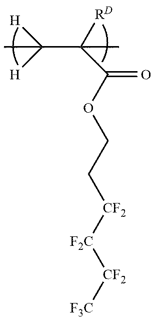

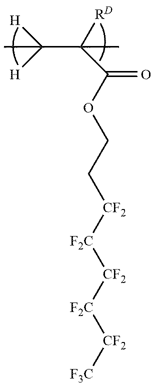

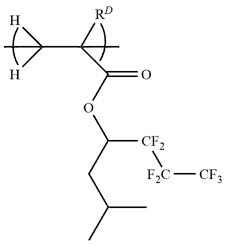

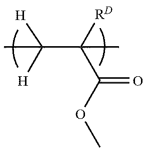

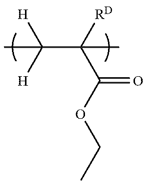

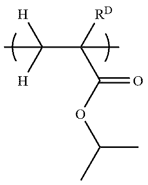

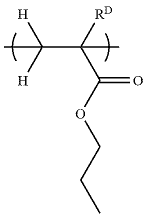

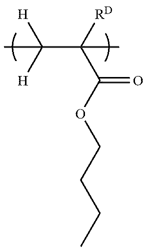

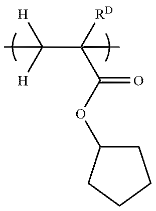

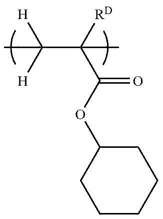

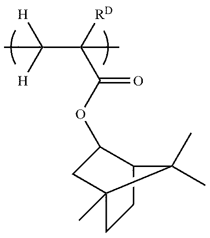

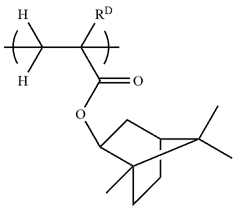

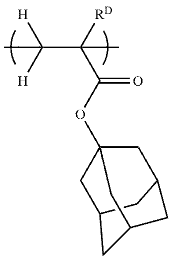

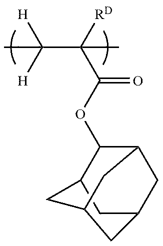

The polymeric surfactant may further contain repeat units other than the repeat units having formulae (4A) to (4E). Typical other repeat units are those derived from methacrylic acid and α-trifluoromethylacrylic acid derivatives. In the polymeric surfactant, the content of the repeat units having formulae (4A) to (4E) is preferably at least 20 mol%, more preferably at least 60 mol%, most preferably 100 mol% of the overall repeat units.

The polymeric surfactant preferably has a Mw of 1,000 to 500,000, more preferably 3,000 to 100,000 and a Mw/Mn of 1.0 to 2.0, more preferably 1.0 to 1.6.

The polymeric surfactant may be synthesized by any desired method, for example, by dissolving an unsaturated bond-containing monomer or monomers providing repeat units having formula (4A) to (4E) and optionally other repeat units in an organic solvent, adding a radical initiator, and heating for polymerization. Suitable organic solvents used herein include toluene, benzene, THF, diethyl ether, and dioxane. Examples of the polymerization initiator used herein include AIBN, 2,2′-azobis(2,4-dimethylvaleronitrile), dimethyl 2.2-azobis(2-methylpropionate), benzoyl peroxide, and lauroyl peroxide. Preferably the reaction temperature is 50 to 100° C. and the reaction time is 4 to 24 hours. The acid labile group that has been incorporated in the monomer may be kept as such, or the polymer may be protected or partially protected therewith at the end of polymerization.

During the synthesis of polymeric surfactant, any known chain transfer agent such as dodecyl mercaptan or 2-mercaptoethanol may be added for molecular weight control purpose. The amount of chain transfer agent added is preferably 0.01 to 10 mol% based on the total moles of monomers to be polymerized.

When the resist composition contains a surfactant (F), the amount thereof is preferably 0.1 to 50 parts by weight, and more preferably 0.5 to 10 parts by weight per 80 parts by weight of the polymer A. At least 0.1 part of the surfactant is effective in improving the receding contact angle with water of the resist film at its surface. Up to 50 parts of the surfactant is effective in forming a resist film having a low rate of dissolution in a developer and capable of maintaining the height of a fine pattern formed therein. The surfactant may be used alone or in admixture.

### Process

Another embodiment of the invention is a process of forming a pattern from the resist composition defined above by lithography. The preferred process includes the steps of applying the resist composition to form a resist film on a substrate, exposing the resist film to KrF excimer laser, ArF excimer laser, EB or EUV, and developing the exposed resist film in a developer. Any desired steps may be added to the process if necessary.

The substrate used herein may be a substrate for integrated circuitry fabrication, e.g., Si, SiO2, SiN, SiON, TiN, WSi, BPSG, SOG. organic antireflective film, etc. or a substrate for mask circuitry fabrication, e.g., Cr, CrO, CrON, MoSi₂, SiO₂, etc.

The resist composition is applied onto a substrate by a suitable coating technique such as spin coating. The coating is prebaked on a hot plate preferably at a temperature of 60 to 150° C. for 1 to 10 minutes, more preferably at 80 to 140° C. for 1 to 5 minutes. The resulting resist film preferably has a thickness of 0.05 to 2 µm.

Then the resist film is exposed patternwise to KrF or ArF excimer laser. EUV or EB. On use of KrF excimer laser, ArF excimer laser or EUV of wavelength 13.5 nm, the resist film is exposed through a mask having a desired pattern, preferably in a dose of 1 to 200 mJ/cm2, more preferably 10 to 100 mJ/cm2, On use of EB, a pattern may be written directly or through a mask having the desired pattern, preferably in a dose of 1 to 300 µC/cm2, more preferably 10 to 200 µC/cm².

The exposure may be performed by conventional lithography whereas the immersion lithography of holding a liquid having a refractive index of at least 1.0 between the resist film and the projection lens may be employed if desired. The liquid is typically water, and in this case, a protective film which is insoluble in water may be formed on the resist film.

While the water-insoluble protective film serves to prevent any components from being leached out of the resist film and to improve water sliding on the film surface, it is generally divided into two types. The first type is an organic solvent-strippable protective film which must be stripped, prior to alkaline development, with an organic solvent in which the resist film is not dissolvable. The second type is an alkali-soluble protective film which is soluble in an alkaline developer so that it can be removed simultaneously with the removal of solubilized regions of the resist film. The protective film of the second type is preferably of a material comprising a polymer having a 1,1,1,3,3,3-hexafluoro-2-propanol residue (which is insoluble in water and soluble in an alkaline developer) as a base in an alcohol solvent of at least 4 carbon atoms, an ether solvent of 8 to 12 carbon atoms or a mixture thereof. Alternatively, the aforementioned surfactant which is insoluble in water and soluble in an alkaline developer may be dissolved in an alcohol solvent of at least 4 carbon atoms, an ether solvent of 8 to 12 carbon atoms or a mixture thereof to form a material from which the protective film of the second type is formed.

After the exposure, the resist film may be baked (PEB), for example, on a hotplate at 60 to 150° C. for 1 to 5 minutes, preferably at 80 to 140° C. for 1 to 3 minutes.

The resist film is then developed with a developer in the form of an aqueous base solution, for example, 0.1 to 5 wt%, preferably 2 to 3 wt% aqueous solution of tetramethylammonium hydroxide (TMAH) for 0.1 to 3 minutes, preferably 0.5 to 2 minutes by conventional techniques such as dip, puddle and spray techniques. In the development step, the exposed region of resist film is dissolved away, and a desired resist pattern is formed on the substrate.

Any desired step may be added to the pattern forming process. For example, after the resist film is formed, a step of rinsing with pure water (post-soaking) may be introduced to extract the acid generator or the like from the film surface or wash away particles. After exposure, a step of rinsing (post-soaking) may be introduced to remove any water remaining on the film after exposure.

Also, a double patterning process may be used for pattern formation. The double patterning process includes a trench process of processing an underlay to a 1:3 trench pattern by a first step of exposure and etching, shifting the position, and forming a 1:3 trench pattern by a second step of exposure, for forming a 1:1 pattern: and a line process of processing a first underlay to a 1:3 isolated left pattern by a first step of exposure and etching, shifting the position, processing a second underlay formed below the first underlay by a second step of exposure through the 1:3 isolated left pattern, for forming a half-pitch 1:1 pattern.

In the pattern forming process, negative tone development may also be used. That is, an organic solvent may be used instead of the aqueous alkaline solution as the developer for developing and dissolving away the unexposed region of the resist film.

The organic solvent used as the developer is preferably selected from 2-octanone, 2-nonanone, 2-heptanone, 3-heptanone, 4-heptanone, 2-hexanone. 3-hexanone, diisobutyl ketone, methylcyclohexanone, acetophenone, methylacetophenone, propyl acetate, butyl acetate, isobutyl acetate, pentyl acetate, isopentyl acetate, butenyl acetate, propyl formate, butyl formate, isobutyl formate, pentyl formate, isopentyl formate, methyl valerate, methyl pentenoate, methyl crotonate, ethyl crotonate, methyl propionate, ethyl propionate, ethyl 3-ethoxypropionate, methyl lactate, ethyl lactate, propyl lactate, butyl lactate, isobutyl lactate, pentyl lactate, isopentyl lactate, methyl 2-hydroxyisobutyrate, ethyl 2-hydroxyisobutyrate, methyl benzoate, ethyl benzoate, phenyl acetate, benzyl acetate, methyl phenyl acetate, benzyl formate, phenylethyl formate, methyl 3-phenylpropionate, benzyl propionate, ethyl phenylacetate, and 2-phenylethyl acetate. These organic solvents may be used alone or in admixture of two or more.

### EXAMPLES

Synthesis Examples, Examples and Comparative Examples are given below by way of illustration and not by way of limitation. The abbreviation “pbw” is parts by weight. For all polymers, Mw and Mn are determined by GPC versus polystyrene standards using THF solvent. THF stands for tetrahydrofuran, and PGMEA for propylene glycol monomethyl ether acetate. Analysis is made by IR and ¹H-NMR spectroscopy using analytic instruments as shown below.
IR: NICOLET 6700 by Thermo Fisher Scientific Inc.
¹H-NMR: ECA-500 by JEOL Ltd.

### Synthesis of Amine Compounds

### Synthesis Example 1-1

### Synthesis of Q-1

Synthesis of Intermediate In-1

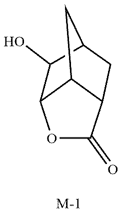 [SMILES: O=C1OC2C(O)C3CC1C2C3 ; "M-1"]

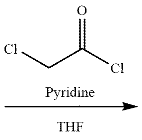

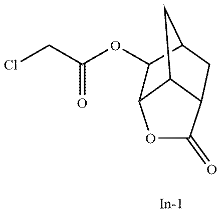

In a reactor under nitrogen atmosphere, 61.7 g of reactant M-1 and 54.2 g of chloroacetyl chloride were dissolved in 400 g of THF. The reactor was cooled below 10° C., to which a solution of 37.3 g of pyridine in 40 g of THF was added dropwise. At the end of addition, the reaction system was aged at an internal temperature of 20° C. for 12 hours. At the end of aging, the reaction system was cooled, to which 440 g of saturated sodium bicarbonate aqueous solution was added dropwise to quench the reaction. Thereafter, 880 g of diisopropyl ether was added for crystallization. The crystal precipitate was collected by filtration and dried in vacuum, obtaining Intermediate In-1 as white crystals (amount 91.1 g, yield 99%).

Synthesis of Q-1

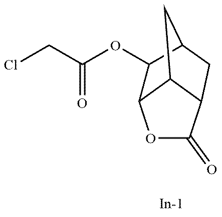

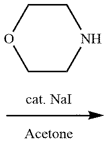

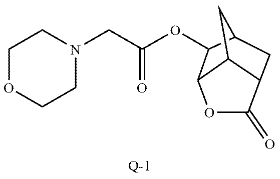 [SMILES: O=C(CN1CCOCC1)OC1C2CC3C(=O)OC1C3C2 ; "Q-1"]

In nitrogen atmosphere, a reactor was charged with 91.1 g of Intermediate In-1, 6.0 g of sodium iodide, and 320 g of acetone. At room temperature, 41.8 g of morpholine was added dropwise thereto. At the end of addition, the reaction system was aged for 24 hours while heating under reflux. After the disappearance of intermediate In-1 was confirmed by TLC. the reaction solution was cooled down to room temperature, to which 160 g of saturated sodium bicarbonate aqueous solution was added to quench the reaction. Using an evaporator, the acetone was distilled off. After distillation. 480 g of methylene chloride was added for extracting the desired compound, followed by separatory operation. The organic layer was washed 4 times with 160 g of water and once with 160 g of saturated brine. The organic layer was separated and concentrated. The residue was purified through a silica gel column, obtaining Q-1 as oily matter (amount 91.3 g. yield 71%).

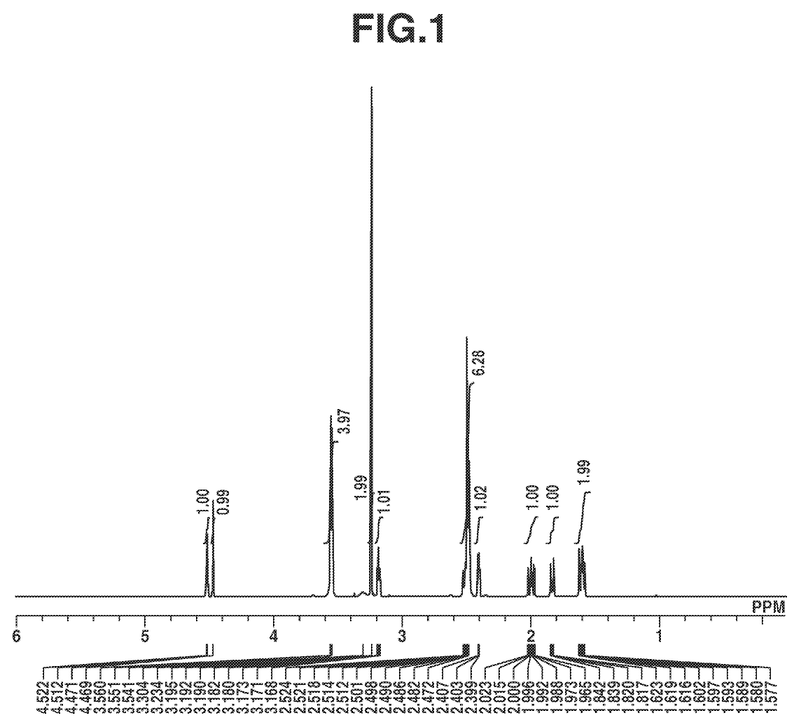

Q-1 was analyzed by IR spectroscopy, with the data shown below. FIG. 1 is the ¹H-NMR/DMSO-d₆ spectrum of Q-1.

IR (D-ATR): v = 2988, 2973, 2941, 2892, 2863, 2800, 2694, 1781, 1743, 1451, 1412, 1402, 1360, 1339, 1301, 1292, 1277, 1240, 1208, 1196, 1183, 1169, 1121, 1101, 1070, 1041, 1020, 1009, 994, 959, 905. 891, 867, 837, 809, 789. 737, 715. 643, 589, 549, 484, 436 cm⁻¹

### Synthesis Example 1-2

Synthesis of Q-2

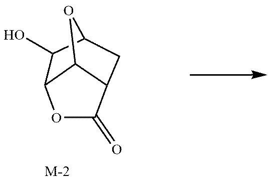 [SMILES: O=C1OC2C(O)C3CC1C2O3 ; "M-2"]

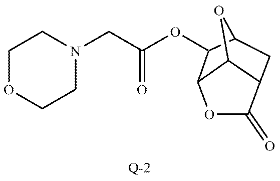 [SMILES: O=C(CN1CCOCC1)OC1C2CC3C(=O)OC1C3O2 ; "Q-2"]

Q-2 was synthesized by the same procedure as in Synthesis Example 1-1 aside from using reactant M-2 instead of reactant M-1. (amount 11.9 g, yield 70%).

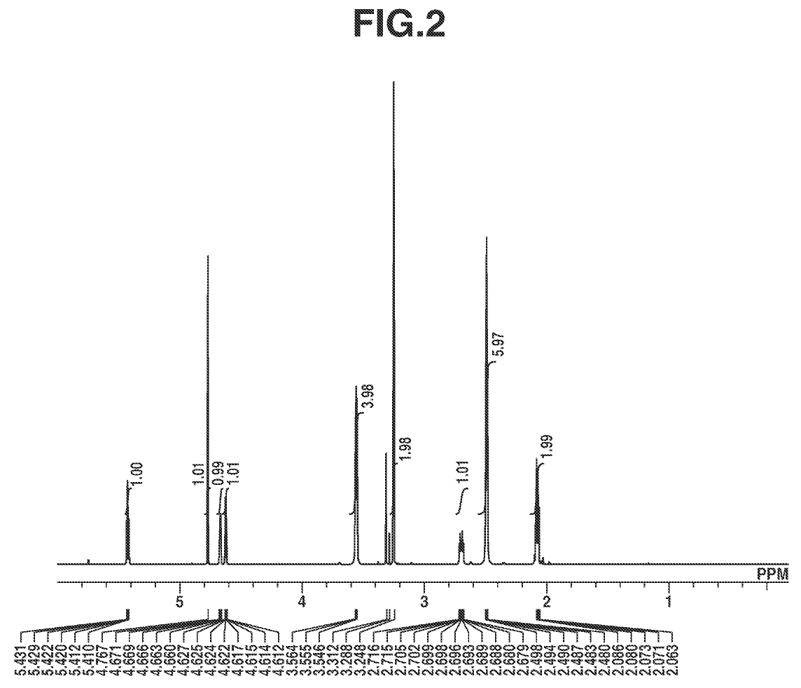

Q-2 was analyzed by IR spectroscopy, with the data shown below. FIG. 2 is the ¹H-NMR/DMSO-d₆, spectrum of Q-2.

IR (D-ATR): v = 3029, 2980, 2935, 2907, 2860, 2843, 2751, 2684, 1786, 1745, 1460, 1445, 1413, 1375, 1360, 1339, 1328, 1320, 1296, 1278, 1244, 1234, 1191, 1180, 1159, 1146, 1112, 1071, 1045, 1037, 1026, 990, 963, 935, 905, 898, 873, 862, 855, 807. 740, 704, 651, 639. 584, 522, 446, 438 cm⁻¹

### Synthesis Example 1-3

Synthesis of Q-3

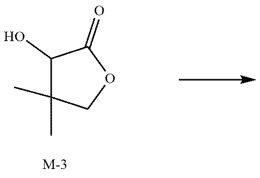

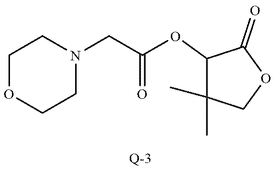 [SMILES: CC1(C)COC(=O)C1OC(=O)CN1CCOCC1 ; "Q-3"]

Q-3 was synthesized by the same procedure as in Synthesis Example 1-1 aside from using reactant M-3 instead of reactant M-1. (amount 23.3 g. yield 90%).

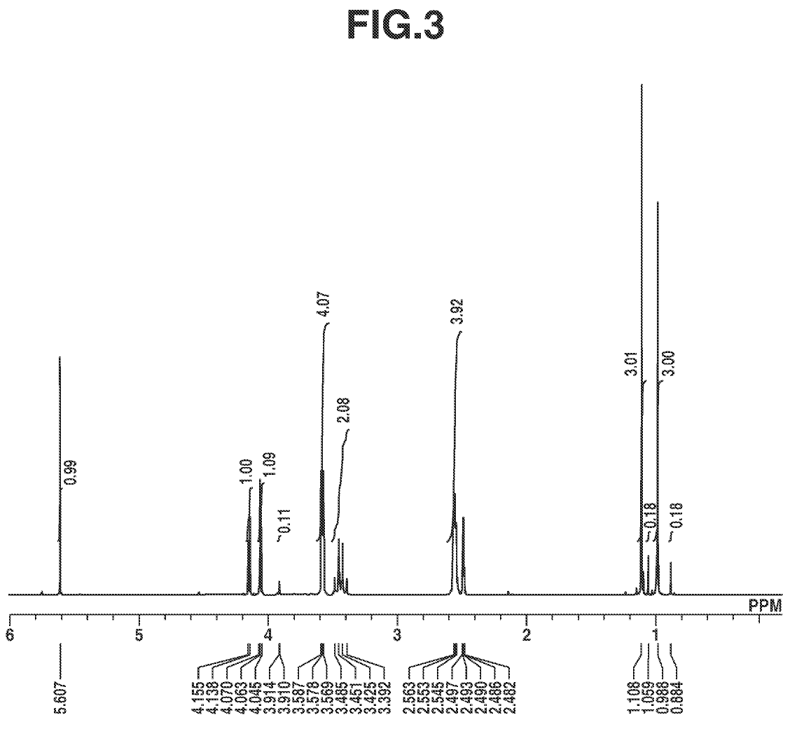

Q-3 was analyzed by IR spectroscopy, with the data shown below. FIG. 3 is the ¹H-NMR/DMSO-d₆ spectrum of Q-3.

IR (D-ATR): v = 2967, 2932, 2854, 2696, 2432, 1789, 1775, 1765, 1642, 1453, 1426, 1404, 1375, 1333. 1300, 1279, 1230, 1205, 1181, 1162, 1116, 1073, 1036, 1013, 999, 960. 918, 891, 868, 814, 709, 662, 632, 589. 548, 515, 459 cm⁻¹

### Synthesis of Base Polymers

Base polymers used in chemically amplified resist compositions were synthesized by the following procedure.

### Synthesis Example 2-1

### Synthesis of Polymer P-1

In nitrogen atmosphere, 19 g of 1-ethylcyclopentyl methacrylate, 17 g of 2-oxotetrahydrofuran-3-yl mechacrylate, 0.48 g of dimethyl 2.2′-azobis(2-methylpropionate) (V-601 by Fuji Film Wako Pure Chemical Corp.), 0.41 g of 2-mercaptoethanol, and 50 g of methyl ethyl ketone were fed into a funnel to form a monomer/initiator solution. A flask in nitrogen atmosphere was charged with 23 g of methyl ethyl ketone, which was heated at 80° C. with stirring. With stirring, the monomer/initiator solution was added dropwise to the flask over 4 hours. After the completion of dropwise addition, the polymerization solution was continuously stirred for 2 hours while maintaining its temperature at 80° C. After the polymerization solution was cooled to room temperature, it was added dropwise to 640 g of methanol under vigorous stirring. The precipitate was collected by filtration, washed twice with 240 g of methanol, and vacuum dried at 50° C. for 20 hours, obtaining a polymer P-1 in white powder form. Amount 36 g. yield 90%. On GPC analysis. Polymer P-1 had a Mw of 8.755 and a Mw/Mn of 1.94.

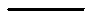

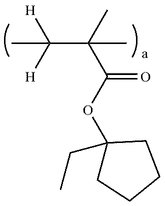

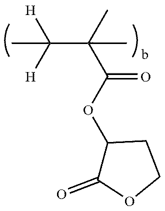

### Synthesis Examples 2-2 to 2-14

### Synthesis of Polymers P-2 to P-14

Polymers consisting of units in Table 1 were synthesized by the same procedure as in Synthesis Example 2-1 aside from changing the type and amount of monomers. Table 1 shows the proportion (in molar ratio) of repeat units incorporated in the polymers.

TABLE 1

| Polymer | Unit 1 (ratio) | Unit 2 (ratio) | Unit 3 (ratio) | Unit 4 (ratio) | Mw | Mw/Mn |
|---|---|---|---|---|---|---|
| P-1 | A-1 (0.50) | B-1 (0.50) | - | - | 8,755 | 1.94 |
| P-2 | A-4 (0.50) | B-2 (0.40) | B-4 (0.10) | - | 8.500 | 1.81 |
| P-3 | A-1 (0.50) | B-1 (0.30) | B-3 (0.20) | - | 8,700 | 1.82 |
| P-4 | A-1 (0.30) | A-5 (0.20) | B-3 (0.50) | - | 8,800 | 1.65 |
| P-5 | A-1 (0.30) | A-4 (0.20) | B-1 (0.40) | B-4 (0.10) | 8.400 | 1.72 |
| P-6 | A-1 (0.30) | A-4 (0.20) | B-2 (0.40) | B-4 (0.10) | 8,800 | 1.78 |
| P-7 | A-5 (0.50) | B-3 (0.50) | - | - | 8,300 | 1.83 |
| P-8 | A-1 (0.30) | A-6 (0.20) | B-3 (0.40) | B-4 (0.10) | 8,200 | 1.79 |
| P-9 | A-1 (0.50) | B-6 (0.50) | - | - | 8,100 | 1.93 |
| P-10 | A-2 (0.50) | B-6 (0.50) | - | - | 8,400 | 1.94 |
| P-11 | A-3 (0.50) | B-6 (0.50) | - | - | 8,600 | 1.85 |
| P-12 | A-3 (0.60) | B-5 (0.40) | - | - | 8,100 | 1.81 |
| P-13 | A-7 (0.60) | B-6 (0.40) | - | - | 8,800 | 1.72 |
| P-14 | A-8 (0.60) | B-6 (0.40) | - | - | 8,700 | 1.79 |

The structure of repeat units in Table 1 is shown below.

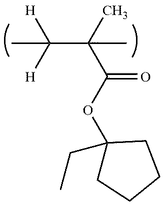

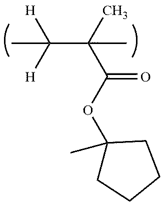

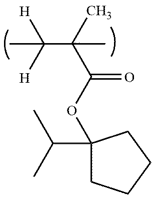

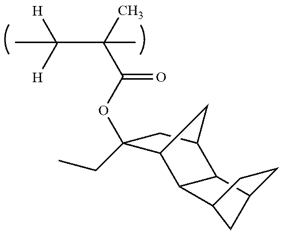

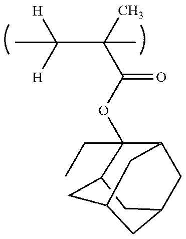

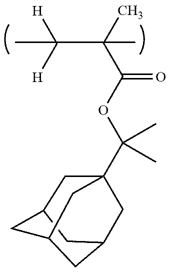

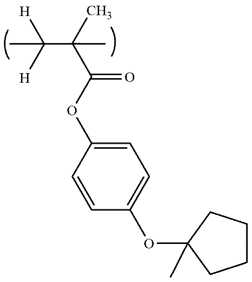

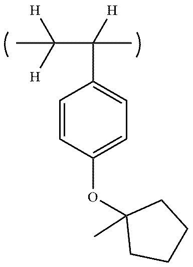

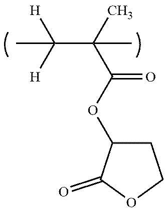

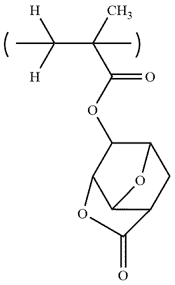

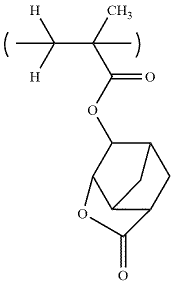

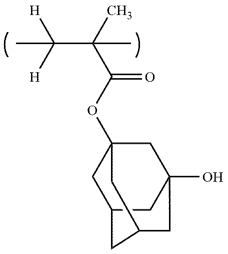

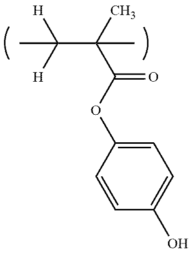

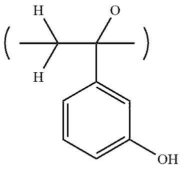

### Preparation of Resist Composition

### Examples 1-1 to 1-23 and Comparative Examples 1-1 to 1-7

A chemically amplified resist composition (R-01 to R-30) was prepared by dissolving an amine compound (Q-1 to Q-3), comparative quencher (Q-A to Q-C), polymer (P-1 to P-14), photoacid generator (PAG-X to PAG-Z), and alkali-soluble surfactant (SF-1) in an organic solvent containing 0.01 wt% of surfactant A in accordance with the formulation shown in Tables 2 and 3, and filtering the solution through a Teflon® filter with a pore size of 0.2 µm.

TABLE 2

| | | Resist composition | Polymer (pbw) | Photoacid generator (pbw) | Quencher (pbw) | Surfactant (pbw) | Solvent 1 (pbw) | Solvent 2 (pbw) |
|---|---|---|---|---|---|---|---|---|
| Example | 1-1 | R-01 | P-1 (80) | PAG-X (7.6) | Q-1 (1.2) | SF-1 (3.0) | PGMEA (1,728) | GBL (192) |
| | 1-2 | R-02 | P-1 (80) | PAG-X (7.6) | Q-2 (1.2) | SF-1 (3.0) | PGMEA (1,728) | GBL (192) |
| | 1-3 | R-03 | P-1 (80) | PAG-X (7.6) | Q-3 (1.1) | SF-1 (3.0) | PGMEA (1,728) | GBL (192) |
| | 1-4 | R-04 | P-1 (80) | PAG-Y (7.0) | Q-1 (1.2) | SF-1 (3.0) | PGMEA (1,728) | GBL (192) |
| | 1-5 | R-05 | P-1 (80) | PAG-X (7.6) | Q-1 (0.6) Q-B (1.8) | SF-1 (3.0) | PGMEA (1,728) | GBL (192) |
| | 1-6 | R-06 | P-2 (80) | PAG-X (7.6) | Q-l (1.2) | SF-1 (3.0) | PGMEA (1,728) | GBL (192) |
| | 1-7 | R-07 | P-3 (80) | PAG-X (7.6) | Q-1 (1.2) | SF-1 (3.0) | PGMEA (1,728) | GBL (192) |
| | 1-8 | R-08 | P-4 (80) | PAG-X (7.6) | Q-1 (1.2) | SF-1 (3.0) | PGMEA (1,728) | GBL (192) |
| | 1-9 | R-09 | P-5 (80) | PAG-X (7.6) | Q-1 (1.2) | SF-1 (3.0) | PGMEA (1,728) | GBL (192) |
| | 1-10 | R-10 | P-6 (80) | PAG-X (7.6) | Q-l (1.2) | SF-1 (3.0) | PGMEA (1,728) | GBL (192) |
| | 1-11 | R-11 | P-7 (80) | PAG-X (7.6) | Q-1 (1.2) | SF-1 (3.0) | PGMEA (1,728) | GBL (192) |
| | 1-12 | R-12 | P-8 (80) | PAG-X (7.6) | Q-1 (1.2) | SF-1 (3.0) | PGMEA (1,728) | GBL (192) |
| | 1-13 | R-13 | P-9 (80) | PAG-X (25.3) | Q-1 (2.9) | SF-1 (3.0) | PGMEA (1,728) | GBL (192) |
| | 1-14 | R-14 | P-9 (80) | PAG-X (253) | Q-2 (3.0) | SF-1 (3.0) | PGMEA (1,728) | GBL (192) |
| | 1-15 | R-15 | P-9 (80) | PAG-X (25.3) | Q-3 (2.7) | SF-1 (3.0) | PGMEA (1,728) | GBL (192) |
| | 1-16 | R-16 | P-9 (80) | PAG-Y (23.3) | Q-1 (2.9) | SF-1 (3.0) | PGMEA (1,728) | GBL (192) |
| | 1-17 | R-17 | P-9 (80) | PAG-X (25.3) | Q-1 (1.5) Q-B (4.6) | SF-1 (3.0) | PGMEA (1,728) | GBL (192) |
| | 1-18 | R-18 | P-9 (80) | PAG-X (253) | Q-1 (1.5) Q-C (3.9) | SF-1 (3.0) | PGMEA (1,728) | GBL (192) |
| | 1-19 | R-19 | P-10 (80) | PAG-X (25.3) | Q-1 (2.9) | SF-1 (3.0) | PGMEA (1,728) | GBL (192) |
| | 1-20 | R-20 | P-11 (80) | PAG-X (25.3) | Q-1 (2.9) | SF-1 (3.0) | PGMEA (1,728) | GBL (192) |
| | 1-21 | R-21 | P-12 (80) | PAG-X (25.3) | Q-1 (2.9) | SF-1 (3.0) | PGMEA (1,728) | GBL (192) |
| | 1-22 | R-22 | P-13 (80) | PAG-X (25.3) | Q-1 (2.9) | SF-1 (3.0) | PGMEA (1,728) | GBL (192) |
| | 1-23 | R-23 | P-14 (80) | PAG-X (25.3) | Q-1 (2.9) | SF-1 (3.0) | PGMEA (1,728) | GBL (192) |

TABLE 3

| | | Resist composition | Polymer (pbw) | Photoacid generator (pbw) | Quencher (pbw) | Surfactant (pbw) | Solvent 1 (pbw) | Solvent 2 (pbw) |
|---|---|---|---|---|---|---|---|---|
| Comparative Example | 1-1 | R-24 | P-1 (80) | PAG-X (7.6) | Q-A (1.3) | SF-1 (3.0) | PGMEA (1,728) | GBL (192) |
| | 1-2 | R-25 | P-1 (80) | PAG-X (7.6) | Q-B (3.7) | SF-1 (3.0) | PGMEA (1,728) | GBL (192) |
| | 1-3 | R-26 | P-1 (80) | PAG-Z (6.8) | Q-1 (1.2) | SF-1 (3.0) | PGMEA (1,728) | GBL (192) |
| | 1-4 | R-27 | P-9 (80) | PAG-X (253) | Q-A (3.3) | SF-1 (3.0) | PGMEA (1,728) | GBL (192) |
| | 1-5 | R-28 | P-9 (80) | PAG-X (25.3) | Q-B (9.2) | SF-1 (3.0) | PGMEA (1,728) | GBL (192) |
| | 1-6 | R-29 | P-9 (80) | PAG-X (25.3) | Q-C (7.7) | SF-1 (3.0) | PGMEA (1,728) | GBL (192) |
| | 1-7 | R-30 | P-9 (80) | PAG-Z (22.8) | Q-1 (3.1) | SF-1 (3.0) | PGMEA (1,728) | GBL (192) |

The solvents, surfactant SF-1, photoacid generators PAG-X to PAG-Z. and comparative quenchers Q-A to Q-C in Tables 2 and 3 are identified below.

Solvents
PGMEA (propylene glycol monomethyl ether acetate)
GBL (γ-butyrolactone)

Alkali-soluble surfactant SF-1: poly(2,2,3,3,4,4,4-heptafluoro-1-isobutyl-1-butyl methacrylate/9-(2,2,2-trifluoro-1-trifluoroethyloxycarbonyl)-4-oxatricyclo[4.2.1.0^{3,7}]nonan-5-on-2-yl methacrylate)

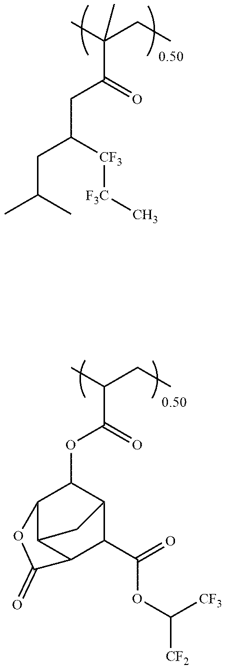

$$\begin{matrix}\text{Mw =7,700} \\ \text{Mw/Mn =1} \text{.82}\end{matrix}$$

Photoacid generators: PAG-X to PAG-Z

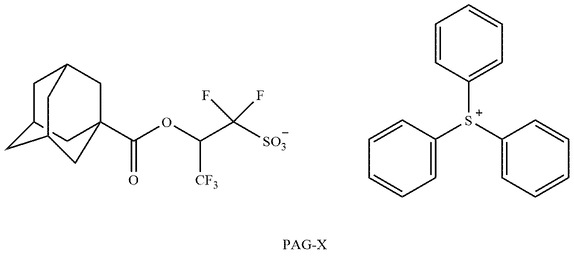

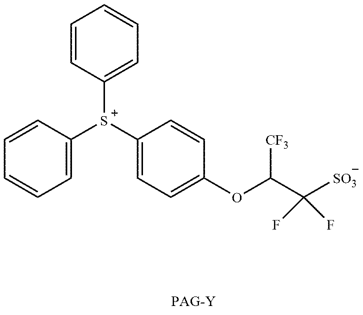

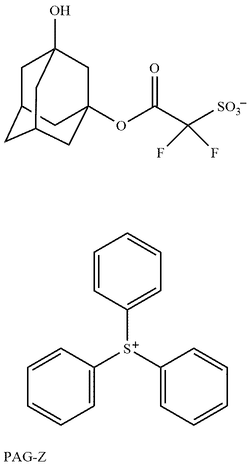

Comparative quenchers: Q-A to Q-C

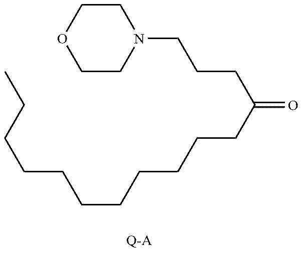

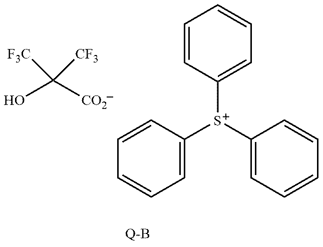

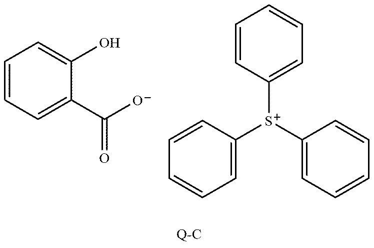

Surfactant A: 3-methyl-3-(2,2,2-trifluoroethoxymethyl)oxetane/tetrahydrofuran/2,2-dimethyl-1,3-propane diol copolymer (Omnova Solutions, Inc.)

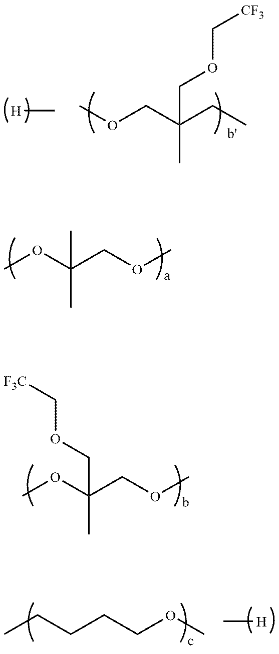

$$\begin{matrix}\text{a} \left(\text{b+} {\text{b}}^{′}\right) : \left(\text{c+} {\text{c}}^{′}\right) = 1 : 4 \text{-7:0} \text{.01-1} \left(\text{molar ratio}\right) \\ \text{Mw =1,500}\end{matrix}$$

### Evaluation of Resist Composition: ArF Lithography Test

### Examples 2-1 to 2-12 and Comparative Examples 2-1 to 2-3

On a silicon wafer, a spin-on carbon film ODL-50 (Shin-Etsu Chemical Co., Ltd.) having a carbon content of 80 wt% was deposited to a thickness of 200 nm and a silicon-containing spin-on hard mask SHB-A940 having a silicon content of 43 wt% was deposited thereon to a thickness of 35 nm. On this substrate for trilayer process, each of the resist compositions (R-01 to R-12. R-24 to R-26) was spin coated and baked on a hotplate at 100° C. for 60 seconds to form a resist film of 90 nm thick.

Using an ArF excimer laser immersion lithography scanner NSR-610C (Nikon Corp., NA 1.30, σ 0.98/0.74, dipole opening 90 deg., s-polarized illumination), pattern exposure was performed through a photomask with a varying exposure dose. Water was used as the immersion liquid. After exposure, the resist film was baked (PEB) at the temperature shown in Table 4 for 60 seconds, developed in butyl acetate for 30 seconds, and rinsed with diisoamyl ether.

The mask used herein was a halftone phase shift mask having a transmittance of 6% and bearing a pattern with a line size of 45 nm and a pitch of 90 nm as on-mask size (actual on-mask size is 4 times because of ¼ image reduction projection exposure). The trench pattern formed in the light-shielded region was observed under CD-SEM CG-4000 (Hitachi High Technologies Corp.) whereupon sensitivity, LWR, and collapse limit were evaluated by the following methods.

### Evaluation of Sensitivity

The optimum dose Eop (mJ/cm²) which provided a pattern with a trench width of 45 nm was determined and reported as an index of sensitivity.

### Evaluation of LWR

With respect to the trench pattern formed by exposure in the optimum dose, the trench width was measured in the range of 200 nm at a spacing of 10 nm, from which a 3-fold value (3σ) of standard deviation (σ) was determined and reported as LWR (nm). A smaller value of LWR indicates that a pattern with smaller roughness and more uniform space width is formed.

### Evaluation of Collapse Limit

As the exposure dose was reduced in the process, the trench size was enlarged and the line size was reduced. The maximum of trench width (nm) at which lines could be resolved without collapse was determined and reported as collapse limit. A larger value indicates greater collapse resistance and is preferable.

The results are shown in Table 4.

TABLE 4

| | | Resist composition | PEB temp. (°C) | Eop (mJ/cm²) | LWR (nm) | Collapse limit (nm) |
|---|---|---|---|---|---|---|
| Example | 2-1 | R-01 | 90 | 32 | 3.2 | 56 |
| | 2-2 | R-02 | 90 | 34 | 3.3 | 56 |
| | 2-3 | R-03 | 90 | 31 | 3.6 | 54 |
| | 2-4 | R-04 | 90 | 35 | 3.5 | 54 |
| | 2-5 | R-05 | 90 | 30 | 3.0 | 58 |
| | 2-6 | R-06 | 85 | 28 | 3.3 | 54 |
| | 2-7 | R-07 | 90 | 33 | 3.5 | 56 |
| | 2-8 | R-08 | 90 | 34 | 3.4 | 54 |
| | 2-9 | R-09 | 85 | 31 | 3.4 | 56 |
| | 2-10 | R-10 | 85 | 33 | 3.3 | 54 |
| | 2-11 | R-11 | 90 | 32 | 3.5 | 56 |
| | 2-12 | R-12 | 90 | 33 | 3.6 | 54 |
| Comparative Example | 2-1 | R-24 | 90 | 32 | 5.2 | 44 |
| | 2-2 | R-25 | 90 | 30 | 4.8 | 48 |
| | 2-3 | R-26 | 90 | 30 | 4.9 | 46 |

As is evident from Table 4, the chemically amplified resist compositions within the scope of the invention exhibit a satisfactory sensitivity and improved values of LWR and collapse limit. The resist compositions are useful in the ArF immersion lithography process.

### Evaluation of Resist Composition: EUV Lithography Test #1

### Examples 3-1 to 3-11 and Comparative Examples 3-1 to 3-4

Each of the resist compositions (R-13 to R-23, R-27 to R-30) was spin coated on a silicon substrate having a 20-nm coating of silicon-containing spin-on hard mask SHB-A940 (Shin-Etsu Chemical Co., Ltd., silicon content 43 wt%) and prebaked on a hotplate at 100° C. for 60 seconds to form a resist film of 40 nm thick. Using an EUV scanner NXE3400 (ASML, NA 0.33, σ 0.9, 90° dipole illumination), the resist film was exposed to EUV through a mask bearing a 1:1 line-and-space (LS) pattern with a size of 22 nm. The resist film was baked (PEB) on a hotplate at the temperature shown in Table 5 for 60 seconds and developed in a 2.38 wt% TMAH aqueous solution for 30 seconds to form a LS pattern.

The LS pattern was observed under CD-SEM (CG-5000, Hitachi High-Technologies Corp.) and evaluated for sensitivity, LWR, and maximum resolution by the following methods.

### Evaluation of Sensitivity

The optimum dose Eop is a dose (mJ/cm²) which provides a LS pattern with a space width of 26 nm and a pitch of 52 nm and is reported as sensitivity.

### Evaluation of LWR

For the LS pattern formed by exposure in the optimum dose Eop, the space width was measured at longitudinally spaced apart 10 points, from which a 3-fold value (3σ) of standard deviation (σ) was determined and reported as LWR. A smaller value of 3σ indicates a pattern having a lower roughness and more uniform space width.

### Evaluation of Maximum Resolution

The minimum line width (nm) of the LS pattern which remains separate at the optimum dose Eop is reported as maximum resolution.

The results are shown in Table 5.

TABLE 5

| | | Resist composition | PEB temp. (°C) | Eop (mJ/cm²) | LWR (nm) | Maximum resolution (nm) |
|---|---|---|---|---|---|---|
| Example | 3-1 | R-13 | 80 | 44 | 3.0 | 18 |
| | 3-2 | R-14 | 80 | 46 | 3.1 | 20 |
| | 3-3 | R-15 | 80 | 46 | 3.4 | 20 |
| | 3-4 | R-16 | 80 | 50 | 3.4 | 20 |
| | 3-5 | R-17 | 80 | 45 | 2.9 | 18 |
| | 3-6 | R-18 | 80 | 47 | 2.8 | 16 |
| | 3-7 | R-19 | 85 | 50 | 3.1 | 18 |
| | 3-8 | R-20 | 80 | 42 | 3.1 | 18 |
| | 3-9 | R-21 | 80 | 40 | 3.4 | 20 |
| | 3-10 | R-22 | 85 | 43 | 3.5 | 20 |
| | 3-11 | R-23 | 85 | 46 | 3.4 | 20 |
| Comparative Example | 3-1 | R-27 | 80 | 50 | 4.8 | 26 |
| | 3-2 | R-28 | 80 | 44 | 4.4 | 26 |
| | 3-3 | R-29 | 80 | 48 | 4.2 | 24 |
| | 3-4 | R-30 | 80 | 42 | 4.6 | 24 |

It is evident from Table 5 that the resist compositions within the scope of the invention form LS patterns having satisfactory sensitivity, LWR and maximum resolution when processed by the EUV lithography.

### Evaluation of Resist Composition: EUV Lithography Test #2

### Examples 4-1 to 4-11 and Comparative Examples 4-1 to 4-4

On a silicon substrate having a silicon-containing spin-on hard mask SHB-A940 (Shin-Etsu Chemical Co., Ltd., a silicon content of 43 wt%) deposited thereon to a thickness of 20 nm, each of the resist compositions (R-13 to R-23, R-27 to R-30) was spin coated and baked on a hotplate at 105° C. for 60 seconds to form a resist film of 50 nm thick. Using an EUV scanner NXE3400 (ASML, NA 0.33, σ 0.9/0.6. quadrupole illumination), the resist film was exposed to EUV through a mask bearing a hole pattern with a pitch of 40 nm +20% bias (on-wafer size). After exposure, the resist film was baked (PEB) on a hotplate at the temperature shown in Table 6 for 60 seconds and developed in 2.38 wt% TMAH aqueous solution for 30 seconds to form a hole pattern.

The hole pattern was observed under CD-SEM (CG-6300, Hitachi High-Technologies Corp.) and evaluated for sensitivity and CDU by the following methods.

### Evaluation of Sensitivity

The optimum dose Eop is a dose (mJ/cm²) which provides a hole pattern with a size of 40 nm and is reported as sensitivity.

### Evaluation of CDU

The size of 50 holes which were printed at Eop was measured, from which a 3-fold value (3σ) of standard deviation (σ) was computed and reported as CDU. A smaller value of CDU indicates a hole pattern with better dimensional uniformity.

The results are shown in Table 6.

TABLE 6

| | | Resist composition | PEB temp. (°C) | Eop (mJ/cm²) | CDU (nm) |
|---|---|---|---|---|---|
| Example | 4-1 | R-13 | 80 | 34 | 3.3 |
| | 4-2 | R-14 | 80 | 36 | 3.2 |
| | 4-3 | R-15 | 80 | 36 | 3.6 |
| | 4-4 | R-16 | 80 | 40 | 3.7 |
| | 4-5 | R-17 | 80 | 35 | 2.9 |
| | 4-6 | R-18 | 80 | 37 | 2.8 |
| | 4-7 | R-19 | 85 | 41 | 3.0 |
| | 4-8 | R-20 | 80 | 32 | 3.2 |
| | 4-9 | R-21 | 80 | 30 | 3.3 |
| | 4-10 | R-22 | 85 | 33 | 3.2 |
| | 4-11 | R-23 | 85 | 36 | 3.4 |
| Comparative Example | 4-1 | R-27 | 80 | 39 | 5.0 |
| | 4-2 | R-28 | 80 | 34 | 4.5 |
| | 4-3 | R-29 | 80 | 38 | 4.2 |
| | 4-4 | R-30 | 80 | 32 | 4.9 |

It is evident from Table 6 that the resist compositions within the scope of the invention form hole patterns having improved CDU at a high sensitivity when processed by the EUV lithography.

Japanese Patent Application No. 2021-155463 is incorporated herein by reference.

Although some preferred embodiments have been described, many modifications and variations may be made thereto in light of the above teachings. It is therefore to be understood that the invention may be practiced otherwise than as specifically described without departing from the scope of the appended claims.

1. A chemically amplified resist composition comprising
(A) a polymer A adapted to increase its solubility in alkaline aqueous solution under the action of acid,
(B) a photoacid generator capable of generating an acid upon exposure to KrF excimer laser radiation, ArF excimer laser radiation, EB or EUV, and (C) a quencher in the form of an amine compound.
said photoacid generator (B) having the formula (1a) or (1b): 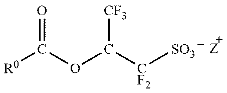
wherein R⁰ is hydrogen or a C₁-C₅₀ hydrocarbyl group in which some or all of the hydrogen atoms may be substituted by halogen and any constituent —CH₂— may be replaced by —O— or —C(═O)—, Z⁺ is an organic cation, 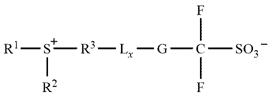
wherein R¹ and R² are each independently a C₁-C₂₀ hydrocarbyl group which may contain a heteroatom, R¹ and R² may bond together to form a ring with the sulfur atom to which they are attached, R³ is a C₁-C₂₀ hydrocarbylene group which may contain a heteroatom. G is a single bond or a C₁-C₂₀ hydrocarbylene group which may contain a heteroatom, and Lx is a divalent linking group,
said amine compound having the formula (2): 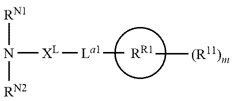
wherein m is an integer of 0 to 10,
R^{N1} and R^{N2} are each independently hydrogen or a C₁-C₂₀ hydrocarbyl group in which some or all of the hydrogen atoms may be substituted by halogen and any constituent —CH₂— may be replaced by —O— or —C(═O)—, R^{N1} and R^{N2} may bond together to form a ring with the nitrogen atom to which they are attached, the ring optionally containing —O— or —S—, with the proviso that R^{N1} and R^{N2} are not hydrogen at the same time,
X^{L} is a C₁-C₄₀ hydrocarbylene group which may contain a heteroatom,
L^{a1} is a single bond, ether bond, ester bond, sulfonic ester bond, carbonate bond or carbamate bond.
the ring R^{R1} is a C₂-C₂₀ (m+1)-valent heterocyclic group having a lactone, lactam, sultone or sultam structure,
R¹¹ is a C₁-C₂₀ hydrocarbyl group which may contain a heteroatom, and when m is 2 or more, a plurality of R¹¹ may be the same or different, and a plurality of R¹¹ may bond together to form a ring with the atoms on R^{R1} to which they are attached.

2. The resist composition of claim 1 wherein the polymer A comprises repeat units having the formula (al) or (a2): 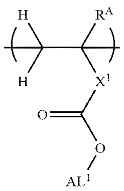 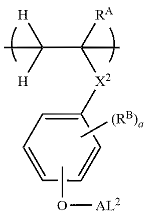
wherein R^{A} is each independently hydrogen, fluorine, methyl or trifluoromethyl,
X¹ is a single bond, phenylene, naphthylene, or ^{∗}—C(═O)—O—X¹¹—, X¹¹ is a C₁-C₁₀ alkanediyl group which may contain a hydroxy moiety, ether bond, ester bond or lactone ring, or phenylene group or naphthylene group,
X² is a single bond or ^{∗}—C(═O)—O—,
the asterisk (^{∗}) designates a point of attachment to the carbon atom in the backbone.
AL¹ and AL² are each independently an acid labile group,
R^{B} is a C₁-C₂₀ hydrocarbyl group which may contain a heteroatom, and
a is an integer of 0 to 4.

3. The resist composition of claim 1 wherein the polymer A comprises repeat units having the formula (b1) or (b2): 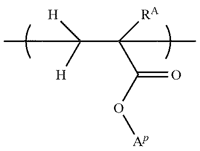 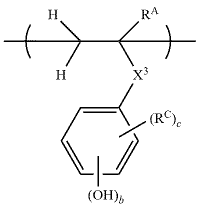
wherein R^{A} is each independently hydrogen, fluorine, methyl or trifluoromethyl,
A^{P} is hydrogen, or a polar group containing at least one structure selected from a hydroxy moiety, cyano moiety, carbonyl moiety, carboxy moiety, ether bond, ester bond, sulfonic ester bond, carbonate bond, lactone ring, sultone ring, and carboxylic anhydride (—C(═O)—O—C(═O)—),
X³ is a single bond or ^{∗}—C(═O)—O—, the asterisk (^{∗}) designates a point of attachment to the carbon atom in the backbone,
R^{C} is halogen, cyano group, or a C₁-C₂₀ hydrocarbyl group which may contain a heteroatom, C₁-C₂₀ hydrocarbyloxy group which may contain a heteroatom, or C₂-C₂₀ hydrocarbylcarbonyl group which may contain a heteroatom,
b is an integer of 1 to 4, c is an integer of 0 to 4, and 1 ≤ b+c ≤ 5.

4. The resist composition of claim 1, further comprising (D) an organic solvent.

5. The resist composition of claim 1, further comprising (E) a quencher other than the amine compound having formula (2).

6. The resist composition of claim 1, further comprising (F) a surfactant.

7. A pattern forming process comprising the steps of applying the chemically amplified resist composition of claim 1 onto a substrate to form a resist film thereon, exposing the resist film to KrF excimer laser radiation, ArF excimer laser radiation, EB or EUV, and developing the exposed resist film in a developer.
